(19) United States
(12) Patent Application Publication
(10) Pub. No.: US 2025/0376552 A1
(43) Pub. Date: Dec. 11, 2025

(54) RESIN COMPOSITION, CURED SUBSTANCE, LAMINATE, MANUFACTURING METHOD FOR CURED SUBSTANCE, MANUFACTURING METHOD FOR LAMINATE, MANUFACTURING METHOD FOR SEMICONDUCTOR DEVICE, AND SEMICONDUCTOR DEVICE

(71) Applicant: FUJIFILM CORPORATION, Tokyo (JP)

(72) Inventors: Yuta Yamakawa, Shizuoka (JP); Atsuyasu Nozaki, Shizuoka (JP); Kazuya Oota, Shizuoka (JP)

(21) Appl. No.: 19/312,438

(22) Filed: Aug. 28, 2025

Related U.S. Application Data
(63) Continuation of application No. PCT/JP2024/007579, filed on Feb. 29, 2024.

(30) Foreign Application Priority Data
Mar. 8, 2023 (JP) 2023-035701

(51) Int. Cl. C08F 290/14; C08F 2/50; C08L 55/00; G03F 7/029; G03F 7/037

(52) U.S. Cl. CPC C08F 290/145; C08F 2/50; C08L 55/005; G03F 7/029; G03F 7/037; C08L 2203/20

(57) ABSTRACT

Provided are a resin composition including at least one resin selected from the group consisting of polyimide and a precursor of the polyimide, a polymerizable compound, and a polymerization initiator, in which a dissolution rate of a film having a film thickness of 10 μm, which is obtained from the resin composition, in cyclopentanone is 0.01 to 0.55 μm/sec, a cured substance obtained by curing the composition, a laminate including the cured substance, a manufacturing method for a cured substance, a manufacturing method for a laminate, a manufacturing method for a semiconductor device including the method for a cured substance, and a semiconductor device including a cured substance.

### CROSS-REFERENCE TO RELATED APPLICATIONS

This application is a Continuation of PCT International Application No. PCT/JP2024/007579 filed on Feb. 29, 2024, which claims priority under 35 U.S.C § 119 (a) to Japanese Patent Application No. 2023-035701 filed on Mar. 8, 2023. Each of the above application(s) is hereby expressly incorporated by reference, in its entirety, into the present application.

### BACKGROUND OF THE INVENTION

### 1. Field of the Invention

The present invention relates to a resin composition, a cured substance, a laminate, a manufacturing method for a cured substance, a manufacturing method for a laminate, a manufacturing method for a semiconductor device, and a semiconductor device.

### 2. Description of the Related Art

In recent years, in various fields, a resin material produced from a resin composition containing a polyimide or a precursor of the polyimide has been used.

For example, use applications of the above-described resin material are not particularly limited, and examples thereof in a semiconductor device for mounting include the use as a material of an insulating film or sealing material, or as a protective film. In addition, such a resin can also be used as a base film or a cover lay for a flexible substrate.

Since the resin composition can be applied by a publicly known coating method or the like, it can be said that the resin composition is excellent in the manufacturing adaptability, for example, a high degree of freedom in designing the shape, size, application position of the resin composition to be applied during application. From the viewpoint of such excellent manufacturing adaptability, the industrial application and development of the above-described resin composition are expected increasingly.

For example, JP2003-131371A describes a photosensitive resin composition containing, as essential components, (A) a soluble polyimide containing at least one constitutional unit of a specific structure, (B) a compound in which at least one atom or moiety selected from the group consisting of phosphorus, halogen, and siloxane moieties is covalently bonded, and (C) a (meth)acrylic compound having one or more carbon double bonds.

JP2000-147768A describes a solvent-soluble negative-tone photosensitive polyimide composition including two or more aromatic diamine components in a polyimide main chain, in which one of the two or more aromatic diamines is an aromatic diamine having photosensitivity and the other is an aromatic diamine having a hydrophilic group.

### SUMMARY OF THE INVENTION

In recent years, it has been more and more important to increase the signal speed of the inter-chip wiring, and the miniaturization of the re-distribution wiring for connecting the chips has progressed. Therefore, even in a cured substance of a resin composition used for applications such as re-distribution line formation and insulation, there is an increasing demand for further resolution.

An object of the present invention is to provide a resin composition having excellent resolution in a case of forming a pattern of a cured substance, a cured substance obtained by curing the composition, a laminate including the cured substance, a manufacturing method for a cured substance, a manufacturing method for a laminate, a manufacturing method for a semiconductor device including a manufacturing method for a cured substance, a semiconductor device including a cured substance, and a novel resin.

Examples of representative embodiments according to the present invention are described below.

<1> A resin composition comprising:
at least one resin selected from the group consisting of a polyimide and a precursor of the polyimide;
a polymerizable compound; and
a polymerization initiator,
in which a dissolution rate of a film having a film thickness of 10 μm, which is obtained from the resin composition, in cyclopentanone is 0.01 to 0.55 μm/sec.

<2> A resin composition comprising:
at least one resin selected from the group consisting of a polyimide and a precursor of the polyimide;
a polymerizable compound; and
a polymerization initiator,
in which the resin composition includes a resin in which a dissolution rate of a film of the resin having a film thickness of 10 μm in cyclopentanone is 0.01 to 0.2 μm/sec as the resin.

<3> The resin composition according to <1> or <2>,
in which a weight-average molecular weight of the resin is 8,000 or more and less than 30,000.

<4> The resin composition according to any one of <1> to <3>,
in which the resin is a resin having a ring structure with 5 or more ring members in a side chain.

<5> The resin composition according to any one of <1> to <4>,
in which the resin is a resin including a structure represented by Formula (A-1),

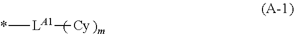

in Formula (A-1), L^{A1} represents a single bond or an (m+1)-valent linking group, Cy's each independently represent a ring structure with 5 or more ring members, which may have a substituent, m represents an integer of 1 or more, and * represents a bonding site to another structure.

<6> The resin composition according to any one of <1> to <5>,
in which the resin has a polymerizable group.

<7> The resin composition according to any one of <1> to <6>,
in which the resin includes a repeating unit represented by Formula (1-1),

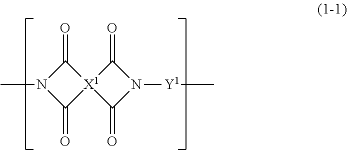

in Formula (1-1), X¹ is a tetravalent organic group, and Y¹ is an organic group including a group having an ethylenically unsaturated bond.

<8> The resin composition according to <7>,
in which a value of a molar amount of oxygen atoms/weight-average molecular weight in the resin is 9.7 mmol/g or less.

<9> The resin composition according to <7> or <8>,
in which Y¹ in Formula (1-1) includes a ring structure with 5 or more ring members.

<10> The resin composition according to any one of <7> to <9>,
in which Y¹ in Formula (1-1) includes a vinylphenyl group.

<11> The resin composition according to any one of <7> to <9>,
in which Y¹ in Formula (1-1) includes a structure represented by Formula (B-1) or (B-2),

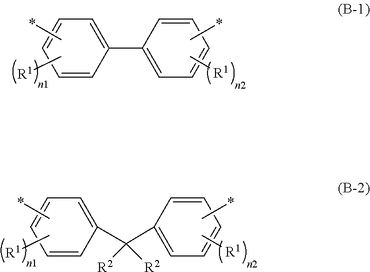

in Formula (B-1), R¹'s each independently represent an organic group including a group having an ethylenically unsaturated bond, n1 represents an integer of 0 to 3, n2 represents an integer of 0 to 3, n1+n2 represents an integer of 1 to 6, and * represents a bonding site to another structure,
in Formula (B-2), R¹'s each independently represent an organic group including a group having an ethylenically unsaturated bond, n1 represents an integer of 0 to 3, n2 represents an integer of 0 to 3, n1+n2 represents an integer of 1 to 6, R²'s each independently represent an alkyl group or a fluoroalkyl group, and * represents a bonding site to another structure.

<12> The resin composition according to <11>, further comprising:
a repeating unit represented by Formula (1-2),

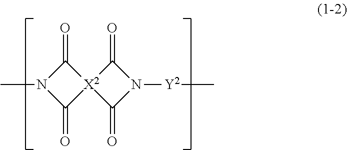

in Formula (1-2), X² is a tetravalent organic group, Y² is a divalent organic group having no ethylenically unsaturated bond, and at least one of X² or Y² includes a group obtained by removing two or more hydrogen atoms from a structure represented by Formula (C-1),

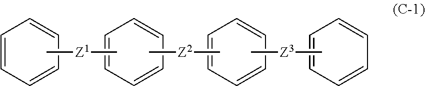

in Formula (C-1), Z¹ to Z³ are each independently a single bond or a divalent linking group, and four benzene rings described in Formula (C-1) may each have a substituent.

<13> A resin composition comprising:
a resin having a repeating unit represented by Formula (1-3) and a structure represented by Formula (A-1);
a polymerizable compound; and
a polymerization initiator,

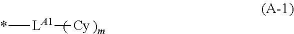

in Formula (A-1), L^{A1} represents a single bond or an (m+1)-valent linking group, Cy's each independently represent a ring structure with 5 or more ring members, which may have a substituent, m represents an integer of 1 or more, and * represents a bonding site to another structure,

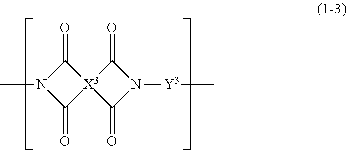

in Formula (1-3), X³ is a tetravalent organic group, Y³ is a divalent organic group including a vinylphenyl group, and Y³ includes a structure represented by Formula (B-1) or Formula (B-2),

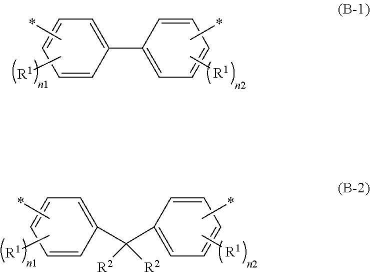

in Formula (B-1), R¹'s each independently represent an organic group including a group having an ethylenically unsaturated bond, n1 represents an integer of 0 to 3, n2 represents an integer of 0 to 3, n1+n2 represents an integer of 1 to 6, and * represents a bonding site to another structure,
in Formula (B-2), R¹'s each independently represent an organic group including a group having an ethylenically unsaturated bond, n1 represents an integer of 0 to 3, n2 represents an integer of 0 to 3, n1+n2 represents an integer of 1 to 6, R²'s each independently represent an alkyl group or a fluoroalkyl group, and * represents a bonding site to another structure.

<14> The resin composition according to any one of <1> to <13>,
in which the resin composition contains a radically polymerizable compound as the polymerizable compound, and
a content of the radically polymerizable compound is 8 parts by mass or more and 30 parts by mass or less with respect to 100 parts by mass of the resin.

<15> The resin composition according to <1> or <2>,
in which the resin composition includes a photoradical polymerization initiator as the polymerization initiator, and
the resin composition includes a radically polymerizable compound as the polymerizable compound.

<16> The resin composition according to <15>,
in which the radically polymerizable compound includes two or more (meth)acryloyl groups.

<17> The resin composition according to <15> or <16>,
in which the resin composition includes an oxime compound as the photoradical polymerization initiator.

<18> The resin composition according to <15> or <16>,
in which the resin composition includes a compound having a ketoxime group as the photoradical polymerization initiator.

<19> The resin composition according to any one of <1> to <18>,
in which the resin composition includes a resin having an ethylenically unsaturated bond equivalent of 0.5 to 2.0 mmol/g as the resin.

<20> The resin composition according to <1> or <2>,
in which the resin composition is used for forming an interlayer insulating film for a re-distribution layer.

<21> A cured substance obtained by curing the resin composition according to any one of <1> to <20>.

<22> A laminate comprising:
two or more layers consisting of the cured substance according to <21>; and a metal layer provided between any of the layers consisting of the cured substance.

<23> A manufacturing method for a cured substance, further comprising:
a film forming step of applying the resin composition according to any one of <1> to <20> onto a base material to form a film.

<24> The manufacturing method for a cured substance according to <23>, further comprising:
an exposure step of selectively exposing the film; and
a development step of developing the film using a developer to form a pattern.

<25> The manufacturing method for a cured substance according to <23> or <24>, further comprising:
a heating step of heating the film at 50° C. to 450° C.

<26> A manufacturing method for a laminate, comprising:
the manufacturing method for a cured substance according to any one of <23> to <25>.

<27> A manufacturing method for a semiconductor device, comprising:
the manufacturing method for a cured substance according to any one of <23> to <25>.

<28> A semiconductor device comprising:
the cured substance according to <21>.

According to the present invention, there are provided a resin composition having excellent resolution in a case of forming a pattern of a cured substance, a cured substance obtained by curing the composition, a laminate including the cured substance, a manufacturing method for a cured substance, a manufacturing method for a laminate, a manufacturing method for a semiconductor device including a manufacturing method for a cured substance, and a semiconductor device including a cured substance.

### DESCRIPTION OF THE PREFERRED EMBODIMENTS

Hereinafter, the main embodiments according to the present invention will be described. However, the present invention is not limited to the specified embodiments.

In the present specification, a numerical value range described by using “to” means a range including numerical values described before and after the preposition “to” as a lower limit value and an upper limit value, respectively.

In the present specification, the term “step” means not only an independent step but also a step that cannot be clearly distinguished from other steps as long as the desired action of the step can be achieved.

In describing a group (an atomic group) in the present specification, in a case where a description of substitution and unsubstitution is not provided, the description means the group includes a group (an atomic group) having a substituent as well as a group (an atomic group) having no substituent. For example, the “alkyl group” includes not only an alkyl group that does not have a substituent (an unsubstituted alkyl group) but also an alkyl group that has a substituent (a substituted alkyl group).

In the present specification, the “exposure” includes not only exposure using light but also exposure using corpuscular beams such as an electron beam and an ion beam, unless otherwise specified. In addition, examples of the light that is used for exposure include an actinic ray such as a bright line spectrum of a mercury lamp, a far ultraviolet ray represented by an excimer laser, an extreme ultraviolet ray (EUV light), an X-ray, or an electron beam, and a radioactive ray.

In the present specification, “(meth)acrylate” means one or both of “acrylate” and “methacrylate”, “(meth)acryl” means one or both of “acryl” and “methacryl”, and “(meth)acryloyl” means one or both of “acryloyl” and “methacryloyl”.

In the structural formulae of the present specification, Me represents a methyl group, Et represents an ethyl group, Bu represents a butyl group, and Ph represents a phenyl group.

In the present specification, the total solid content refers to the total mass of components excluding a solvent from the entire components of the composition. In addition, in the present specification, the concentration of solid contents is a mass percentage of other components excluding a solvent with respect to the total mass of the composition.

In the present specification, weight-average molecular weight (Mw) and number-average molecular weight (Mn) are each a value measured using gel permeation chromatography (GPC) unless otherwise specified, which are defined as a polystyrene equivalent value. In the present specification, the weight-average molecular weight (Mw) and the number-average molecular weight (Mn) can be determined, for example, by using HLC-8220 GPC (manufactured by Tosoh Corporation) and using GUARD COLUMN HZ-L, TSKgel Super HZM-M, TSK gel Super HZ4000, TSK gel Super HZ3000, and TSK gel Super HZ2000 (all of which are manufactured by Tosoh Corporation) as a column connected in series. The measurements of the above molecular weights are carried out using tetrahydrofuran (THF) as an eluent unless otherwise specified. However, N-methyl-2-pyrrolidone (NMP) can also be used in a case where THE is not suitable as the eluent, for example, in a case where the solubility is low. In addition, the detection in GPC measurement is carried out using a detector with an ultraviolet ray (a UV ray) of a wavelength of 254 nm unless otherwise specified.

In the present specification, in a case where the positional relationship of respective layers constituting the laminate is described as “upper” or “lower”, it suffices that another layer is on the upper side or the lower side of the reference layer among the plurality of layers of interest. That is, a third layer or element may be further interposed between the reference layer and the other layer, and the reference layer and the other layer need not be in contact with each other. Unless otherwise specified, the direction in which the layers are laminated on the base material is referred to as “upward”, or in a case where a resin composition layer is present, the direction from the base material to the resin composition layer is referred to as “upper”. The opposite direction thereof is referred to as “downward”. Furthermore, such a setting of upward and downward directions is for convenience in the present specification, and in a practical aspect, the “upward” direction in the present specification may be different from a vertically upward direction.

In the present specification, a composition may contain, as each component contained in the composition, two or more compounds corresponding to the component unless otherwise specified. The content of each component in the composition means the total content of all the compounds corresponding to the component unless otherwise specified.

In the present specification, unless otherwise specified, the temperature is 23° C., the atmospheric pressure is 101,325 Pa (1 atm), and the relative humidity is 50% RH.

In addition, in the present specification, a combination of preferred aspects is a more preferred aspect.

### (Resin Composition)

A resin composition according to a first aspect of the present invention (hereinafter, also simply referred to as a “first resin composition”) is a resin composition containing at least one resin selected from the group consisting of a polyimide and a precursor of the polyimide, a polymerizable compound, and a polymerization initiator, in which a dissolution rate of a film having a film thickness of 10 μm, which is obtained from the resin composition, in cyclopentanone is 0.01 to 0.55 μm/sec.

A resin composition according to a second aspect of the present invention (hereinafter, also simply referred to as a “second resin composition”) is a resin composition containing at least one resin selected from the group consisting of a polyimide and a precursor of the polyimide, a polymerizable compound, and a polymerization initiator, in which the resin includes a resin having a dissolution rate of 0.01 to 0.2 μm/sec in cyclopentanone for a film of the resin having a film thickness of 10 μm.

A resin composition according to a third aspect of the present invention (hereinafter, also simply referred to as a “third resin composition”) includes a resin having a repeating unit represented by Formula (1-3) and a structure represented by Formula (A-1), a polymerizable compound, and a polymerization initiator.

Hereinafter, the first resin composition, the second resin composition, and the third resin composition are simply referred to as a “resin composition”.

Hereinafter, the resin which is contained in the first resin composition and is a polyimide having a repeating unit represented by Formula (1-2) is also referred to as a “first specific resin”.

Hereinafter, at least one resin selected from the group consisting of a polyimide and a precursor of the polyimide, which is contained in the second resin composition, is also referred to as a “second specific resin”.

Hereinafter, at least one resin selected from the group consisting of a polyimide and a precursor of the polyimide, which is contained in the third resin composition, is also referred to as a “third specific resin”.

Hereinafter, in a case where the term “specific resin” is simply described, it refers to all of the first specific resin, the second specific resin, and the third specific resin.

The resin composition according to the embodiment of the present invention is preferably used for forming a photosensitive film that is subjected to exposure and development, and more preferably used for forming a film that is subjected to exposure and development using a developer containing an organic solvent.

The resin composition according to the embodiment of the present invention can be used, for example, for forming an insulating film of a semiconductor device, an interlayer insulating film for a re-distribution layer, a stress buffer film, or the like, and it is preferably used for forming an interlayer insulating film for a re-distribution layer.

In particular, one of the preferred aspects of the present invention is that the resin composition according to the embodiment of the present invention is used for forming an interlayer insulating film for a re-distribution layer.

In addition, the resin composition according to the embodiment of the present invention is preferably used for forming a photosensitive film that is subjected to negative-tone development.

In the present invention, the negative-tone development refers to development in which, in exposure and development, a non-exposed portion is removed by the development, and the positive-tone development means a development in which an exposed portion is removed by the development.

As the exposure method, the developer, and the development method, for example, the following ones in the description of the manufacturing method for a cured substance, which will be described later, are used: an exposure method to be described in the exposure step, and a developer and a development method to be described in the development step. The resin composition according to the embodiment of the present invention has excellent resolution in a case of forming a pattern of a cured substance.

Although the mechanism by which the above effect is obtained is not revealed, it is presumed as follows.

In the first aspect of the present invention, in the first resin composition, a dissolution rate of a film having a film thickness of 10 μm, which is obtained from the resin composition, in cyclopentanone is 0.01 to 0.55 μm/sec.

It is considered that, in such a film having low solubility in cyclopentanone, the image area (a region that is not developed) is less likely to swell by development, and defects such as opening defects are less likely to occur in a case of forming a fine pattern, and thus high resolution is exhibited.

In the second aspect of the present invention, the second resin composition includes, as the resin, a resin having a dissolution rate of 0.01 to 0.2 μm/sec with respect to cyclopentanone in a film of the resin having a film thickness of 10 μm.

It is considered that, in such a film including a resin having low solubility in cyclopentanone, the image area is less likely to swell by development, and defects such as opening defects are less likely to occur in a case of forming a fine pattern, and thus high resolution is exhibited.

In the third aspect of the present invention, the third resin composition has a repeating unit represented by Formula (1-3) and has a structure represented by Formula (A-1).

It is considered that, in such a film including a resin having a specific structure and molecular weight, an image area is not likely to swell by development, defects such as opening defects are not likely to occur in a case of forming a fine pattern, and high resolution is exhibited. In addition, as described above, it is considered that the pattern of the resin composition according to the embodiment of the present invention is not likely to swell during development. Therefore, it is considered that the adhesiveness to the base material is excellent and the pattern collapse due to development is also suppressed.

Furthermore, in a case where the resin composition according to the embodiment of the present invention is used, it is considered that the resin is suppressed from being dissolved out during development from the pattern, and thus the obtained pattern is suppressed from having a skirting shape (that is, a shape having a small taper angle).

Here, JP2003-131371A and JP2000-147768A do not describe the first resin composition, the second resin composition, and the third resin composition.

Hereinafter, the characteristics of the resin composition according to the embodiment of the present invention and the components contained in the resin composition will be described in detail.

<Dissolution Rate of Film Obtained from Resin Composition>

A dissolution rate of a film having a film thickness of 10 μm, which is obtained from the first resin composition, in cyclopentanone is 0.01 to 0.55 μm/sec.

The dissolution rate of the film having a film thickness of 10 μm, which is obtained from the second resin composition, in cyclopentanone is preferably 0.01 to 0.55 μm/sec.

The dissolution rate of the film having a film thickness of 10 μm, which is obtained from the third resin composition, in cyclopentanone is preferably 0.01 to 0.55 μm/sec.

The lower limit of the dissolution rate of the film is preferably 0.01 μm/sec or more and more preferably 0.1 μm/sec or more.

The upper limit of the dissolution rate of the film is preferably 0.55 μm/sec or less and more preferably 0.40 μm/sec or less.

The above-described film is obtained, for example, by applying a resin composition to a base material such as a silicon wafer and drying the applied resin composition as necessary. In a case where the drying is performed, the film thickness after the drying is 10 μm.

A silicon wafer can be used as the base material. In a case where it is difficult to form a film having a film thickness of 10 μm on a silicon wafer, another base material having different properties such as wettability of the surface may be used.

The method of applying the resin composition to the base material is not particularly limited, and any method may be used as long as the film thickness is 10 μm. However, a spin coating method can be used. In a case where it is difficult to form a film having a film thickness of 10 μm by a spin coating method, a known method such as a dip coating method, an air knife coating method, a curtain coating method, a wire bar coating method, a gravure coating method, an extrusion coating method, a spray coating method, a slit coating method, or an ink jet method may be appropriately selected.

It is preferable that the drying is carried out until the amount of the solvent in the film is 0.1% by mass or less.

The drying conditions are not particularly limited, but can be carried out by drying with heating. In addition, in a case where it is difficult to sufficiently dry the composition only by heating, the pressure may be further reduced.

The drying can be carried out in the atmosphere. However, in a case where the resin composition contains a component or the like that is likely to be modified by oxygen, the treatment can also be carried out under an inert gas replacement such as nitrogen, under vacuum, or the like.

The drying means is not particularly limited, and examples thereof include a hot plate. However, in a case where the above-described pressure reduction, inert gas replacement, and the like are required, an oven with a pressure reduction function, an oven with a gas replacement function, or the like can also be used.

In a case of carrying out drying by heating, the heating temperature can be set to, for example, 110° C. However, in a case where it is difficult to dry at 110° C., the drying temperature may be appropriately changed to 70° C. to 130° C., preferably 90° C. to 120° C., depending on the kind or the like of the solvent contained in the resin composition.

In a case where the drying is performed by heating, the drying time (the time during which the heating is performed at the above-described heating temperature) can be, for example, 5 minutes. However, in a case where it is difficult to carry out drying for 5 minutes, the drying time may be appropriately changed to 30 seconds to 20 minutes, and preferably 1 minute to 10 minutes, depending on the kind of the solvent contained in the resin composition.

In a case where the drying is performed by heating, the temperature rising rate during heating is not particularly limited, and for example, it can be set to 5° C./min. In a case where the drying at the above-described temperature rising rate is difficult, the temperature rising rate may be appropriately changed to 1 to 12° C./min or 2 to 10° C./min depending on the kind or the like of the solvent contained in the resin composition.

The dissolution rate of the film in cyclopentanone can be calculated by immersing a silicon wafer on which the film is formed in cyclopentanone for 15 seconds and measuring the film thickness of the film before and after the immersion with an ellipsometer.

The film is immersed in cyclopentanone in a state in which the film is not subjected to heating other than the drying.

The amount of cyclopentanone used for the immersion is preferably 30 times the volume of the film.

The temperatures of the cyclopentanone, the film, and the silicon wafer during the immersion are set to 23° C.

In a case where the entire film is dissolved or the film thickness does not change at all or similar cases, the dissolution rate may be calculated by appropriately changing the immersion time.

Specifically, the dissolution rate of the film can be measured by a method described in Examples described later.

The dissolution rate of the film can be adjusted by the structure, the content, and the like of the specific resin, the polymerizable compound, and the like contained in the resin composition.

### <Specific Resin>

The first resin composition contains at least one resin selected from the group consisting of polyimide and a precursor of the polyimide, and preferably contains polyimide.

The second resin composition contains at least one resin selected from the group consisting of polyimide and a precursor of the polyimide, and preferably contains polyimide.

The polyimide precursor refers to a resin which is polyimide due to a change in chemical structure caused by an external stimulus, and a resin which is polyimide due to a change in chemical structure caused by heat is preferable, and a resin which is polyimide due to a ring closure reaction caused by heat to form a ring structure is more preferable.

### [Dissolution Rate]

The dissolution rate of the film of the second specific resin having a film thickness of 10 μm in cyclopentanone is 0.01 to 0.2 μm/sec.

The dissolution rate of the film of the first specific resin having a film thickness of 10 μm in cyclopentanone is preferably 0.01 to 0.2 μm/sec.

The dissolution rate of the film of the third specific resin having a film thickness of 10 μm in cyclopentanone is preferably 0.01 to 0.2 μm/sec.

The lower limit of the dissolution rate is preferably 0.02 μm/sec or more and more preferably 0.05 μm/sec or more.

The upper limit of the dissolution rate is preferably 0.2 μm/sec or less and more preferably 0.15 μm/sec or less.

The above-described film used for measuring the dissolution rate of the specific resin is obtained, for example, by preparing a solution in which the specific resin is dissolved in a solvent, applying the solution to a base material such as a silicon wafer, and drying the solution as necessary. In a case where the drying is performed, the film thickness after the drying is 10 μm.

As a solvent for dissolving the specific resin used in the preparation of the above-described solution, γ-butyrolactone can be used. In a case where it is difficult to carry out the dissolution in γ-butyrolactone because the specific resin is not dissolved or similar cases, the solvent may be appropriately changed to a solvent that dissolves the specific resin, such as N-methyl-2-pyrrolidone or dimethyl sulfoxide.

The content of the specific resin in the solution can be set to 30% by mass with respect to the total mass of the solvent. However, in a case where it is difficult to form a film having a thickness of 10 μm at the above-described content, the solubility of the specific resin is low and the specific resin cannot be prepared, or similar cases, the above-described content may be appropriately set, for example, in a range of 10% to 60% by mass. In addition, since the influence of the variation in the dissolution rate depending on the film thickness is considered to be quite small in a film having a thickness of 10 μm or more, in a case where a film having a thickness of 10 μm is not obtained, it can be considered that the same dissolution rate as that in a case where the film thickness is 10 μm is obtained even in a case where the measurement is performed by forming a film having a thickness of more than 10 μm.

In addition, the base material, the method of applying the solution to the base material, the drying method, the method of measuring the dissolution rate, and the like can be performed by the same method as the dissolution rate of the film obtained from the above-described resin composition, and the same applies to the preferred aspects thereof.

The dissolution rate of the film of the specific resin can be measured by a method described in Examples described later.

Specifically, for example, the measurement is performed by the following method.

A GBL (γ-butyrolactone) solution of the specific resin is prepared, the solution is applied onto a silicon wafer by a spin coating method, and heating is carried out at 110° C. for 5 minutes or 120° C. for 5 minutes to form a resin layer (film) having a thickness of 10 μm on the silicon wafer.

The silicon wafer on which the obtained resin layer was formed was immersed in cyclopentanone for 15 seconds, and then the wafer was rotated at 2,000 rpm for 10 seconds after the immersion. After that, the film thickness of the resin composition layer after the immersion was measured at 10 points on the coated surface with an ellipsometer (KT-22 manufactured by FOOTHILL), and the arithmetic mean value thereof is obtained. The dissolution rate (μm/sec) is calculated from 10 μm, which is the film thickness measured by the above-described measurement and the film thickness before immersion.

In addition, since the influence of the variation in the dissolution rate depending on the film thickness is considered to be quite small in a film having a thickness of 10 μm or more, in a case where a film having a thickness of 10 μm is not obtained, it can be considered that the same dissolution rate as that in a case where the film thickness is 10 μm is obtained even in a case where the measurement is performed by forming a film having a thickness of more than 10 μm.

In addition, in a case where the first resin composition or the second resin composition contains two or more kinds of the specific resins, a weighted average value of the above-described dissolution rates of the resins based on the content mass ratio is preferably 0.01 to 0.2 μm/sec, more preferably 0.05 to 0.20 μm/sec, and still more preferably 0.05 to 0.15 μm/sec.

In addition, an aspect in which the above-described dissolution rate is 0.01 to 0.2 μm/sec for all the specific resins contained in the first resin composition or the second resin composition is also one of the preferred aspects of the present invention.

The first specific resin and the second specific resin are preferably resins having a ring structure with 5 or more ring members in a side chain.

In the present invention, a main chain of the resin indicates the relatively longest bonding chain in the resin molecule. In addition, in a case where the ring structure is included in the main chain, an atom included as a ring member in the ring structure is an atom included in the main chain.

In the present invention, the side chain of the resin refers to a molecular chain bonded to the main chain, and the molecular chain may or may not have a repeating unit. That is, the molecular chain may or may not include a repeating structure. In addition, the molecular chain is preferably a molecular chain composed of 6 or more atoms, more preferably a molecular chain composed of 10 or more atoms, and still more preferably a molecular chain composed of 15 or more atoms. An upper limit of the number of atoms included in the molecular chain is not particularly limited, but is, for example, preferably 1,000 or less and more preferably 500 or less.

Here, it is preferable that the side chain in the first specific resin and the second specific resin is bonded to a carbon atom included in the main chain, and it is preferable that in a case where the side chain is represented by R, the side chain R is bonded to the carbon atom C of the main chain as C—R. That is, it is preferable that there is only one bond to the main chain in one side chain.

The ring structure with 5 or more ring members is preferably a ring structure with 5 to 20 ring members, and more preferably a ring structure with 5 to 12 ring members.

The ring structure with 5 or more ring members may be any of an aromatic ring or an aliphatic ring, and is preferably an aromatic ring or an aliphatic hydrocarbon ring and more preferably an aromatic ring.

The aromatic ring may be any of an aromatic hydrocarbon ring or a heteroaromatic ring, but is preferably an aromatic hydrocarbon ring or a heteroaromatic ring containing a nitrogen atom as a ring member.

The aromatic hydrocarbon ring is preferably an aromatic hydrocarbon ring having 6 to 20 carbon atoms, more preferably an aromatic hydrocarbon ring having 6 to 10 carbon atoms, and still more preferably a benzene ring.

Examples of the heteroaromatic ring include a furan ring, a benzofuran ring, a thiophene ring, a benzothiophene ring, a pyrrole ring, an imidazole ring, a triazole ring, a tetrazole ring, an oxazole ring, a pyridine ring, a pyridazine ring, a pyrazine ring, a triazine ring, an indole ring, an indazole ring, a benzimidazole ring, and a purine ring.

Examples of the aliphatic ring include an aliphatic hydrocarbon ring having 5 to 20 carbon atoms, a pyrrolidine ring, a pyrroline ring, a pyrazolidine ring, an imidazolidine ring, a tetrahydrofuran ring, a tetrahydrothiophene ring, a piperidine ring, a piperazine ring, a tetrahydropyran ring, a dioxane ring, and a morpholine ring.

Among these, as the ring structure with 5 or more ring members, a benzene ring, a cyclohexane ring, or an adamantane ring is preferable, and a benzene ring is more preferable.

In the ring structure with 5 or more ring members, a hydrogen atom that is bonded to the ring member by a single bond without a linking group being interposed therebetween may be substituted. Examples of the substituent include an alkyl group, an aryl group, a halogen atom, and a polymerizable group described later.

The content of the ring structure with 5 or more ring members in the first specific resin and the second specific resin is preferably 0.01 to 5.0 mmol/g, more preferably 0.1 to 4.0 mmol/g, and still more preferably 0.5 to 2.0 mmol/g with respect to 1 g of the first specific resin.

It is preferable that the first specific resin and the second specific resin include a structure represented by Formula (A-1).

The third specific resin includes a structure represented by Formula (A-1).

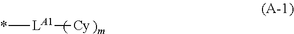

In Formula (A-1), L^{A1} represents a single bond or an (m+1)-valent linking group, Cy's each independently represent a ring structure with 5 or more ring members, which may have a substituent, m represents an integer of 1 or more, and * represents a bonding site to another structure.

In Formula (A-1), L^{A1} is preferably an (m+1)-valent linking group. A preferred aspect of L^{A1} is the same as a preferred aspect of L¹ in Formula (R-1) described later.

In Formula (A-1), a preferred aspect of Cy is the same as the preferred aspect of the ring structure with 5 or more ring members described above.

In addition, it is also preferable that Cy is directly bonded to a polymerizable group described later. In the present invention, the direct bonding of a certain structure A and another structure B means that the structure A and the structure B are bonded to each other without a linking group being interposed therebetween.

In Formula (A-1), * represents a bonding site to another structure, and it preferably represents a bonding site to an atom included in the main chain of the resin, and more preferably represents a bonding site to a carbon atom included in the main chain. The carbon atom is preferably a tertiary carbon atom or a quaternary carbon atom.

It is preferable that the structure represented by Formula (A-1) is not included in the main chain.

In addition, the structure represented by Formula (A-1) is also a structure represented by Formula (R-1) described later, which is one of the preferred aspects of the present invention.

The content of the structure represented by Formula (A-1) in the specific resin is preferably 0.01 to 5.0 mmol/g, more preferably 0.1 to 4.0 mmol/g, and still more preferably 0.5 to 2.0 mmol/g with respect to 1 g of the second specific resin.

The first specific resin and the second specific resin preferably have a polymerizable group.

The polymerizable group may be a cationically polymerizable group, but is preferably a radically polymerizable group.

Examples of the polymerizable group include an epoxy group, an oxetanyl group, an alkoxymethyl group, an acyloxymethyl group, a methylol group, a blocked isocyanate group, and a group containing an ethylenically unsaturated bond, but a group containing an ethylenically unsaturated bond is preferable.

The group having an ethylenically unsaturated bond is preferably a radically polymerizable group.

In addition, examples of the group containing an ethylenically unsaturated bond include a vinyl group, a vinyl ether group, an allyl group, an isoallyl group, a 2-methylallyl group, a (meth)acrylamide group, and a (meth)acryloyloxy group, and from the viewpoint of reducing the polarity and reducing the dielectric constant of the obtained cured substance, a vinyl group or a vinyl ether group is preferable. Here, it is also preferable that the vinyl group is directly bonded to the above-described ring structure with 5 or more ring members. Specifically, it is preferable that the above-described aromatic ring structure with 5 or more ring members and the above-described vinyl group are directly bonded to each other.

The polymerizable group value (the total molar amount of polymerizable groups with respect to 1 g of the specific resin) in the first specific resin and the second specific resin is preferably 0.1 to 10 mmol/g, more preferably 0.2 to 5 mmol/g, and still more preferably 0.5 to 1.5 mmol/g.

The specific resin preferably has a group obtained by removing two or more hydrogen atoms from a structure represented by Formula (C-1), and more preferably has a group obtained by removing two or more hydrogen atoms from a structure represented by Formula (C-2).

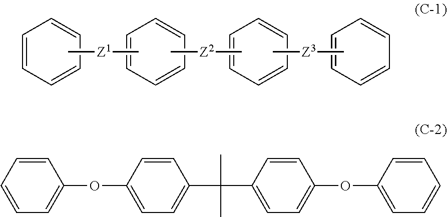

In Formula (C-1), Z¹ to Z³ are each independently a single bond or a divalent linking group, and the four benzene rings described in Formula (C-1) may each have a substituent.

Z¹ to Z³ are each preferably an aliphatic hydrocarbon group having 1 to 10 carbon atoms, which may be substituted with a fluorine atom, —O—, —C(═O)—, —S—, —S(═O)₂—, —NHC(═O)—, or a group consisting of a combination of two or more of these, more preferably an aliphatic hydrocarbon group having 1 to 10 carbon atoms, which may be substituted with a fluorine atom, —O—, —C(═O)—, or a group consisting of a combination of two or more of these, and still more preferably an aliphatic hydrocarbon group having 1 to 10 carbon atoms, which may be substituted with a fluorine atom, or —O—.

In particular, Z¹ and Z³ are preferably-O—.

In particular, Z² is preferably an aliphatic hydrocarbon group having 1 to 10 carbon atoms, which may be substituted with a fluorine atom.

Among these, an aspect in which Z¹ and Z³ are —O— and Z² is —C(CH₃)₂— is also one of the preferred aspects of the present invention.

The number of carbon atoms in the aliphatic hydrocarbon group having 1 to 10 carbon atoms, which may be substituted with a fluorine atom, is not particularly limited, but is preferably 1 to 6 and more preferably 1 to 4.

Specific examples of the aliphatic hydrocarbon group having 1 to 10 carbon atoms, which may be substituted with a fluorine atom, include —CH₂—, —C(CH₃)₂—, and —C(CF₃)₂—, and among these, —C(CH₃)₂— is preferable.

Examples of the substituent in the four benzene rings described in Formula (C-1) include a fluorine atom and a hydrocarbon group having 1 to 10 carbon atoms, in which a hydrogen atom may be substituted with a fluorine atom.

In addition, an aspect in which all four benzene rings described in Formula (C-1) are unsubstituted is also one of the preferred aspects of the present invention.

In addition, the specific resin preferably includes the structure represented by Formula (C-1) as X¹ or Y¹ in Formula (1-1) described later or R¹¹⁵ or R¹¹¹ in Formula (2). These aspects will be described later.

Specific examples of the structure represented by Formula (C-1) will be described below, but the present invention is not limited thereto.

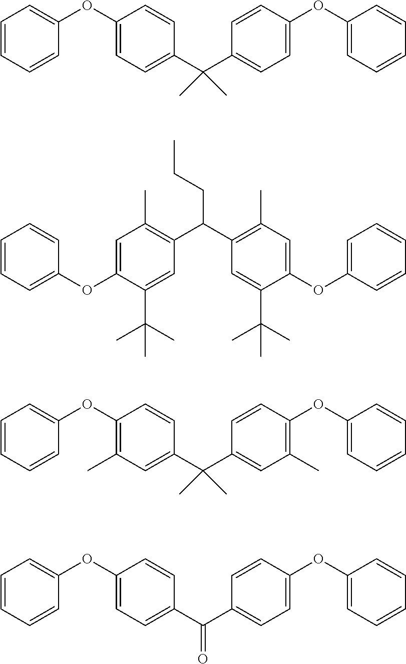

It is preferable that the first specific resin and the second specific resin include a repeating unit represented by Formula (1-1).

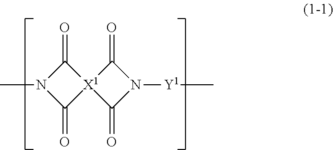

In Formula (1-1), X¹ is a tetravalent organic group, and Y¹ is an organic group including a group having an ethylenically unsaturated bond.

### —X¹—

It is preferable that X¹ includes a structure obtained by removing two or more hydrogen atoms from a structure represented by any one of Formulae (V-1) to (V-5).

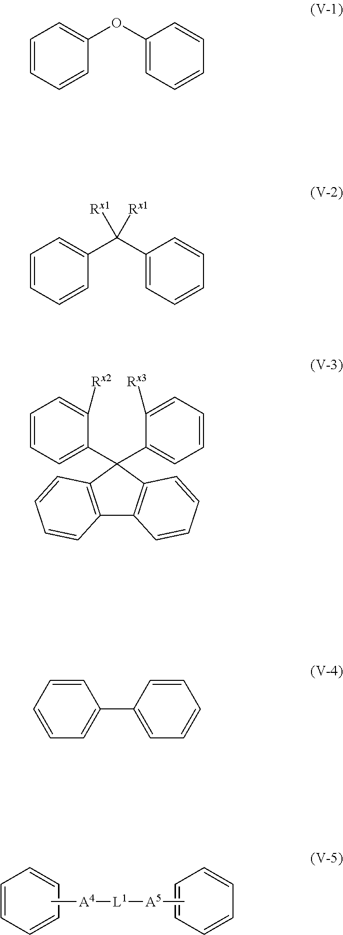

In Formula (V-2), R^{X1}'s each independently represent a hydrogen atom, an alkyl group, or a halogenated alkyl group.

In Formula (V-3), R^{X2} and R^{X3} each independently represent a hydrogen atom or a substituent, and R^{X2} and R^{X3} may be bonded to each other to form a ring structure.

In Formula (V-5), A⁴ and A⁵ are each independently —C(═O)—O— or —C(═O)NH—, L¹ is a divalent linking group, and the two benzene rings described in Formula (V-5) may each have a substituent.

In Formula (V-2), R^{X1}'s are each independently preferably an alkyl group or a halogenated alkyl group, more preferably an alkyl group having 1 to 4 carbon atoms or a halogenated alkyl group having 1 to 4 carbon atoms, and still more preferably a methyl group or a trifluoromethyl group. The halogenated alkyl group refers to a group in which at least one hydrogen atom of an alkyl group is substituted with a halogen atom. As the halogen atom, F or Cl is preferable, and F is more preferable.

In Formula (V-3), R^{X2} and R^{X3} are each independently preferably a hydrogen atom.

In a case where R^{X2} and R^{X3} are bonded to each other to form a ring structure, the structure formed by the bonding of R^{X2} and R^{X3} is preferably a single bond, —O—, or —C(R)₂—, more preferably —O— or —C(R)₂—, and still more preferably —O—. R represents a hydrogen atom or a monovalent organic group, preferably a hydrogen atom, an alkyl group, or an aryl group, and more preferably a hydrogen atom.

In Formula (V-5), an aspect in which one of A⁴ or A⁵ is —C(═O)—O— and the other is —C(═O)NH— is also one of the preferred aspects of the present invention.

Here, the orientation of —C(═O)—O— is not particularly limited, but it is preferable that the carbon atom in —C(═O)—O— is bonded to L¹ by a single bond without a linking group being interposed therebetween.

In addition, the orientation of —C(═O)—NH— is not particularly limited, but it is preferable that the carbon atom in —C(═O)—NH— is bonded to L¹ by a single bond without a linking group being interposed therebetween.

In Formula (V-5), L¹ is preferably a hydrocarbon group which may have a substituent, more preferably an aromatic hydrocarbon group, and still more preferably a phenylene group.

The hydrocarbon group in L¹ may have a substituent. Examples of the substituent include a fluorine atom and a hydrocarbon group having 1 to 10 carbon atoms, in which a hydrogen atom may be substituted with a fluorine atom.

In a case where X¹ is a group including a structure obtained by removing two or more hydrogen atoms from a structure represented by Formula (V-1), X¹ is preferably a group represented by Formula (V-1-1). In the following Formula, * represents a bonding site to four carbonyl groups to which X¹ in Formula (1-1) is bonded, and n1 represents an integer of 0 to 5, and it is also preferable that n1 is an integer of 1 to 5. In addition, the hydrogen atom in the following structure may be further substituted with a known substituent such as a hydroxy group or a hydrocarbon group. In addition, one or more hydrogen atoms may be substituted with the group represented by Formula (R-1).

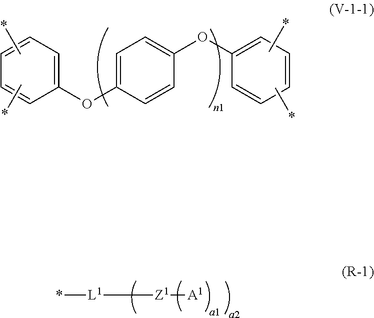

In Formula (R-1), L¹ represents an (a2+1)-valent linking group, Z¹ represents an aromatic group or a cyclic aliphatic group, A¹ represents a polymerizable group, a1 represents an integer of 0 or more and equal to or less than a maximum number of substituents of Z¹, a2 represents an integer of 1 or more, and * represents a bonding site to another structure.

L¹ is preferably a group represented by Formula (L-1).

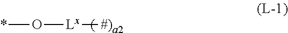

In Formula (L-1), Lx represents an (a2+1)-valent linking group, a2 represents an integer of 1 or more, * represents a bonding site to X¹ in Formula (1-1), and #represents a bonding site to Z¹ in Formula (R-1).

Lx is preferably an alkylene group, more preferably an alkylene group having 1 to 10 carbon atoms, still more preferably an alkylene group having 1 to 4 carbon atoms, and particularly preferably a methylene group.

The preferred aspect of a2 in Formula (L-1) is the same as the preferred aspect of a2 in Formula (R-1).

Z¹ in Formula (R-1) represents an aromatic group or a cyclic aliphatic group. The preferred aspect of these groups is the same as the preferred aspect of the ring structure with 5 or more ring members described above.

A¹ in Formula (R-1) preferably represents a group having an ethylenically unsaturated bond.

A preferred aspect of the group having an ethylenically unsaturated bond is the same as a preferred aspect of the group having an ethylenically unsaturated bond in Y¹ described later.

Among these, at least one of A¹'s in Formula (R-1) is preferably a vinyl group, a (meth)acryloxy group, a vinyl ether group, an allyl group, an epoxy group, or a group including these groups, and more preferably a vinyl group or a vinyl ether group.

In Formula (R-1), a1 is preferably an integer of 0 to 2, and more preferably 0 or 1. In addition, an aspect in which a1 is 1 or 2 is also one of the preferred aspects of the present invention.

In Formula (R-1), a2 represents an integer of 1 or more, and is preferably 1 or 2 and more preferably 1.

In addition, the number of ester bonds included in Formula (R-1) is preferably 1 or 0.

In a case where X¹ is a group including a structure obtained by removing two or more hydrogen atoms from a structure represented by Formula (V-2), X¹ is preferably a group represented by Formula (V-2-1) or Formula (V-2-2), and from the viewpoint of reducing the amine value in the resin, X¹ is preferably a group represented by Formula (V-2-2). In the present specification, a bond that intersects with a side of a ring structure means that any hydrogen atom in the ring structure is substituted. In the following Formula, L^{X1} represents a single bond or —O—, and * represents a bonding site to four carbonyl groups to which X¹ in Formula (1-1) is bonded. In addition, the definition and preferred aspect of R^{X1} are as described above. In addition, the hydrogen atom in these structures may be further substituted with a known substituent such as a hydroxy group or a hydrocarbon group. In addition, one or more hydrogen atoms may be substituted with the group represented by Formula (R-1).

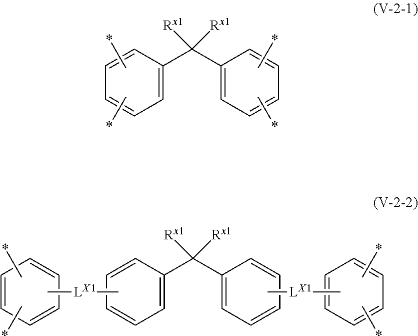

In a case where X¹ is a group including a structure obtained by removing two or more hydrogen atoms from a structure represented by Formula (V-3), X¹ is preferably a group represented by Formula (V-3-1) or Formula (V-3-2), and from the viewpoint of reducing the dielectric constant, X¹ is preferably a group represented by Formula (V-3-2). In the following Formula, * represents a bonding site to four carbonyl groups to which X¹ in Formula (1-1) is bonded. In addition, the definitions and preferred aspects of R^{X2} and R^{X3} are as described above. In addition, the hydrogen atom in these structures may be further substituted with a known substituent such as a hydroxy group or a hydrocarbon group. In addition, one or more hydrogen atoms may be substituted with the group represented by Formula (R-1).

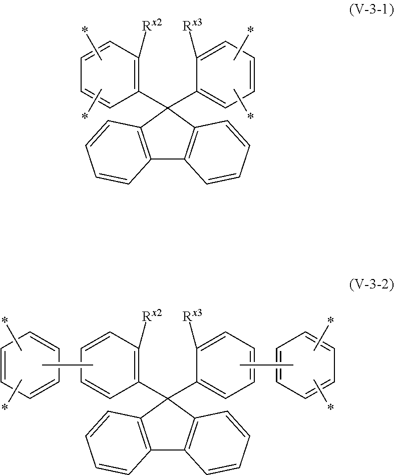

In a case where X¹ is a group including a structure obtained by removing two or more hydrogen atoms from a structure represented by Formula (V-4), X¹ is preferably a group represented by Formula (V-4-1). In the following Formula, * represents a bonding site to four carbonyl groups to which X¹ in Formula (1-1) is bonded, and n1 represents an integer of 0 to 5. In addition, the hydrogen atom in the following structure may be further substituted with a known substituent such as a hydroxy group or a hydrocarbon group. In addition, one or more hydrogen atoms may be substituted with the group represented by Formula (R-1).

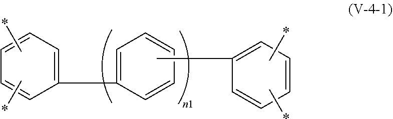

In a case where X¹ is a group including a structure obtained by removing two or more hydrogen atoms from a structure represented by Formula (V-5), X¹ is preferably a group represented by Formula (V-5-1) and more preferably a group represented by Formula (V-5-2). In addition, the hydrogen atom in the following structure may be further substituted with a known substituent such as a hydroxy group or a hydrocarbon group. In addition, one or more hydrogen atoms may be substituted with the group represented by Formula (R-1).

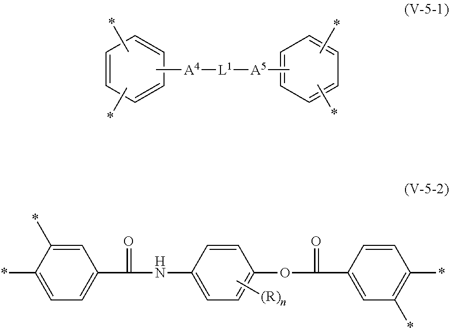

In Formula (V-5-1), A⁴ and A⁵ are each independently —C(═O)—O— or —C(═O)NH—, L¹ is a divalent linking group, * represents a bonding site to a carbonyl group in Formula (1-1), and the two benzene rings described in Formula (V-5-1) may each have a substituent.

In Formula (V-5-1), the preferred aspects of the substituents in the benzene ring A⁴ and A⁵ are the same as the preferred aspects of the substituents in the benzene ring A⁴ and A⁵ in Formula (V-5) described above.

In Formula (V-5-2), R's each independently represent a substituent, n is an integer of 0 to 4, and * represents a bonding site to the carbonyl group in Formula (1-1).

R's are each independently preferably a fluorine atom or a hydrocarbon group having 1 to 10 carbon atoms, in which a hydrogen atom may be substituted with a fluorine atom, and more preferably a hydrocarbon group having 1 to 10 carbon atoms, in which a hydrogen atom may be substituted with a fluorine atom.

n is preferably an integer of 0 to 2. In addition, an aspect in which n is 2 is also one of the preferred aspects of the present invention.

In addition, in Formula (1-1), it is also preferable that X¹ is a group represented by Formula (7). In the above-described aspect, X¹ is more preferably a group represented by Formula (7-2).

Formula (7) is a group obtained by removing four hydrogen atoms from the structure represented by Formula (C-1) described above, and Formula (7-2) is a group obtained by removing four hydrogen atoms from the structure represented by Formula (C-2) described above.

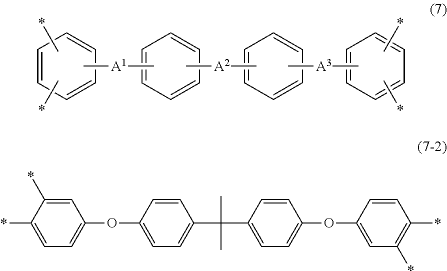

In Formula (7), A¹ to A³ each independently represent a single bond or a divalent linking group, * represents a bonding site to a carbonyl group in Formula (1-1), and the four benzene rings described in Formula (7) may each have a substituent.

In the present specification, a bond that intersects with a side of a ring structure means that any hydrogen atom in the ring structure is substituted.

In Formula (7-2), * represents a bonding site to the carbonyl group in Formula (1-1).

In Formula (7), the preferred aspects of A¹ to A³ and the substituent in the benzene ring are the same as the preferred aspects of Z¹ to Z³ in Formula (C-1) and the substituent in the benzene ring.

In addition, X¹ may be a group obtained by removing m hydrogen atoms from a group represented by R¹³² in Formula (4) described later.

In addition, it is preferable that X¹ does not contain an imide structure in the structure. In the present invention, the imide structure is a structure represented by —C(═O)N(—*)C(═O)—. * represents a bonding site to another structure.

In addition, it is also preferable that X¹ does not contain a urethane bond, a urea bond, and an amide bond in the structure.

In the present invention, the urethane bond is a bond represented by *—O—C(—O)—NR^{N}—*, where R^{N} represents a hydrogen atom or a monovalent organic group, and *'s each represent a bonding site to a carbon atom. R^{N} is preferably a hydrogen atom, an alkyl group, or an aryl group, and more preferably a hydrogen atom.

In the present invention, the urea bond is a bond represented by *—NR^{N}—C(═O)—NR^{N}—*, where R^{N}'s each independently represent a hydrogen atom or a monovalent organic group, and *'s each represent a bonding site to a carbon atom. The preferred aspect of R^{N} is as described above.

In the present invention, the amide bond is a bond represented by *—NR^{N}—C(═O)—*, where R^{N} represents a hydrogen atom or a monovalent organic group, and *'s each represent a bonding site to a carbon atom. The preferred aspect of R^{N} is as described above.

Furthermore, it is also preferable that X¹ does not contain an ester bond in the structure.

In the present invention, the ester bond is a bond represented by *—O—C(═O)—*.

Among these, it is preferable that X¹ does not contain an imide structure, a urethane bond, a urea bond, and an amide bond, and it is preferable that X¹ does not contain an imide structure, a urethane bond, a urea bond, an amide bond, and an ester bond.

### —Y¹—

In Formula (1-1), it is preferable that Y¹ includes a ring structure with 5 or more ring members.

The preferred aspect of the ring structure with 5 or more ring members is as described above.

In Formula (1-1), Y¹ is a group having an ethylenically unsaturated bond.

The preferred aspect of the group having an ethylenically unsaturated bond is as described above.

In particular, the group having an ethylenically unsaturated bond in Y¹ is preferably directly bonded to an aromatic group, and Y¹ more preferably includes a vinylphenyl group.

Y¹ in Formula (1-1) is preferably a group represented by Formula (Y-1).

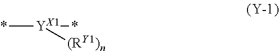

In Formula (Y-1), Y^{X1} represents an (n+2)-valent organic group, R^{Y1}'s each independently represent a structure represented by Formula (R-1) described above, where A¹ in Formula (R-1) is a group having an ethylenically unsaturated bond, and n represents an integer of 1 or more.

In Formula (Y-1), Y^{X1} is preferably a group including a structure obtained by removing 2+n pieces of hydrogen atoms from the structure represented by any of Formula (V-1) to Formula (V-4) described above.

In a case where Y^{X1} is a group including a structure obtained by removing two or more hydrogen atoms from a structure represented by Formula (V-1), Y^{X1} is preferably a group obtained by removing n hydrogen atoms from a group represented by Formula (V-1-2). In the following formula, * represents two bonding sites of Y¹ in Formula (1-1), and n1 represents an integer of 1 to 5. n hydrogen atoms in the following structure are substituted with R^{Y1} in Formula (Y-1). n has the same meaning as n in Formula (1-1). In addition, the hydrogen atom in the following structure may be further substituted with a known substituent such as a hydroxy group or a hydrocarbon group.

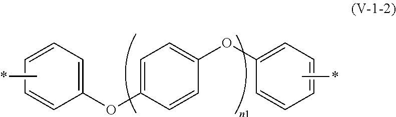

In a case where Y^{X1} is a group including a structure obtained by removing two or more hydrogen atoms from a structure represented by Formula (V-2), Y¹ is preferably a group represented by Formula (V-2-3) or Formula (V-2-4), and from the viewpoint of reducing the dielectric constant or the like, Y¹ is preferably a group represented by Formula (V-2-4). In the following formula, L^{X1} represents a single bond or —O—, and * represents two bonding sites of Y¹ in Formula (1-1). In addition, the preferred aspect of R^{X1} is as described above. n hydrogen atoms in the following structure are substituted with R^{Y1} in Formula (Y-1). n has the same meaning as n in Formula (Y-1). In addition, the hydrogen atom in these structures may be further substituted with a known substituent such as a hydroxy group or a hydrocarbon group.

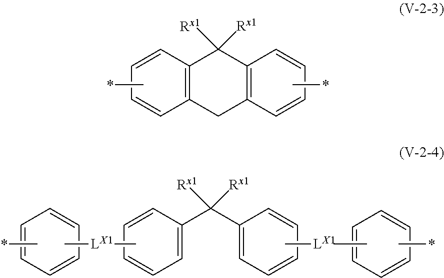

In a case where Y¹ is a group including a structure obtained by removing two or more hydrogen atoms from a structure represented by Formula (V-3), Y¹ is preferably a group represented by Formula (V-3-3) or Formula (V-3-4), and from the viewpoint of reducing the dielectric constant, Y¹ is preferably a group represented by Formula (V-3-3). In the following formulae, * represents two bonding sites of Y¹ in Formula (1-1). In addition, the preferred aspects of R^{X2} and R^{X3} are as described above. n hydrogen atoms in the following structure are substituted with R^{Y1} in Formula (Y-1). n has the same meaning as n in Formula (1-1). In addition, the hydrogen atom in these structures may be further substituted with a known substituent such as a hydroxy group or a hydrocarbon group.

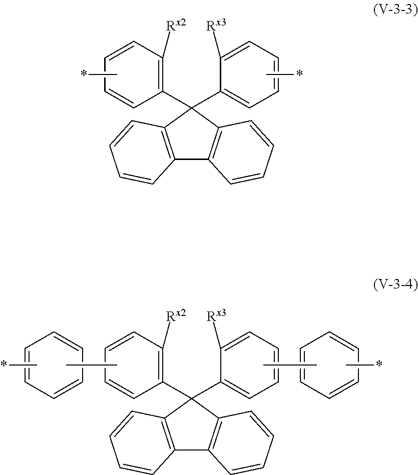

In a case where Y¹ is a group including a structure obtained by removing two or more hydrogen atoms from a structure represented by Formula (V-4), Y¹ is preferably a group represented by Formula (V-4-2). In the following formula, * represents two bonding sites of Y¹ in Formula (1-1), and n1 represents an integer of 0 to 5. In addition, an aspect in which n1 is 0 is also one of the preferred aspects of the present invention. n hydrogen atoms in the following structure are substituted with R^{Y1} in Formula (Y-1). n has the same meaning as n in Formula (1-1). In addition, the hydrogen atom in the following structure may be further substituted with a known substituent such as a hydroxy group or a hydrocarbon group.

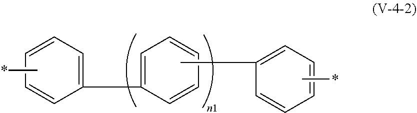

In Formula (Y-1), R^{Y1}'s each independently represent the structure represented by Formula (R-1) described above, and the same applies to the preferred aspect thereof. In Formula (R-1), the description of “* represents a bonding site to X¹ in Formula (1-1)” shall be read as “* represents a bonding site to Y^{Y1} in Formula (Y-1)”.

In addition, R¹¹¹ is also preferably a group represented by Formula (71). In the above-described aspect, R¹¹¹ is more preferably a group represented by Formula (72).

Formula (71) is a group obtained by removing two hydrogen atoms from the structure represented by Formula (C-1) described above, and Formula (72) is a group obtained by removing two hydrogen atoms from the structure represented by Formula (C-2) described above. n hydrogen atoms in the following structure are substituted with R^{Y1} in Formula (Y-1). n has the same meaning as n in Formula (Y-1).

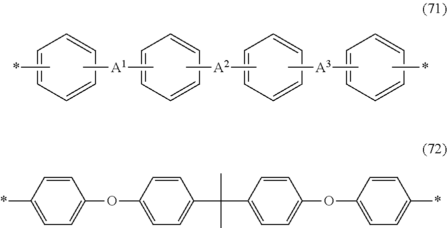

In Formula (71), A¹ to A³ each independently represent a single bond or a divalent linking group, * represents a bonding site to a nitrogen atom in Formula (2), and the four benzene rings described in Formula (71) may each have a substituent.

In Formula (72), * represents a bonding site to the nitrogen atom in Formula (1-1).

In Formula (71), the preferred aspects of A¹ to A³ and the substituent in the benzene ring are the same as the preferred aspects of Z¹ to Z³ in Formula (C-1) and the substituent in the benzene ring.

In Formula (Y-1), n is preferably 1 or 2, and more preferably 2.

In addition, it is also preferable that Y¹ in Formula (1-1) includes a structure represented by Formula (B-1) or Formula (B-2), and it is more preferable that Y¹ in Formula (1-1) is a structure represented by Formula (B-1) or Formula (B-2).

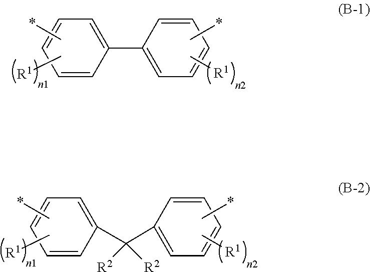

In Formula (B-1), R¹'s each independently represent an organic group including a group having an ethylenically unsaturated bond, n1 represents an integer of 0 to 3, n2 represents an integer of 0 to 3, n1+n2 represents an integer of 1 to 6, and * represents a bonding site to another structure.

In Formula (B-2), R¹'s each independently represent an organic group including a group having an ethylenically unsaturated bond, n1 represents an integer of 0 to 3, n2 represents an integer of 0 to 3, n1+n2 represents an integer of 1 to 6, R²'s each independently represent an alkyl group or a fluoroalkyl group, and * represents a bonding site to another structure.

In Formula (B-1), the preferred aspect of the group having an ethylenically unsaturated bond in R¹ is the same as the preferred aspect of the group having an ethylenically unsaturated bond in Y¹ in Formula (1-1) described above.

In addition, R¹ is preferably a group represented by Formula (R-1) described above, in which Cy is a group directly bonded to a group having an ethylenically unsaturated bond, in which Cy is a polymerizable group. In Formula (R-1), the description of “* represents a bonding site to X¹ in Formula (1-1)” shall be read as “* represents a bonding site to a benzene ring in Formula (B-1)”.

In Formula (B-1), n1 and n2 each independently preferably represent 1 or 2, and more preferably both represent 1.

In Formula (B-2), the preferred aspect of R¹ is the same as the preferred aspect of R¹ in Formula (B-1).

In Formula (B-2), R² is preferably an alkyl group having 1 to 10 carbon atoms or a fluoroalkyl group having 1 to 10 carbon atoms, preferably an alkyl group having 1 to 4 carbon atoms or a fluoroalkyl group having 1 to 4 carbon atoms, more preferably a methyl group, an ethyl group, a trifluoromethyl group, or a pentafluoroethyl group, and particularly preferably a methyl group or a trifluoromethyl group.

In addition, it is preferable that Y¹ does not contain an imide structure in the structure.

In addition, it is preferable that Y¹ does not contain a urethane bond, a urea bond, and an amide bond in the structure.

Furthermore, it is preferable that Y¹ does not contain an ester bond in the structure.

Among these, it is preferable that Y¹ does not contain an imide structure, a urethane bond, a urea bond, and an amide bond, and it is preferable that Y¹ does not contain an imide structure, a urethane bond, a urea bond, an amide bond, and an ester bond.

Among these, it is preferable that X¹ in Formula (1-1) includes a structure obtained by removing two or more hydrogen atoms from a structure represented by any of Formula (V-1) to Formula (V-5), and Y¹ includes a structure obtained by removing two or more hydrogen atoms from a structure represented by any of Formula (V-1) to Formula (V-4).

It is preferable that the specific resin further includes a repeating unit represented by Formula (1-2).

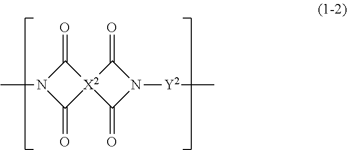

In Formula (1-2), X² is a tetravalent organic group, Y² is a divalent organic group having no ethylenically unsaturated bond, and at least one of X² or Y² includes a group obtained by removing two or more hydrogen atoms from a structure represented by Formula (C-1).

In Formula (1-2), a preferred aspect of X² is the same as the preferred aspect of X¹ in Formula (1-1) described above.

In Formula (1-2), Y² is more preferably a group represented by Formula (71) described above, and it is still more preferably a group represented by Formula (72) described above.

Preferred aspects of Formula (C-1), Formula (71), and Formula (72) in Y² are each as described above.

The third specific resin includes a repeating unit represented by Formula (1-3).

It is preferable that the first specific resin or the second specific resin includes a repeating unit represented by Formula (1-3) as the repeating unit represented by Formula (1-1).

In Formula (1-3), X³ is a tetravalent organic group, Y³ is a divalent organic group including a vinylphenyl group, and Y³ includes a structure represented by Formula (B-1) or Formula (B-2).

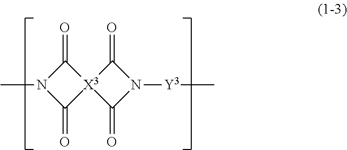

In Formula (1-3), X³ is a tetravalent organic group, Y³ is a divalent organic group including a vinylphenyl group, and Y³ includes a structure represented by Formula (B-1) or Formula (B-2).

In Formula (1-3), a preferred aspect of X³ is the same as the preferred aspect of X¹ in Formula (1-1) described above.

In Formula (1-3), the structures represented by Formula (B-1) and Formula (B-2) in Y³ are the same as the structures represented by Formula (B-1) and Formula (B-2) in Y¹ of Formula (1-1) described above, and the preferred aspects thereof are also the same.

In Formula (1-3), it is more preferable that Y³ represents a structure represented by Formula (B-1) or Formula (B-2).

Here, it is preferable that Y³ is a structure including all of the structure represented by Formula (B-1) or (B-2), the vinylphenyl group, and the structure represented by Formula (A-1) described above.

Specifically, Y³ is preferably a structure represented by Formula (B-3) or (B-4).

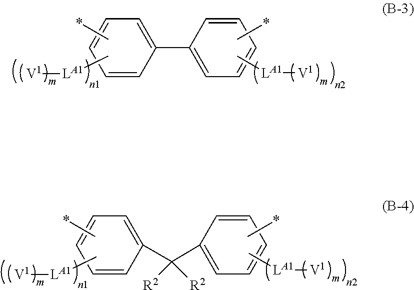

In Formula (B-3), LAI's each independently represent a single bond or an (m+1)-valent linking group, V¹ represents a vinylphenyl group, m represents an integer of 1 or more, n1 represents an integer of 0 to 3, n2 represents an integer of 0 to 3, n1+n2 represents an integer of 1 to 6, and * represents a bonding site to another structure.

In Formula (B-4), LAI's each independently represent a single bond or an (m+1)-valent linking group, V¹ represents a vinylphenyl group, m represents an integer of 1 or more, n1 represents an integer of 0 to 3, n2 represents an integer of 0 to 3, n1+n2 represents an integer of 1 to 6, R²'s each independently represent an alkyl group or a fluoroalkyl group, and * represents a bonding site to another structure.

In Formula (B-3) and Formula (B-4), L^{A1} corresponds to L^{A1} in Formula (A-1) described above, and corresponds to a structure in a case where the vinylphenyl group in V¹ is a benzene ring in which Cy in Formula (A-1) described above is substituted with a vinyl group.

In Formula (B-3), preferred aspects of L^{A1} and m are the same as the preferred aspects of L^{A1} and m in Formula (A-1) described above.

In Formula (B-3), preferred aspects of n1 and n2 are the same as the preferred aspects of n1 and n2 in Formula (B-1) described above.

In Formula (B-4), preferred aspects of L^{A1} and m are the same as the preferred aspects of L^{A1} and m in Formula (A-1) described above.

In Formula (B-4), preferred aspects of R², n1, and n2 are the same as the preferred aspects of R², n1, and n2 in Formula (B-2) described above.

It is also preferable that the first specific resin and the second specific resin include a repeating unit represented by Formula (2-1).

The third specific resin may further include a repeating unit represented by Formula (2-1).

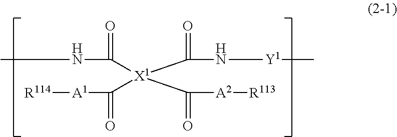

In Formula (2-1), A¹ and A² each independently represent an oxygen atom or —NR^{z}—, X¹ represents an organic group having 4 or more carbon atoms, Y¹ represents an organic group having 4 or more carbon atoms, R¹¹³ and R¹¹⁴ each independently represent a hydrogen atom or a monovalent organic group, and R^{z} represents a hydrogen atom or a monovalent organic group.

Preferred aspects of X¹ and Y¹ in Formula (2-1) are the same as the preferred aspects of X¹ and Y¹ in Formula (1-1) described above.

A¹ and A² in Formula (2-1) each independently represent an oxygen atom or —NR^{z}—, and an oxygen atom is preferable.

R^{Z} represents a hydrogen atom or a monovalent organic group, and a hydrogen atom is preferable.

R¹¹³ and R¹¹⁴ in Formula (2-1) each independently represent a hydrogen atom or a monovalent organic group. The monovalent organic group preferably includes a linear or branched alkyl group, a cyclic alkyl group, an aromatic group, or a polyalkyleneoxy group. In addition, at least one of R¹¹³ or R¹¹⁴ preferably contains a polymerizable group, and more preferably both of them contain a polymerizable group. It is also preferable that at least one of R¹¹³ or R¹¹⁴ contains two or more polymerizable groups. The polymerizable group is preferably a group capable of undergoing a crosslinking reaction under the action of heat, a radical, or the like, where the group is a radically polymerizable group. Specific examples of the polymerizable group include a group having an ethylenically unsaturated bond, an alkoxymethyl group, a hydroxymethyl group, an acyloxymethyl group, an epoxy group, an oxetanyl group, a benzoxazolyl group, a blocked isocyanate group, and an amino group. The radically polymerizable group contained in the second specific resin and the third specific resin is preferably a group having an ethylenically unsaturated bond.

Examples of the group having an ethylenically unsaturated bond include a vinyl group, an allyl group, an isoallyl group, a 2-methylallyl group, a group (for example, a vinylphenyl group) having an aromatic ring that is directly bonded to a vinyl group, a (meth)acrylamide group, a (meth)acryloyloxy group, and a group represented by Formula (III), where a group represented by Formula (III) is preferable.

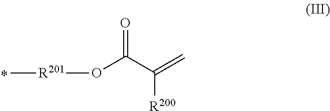

In Formula (III), R²⁰⁰ represents a hydrogen atom, a methyl group, an ethyl group, or a methylol group, where a hydrogen atom or a methyl group is preferable.

In Formula (III), * represents a bonding site to another structure.

In Formula (III), R²⁰¹ represents an alkylene group having 2 to 12 carbon atoms, —CH₂CH(OH)CH₂—, a cycloalkylene group, or a polyalkyleneoxy group.

Suitable examples of R²⁰¹ include an alkylene group such as an ethylene group, a propylene group, a trimethylene group, a tetramethylene group, a pentamethylene group, a hexamethylene group, an octamethylene group, or a dodecamethylene group, a 1,2-butanediyl group, a 1,3-butanediyl group, —CH₂CH(OH)CH₂—, and a polyalkyleneoxy group, where an alkylene group such as an ethylene group or a propylene group, —CH₂CH(OH)CH₂—, or a polyalkyleneoxy group is more preferable, and an alkylene group such as an ethylene group or a propylene group, or a polyalkyleneoxy group is still more preferable.

In the present invention, the polyalkyleneoxy group refers to a group to which two or more alkyleneoxy groups are directly bonded. The alkylene group in the plurality of alkyleneoxy groups contained in the polyalkyleneoxy group may be the same or different from each other.

In a case where the polyalkyleneoxy group contains a plurality of kinds of alkyleneoxy groups having different alkylene groups, the sequence of the alkyleneoxy groups in the polyalkyleneoxy group may be a randomly arranged sequence, may be a sequence arranged to have a block, or may be a sequence arranged to have an alternating pattern or the like.

The number of carbon atoms of the alkylene group (including the number of carbon atoms of the substituent in a case where the alkylene group has a substituent) is preferably 2 or more, more preferably 2 to 10, still more preferably 2 to 6, even more preferably 2 to 5, even still more preferably 2 to 4, even further still more preferably 2 or 3, and particularly preferably 2.

In addition, the alkylene group may have a substituent. Examples of the preferred substituent include an alkyl group, an aryl group, and a halogen atom.

In addition, the number of alkyleneoxy groups contained in the polyalkyleneoxy group (the number of repetitions of the polyalkyleneoxy group) is preferably 2 to 20, more preferably 2 to 10, and still more preferably 2 to 6.

The polyalkyleneoxy group is preferably a polyethyleneoxy group, a polypropyleneoxy group, a polytrimethyleneoxy group, a polytetramethyleneoxy group, or a group obtained by bonding a plurality of ethyleneoxy groups with a plurality of propyleneoxy groups, more preferably a polyethyleneoxy group or a polypropyleneoxy group, and still more preferably a polyethyleneoxy group, from the viewpoint of solubility in a solvent and solvent resistance. In the group obtained by bonding a plurality of ethyleneoxy groups with a plurality of propyleneoxy groups, the ethyleneoxy groups and the propyleneoxy groups may be randomly arranged, may be arranged by forming a block, or may be arranged in an alternately patterned manner or the like. The preferred aspect of the number of repetitions of the ethyleneoxy group and the like in these groups is as described above.

In Formula (2-1), in a case where R¹¹³ is a hydrogen atom or in a case where R¹¹⁴ is a hydrogen atom, the second specific resin or the third specific resin may form a conjugate salt together with a tertiary amine compound having an ethylenically unsaturated bond. Examples of the tertiary amine compound having such an ethylenically unsaturated bond include N,N-dimethylaminopropyl methacrylate.

In Formula (2-1), at least one of R¹¹³ or R¹¹⁴ may be a polarity converting group such as an acid-decomposable group. The acid-decomposable group is not particularly limited as long as it decomposes by the action of the acid to generate an alkali-soluble group such as a phenolic hydroxy group or a carboxy group; however, it is preferably an acetal group, a ketal group, a silyl group, or a silyl ether group, a tertiary alkyl ester group, or the like, and from the viewpoint of exposure sensitivity, it is more preferably an acetal group or a ketal group.

Specific examples of the acid-decomposable group include a tert-butoxycarbonyl group, an isopropoxycarbonyl group, a tetrahydropyranyl group, a tetrahydrofuranyl group, an ethoxyethyl group, a methoxyethyl group, an ethoxymethyl group, a trimethylsilyl group, a tert-butoxycarbonylmethyl group, and a trimethylsilyl ether group. From the viewpoint of exposure sensitivity, an ethoxyethyl group or a tetrahydrofuranyl group is preferable.

The first specific resin and the second specific resin may include a repeating unit represented by Formula (2).

The repeating unit corresponding to the repeating unit represented by Formula (2-1) does not correspond to the repeating unit represented by Formula (2).

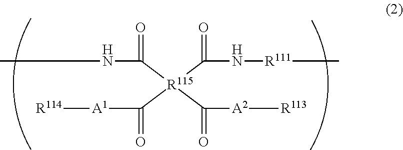

In Formula (2), A¹ and A² each independently represent an oxygen atom or —NR^{z}—, R¹¹¹ represents a divalent organic group which does not contain a group having an ethylenically unsaturated bond, R¹¹⁵ represents a tetravalent organic group, R¹¹³ and R¹¹⁴ each independently represent a hydrogen atom or a monovalent organic group, and R^{z} represents a hydrogen atom or a monovalent organic group.

In Formula (2), the preferred aspect of R¹¹⁵ is the same as the preferred aspect of X¹ in Formula (1-1) described above.

In Formula (2), a preferred aspect of R¹¹¹ is the same as the preferred aspect of X¹ in Formula (1-1) described above, except that the group having an ethylenically unsaturated bond is not included. Specifically, the structure is preferably a structure represented by any of Formulae (V-1) to (V-4) and (71) described above, in which a bonding site with a group having an ethylenically unsaturated bond is substituted with a hydrogen atom. Preferred aspects of these formulas are as described above.

Preferred aspects of A¹, A², R¹¹³, and R¹¹⁴ in Formula (2) are the same as the preferred aspects of A¹, A², R¹¹³, and R¹¹⁴ in Formula (2-1) described above.

In a case where the second specific resin or the third specific resin is a polyimide, the content of the repeating unit represented by Formula (1-1) is preferably 30% by mass or more, preferably 40% by mass or more, still more preferably 50% by mass or more, and particularly preferably 80% by mass or more with respect to the total mass of the first specific resin or the second specific resin. The upper limit of the content is not particularly limited, and may be 100% by mass.

In addition, the second specific resin or the third specific resin may contain two or more kinds of repeating units represented by Formula (1-1) having different structures. In that case, it is preferable that the total amount is within the above-described range.

The content of the repeating unit represented by Formula (1-3) with respect to the total mass of the third specific resin is preferably 10% by mass or more, more preferably 20% by mass or more, and still more preferably 30% by mass or more. The upper limit of the content is not particularly limited, and may be 100% by mass.

In addition, the third specific resin may contain two or more kinds of repeating units represented by Formula (1-3) having different structures. In that case, it is preferable that the total amount is within the above-described range.

In a case where the specific resin is a polyimide, the content of the repeating unit represented by Formula (1-2) with respect to the total mass of the specific resin is preferably 0% to 90% by mass, more preferably 10% to 80% by mass, still more preferably 20% to 70% by mass, and particularly preferably 30% to 60% by mass or more.

In addition, the specific resin may contain two or more kinds of repeating units represented by Formula (1-2) having different structures. In that case, it is preferable that the total amount is within the above-described range.

The content of the repeating unit represented by Formula (1-3) with respect to the total mass of the third specific resin is preferably 10% by mass or more, more preferably 20% by mass or more, and still more preferably 30% by mass or more. The upper limit of the content is not particularly limited, and may be 100% by mass.

In addition, the third specific resin may contain two or more kinds of repeating units represented by Formula (1-3) having different structures. In that case, it is preferable that the total amount is within the above-described range.

In a case where the first specific resin or the second specific resin is a polyimide, the total content of the repeating unit represented by Formula (1-1) and the repeating unit represented by Formula (1-2) with respect to the total mass of the second specific resin and the third specific resin is preferably 50% by mass or more, more preferably 60% by mass or more, still more preferably 70% by mass or more, particularly preferably 80% by mass or more, even more preferably 90% by mass or more, and most preferably 99% by mass or more. The upper limit of the content is not particularly limited, and may be 100% by mass.

The total content of the repeating unit represented by Formula (1-3) and the repeating unit represented by Formula (1-2) with respect to the total mass of the third specific resin is preferably 50% by mass or more, more preferably 60% by mass or more, still more preferably 70% by mass or more, particularly preferably 80% by mass or more, even more preferably 90% by mass or more, and most preferably 99% by mass or more. The upper limit of the content is not particularly limited, and may be 100% by mass.

In a case where the first specific resin or the second specific resin is a polyimide precursor, the content of the repeating unit represented by Formula (2-1) is preferably 30% by mass or more, more preferably 50% by mass or more, still more preferably 70% by mass or more, and particularly preferably 80% by mass or more with respect to the total mass of the first specific resin or the second specific resin. The upper limit of the content is not particularly limited, and may be 100% by mass.

In addition, the first specific resin or the second specific resin may contain two or more kinds of repeating units represented by Formula (2-1) having different structures. In that case, it is preferable that the total amount is within the above-described range.

In a case where the first specific resin or the second specific resin is a polyimide precursor, the total content of the repeating unit represented by Formula (2-1) and the repeating unit represented by Formula (2) is preferably 50% by mass or more, more preferably 70% by mass or more, still more preferably 80% by mass or more, and particularly preferably 90% by mass or more with respect to the total mass of the first specific resin or the second specific resin. The upper limit of the content is not particularly limited, and may be 100% by mass.

In addition, in a case where the first specific resin or the second specific resin includes a repeating unit represented by Formula (2), the first specific resin or the second specific resin may include two or more kinds of repeating units represented by Formula (2) having different structures. In that case, it is preferable that the total amount is within the above-described range.

A value of the molar amount of oxygen atoms/weight-average molecular weight in the specific resin (particularly, the specific resin which is a polyimide) is preferably 9.7 mmol/g or less.

The lower limit of the value of the molar amount of the oxygen atom/weight-average molecular weight is preferably 7.0 mmol/g or more and more preferably 7.5 mmol/g or more.

The upper limit of the value of the molar amount of the oxygen atom/the weight-average molecular weight is preferably 9.2 mmol/g or less and more preferably 8.8 mmol/g or less.

It is considered that since the value of the molar amount of the oxygen atom/weight-average molecular weight value is 9.7 mmol/g or less, the polarity of the resin and the free mobility of the molecule are reduced, and the dissolution rate of the film consisting of the resin itself and the resin composition in cyclopentanone is reduced, the swelling of the image area is suppressed, and the occurrence of the opening defect is suppressed.

The weight-average molecular weight (Mw) of the specific resin which is a polyimide is preferably 3,000 to 100,000, more preferably 5,000 to 50,000, still more preferably 8,000 to 40,000, even more preferably 8,000 or more and less than 30,000, particularly preferably 8,000 to 26,000, and most preferably 10,000 to 25,000.

In a case where the weight-average molecular weight is set to 3,000 or more, the break resistance of the cured substance can be improved. In order to obtain an organic film having excellent mechanical properties (for example, breaking elongation), the weight-average molecular weight is particularly preferably 8,000 or more.

In addition, by setting the weight-average molecular weight to 3,000 or more, the peeling of the resin from the base material is suppressed, and the reliability of the cured substance (the adhesiveness to the base material in a case where the cured substance is further heated) can be improved. In order to obtain a cured substance having excellent reliability, the weight-average molecular weight is particularly preferably 8,000 or more.

Furthermore, in a case where the weight-average molecular weight is set to 100,000 or less, the resolution of the pattern in a case of forming the pattern of the cured substance can be improved. In order to obtain a cured substance having excellent resolution, the weight-average molecular weight is particularly preferably less than 30,000.

The number-average molecular weight (Mn) of the specific resin which is a polyimide is preferably 1,000 to 40,000, more preferably 2,000 to 30,000, and still more preferably 5,000 to 20,000.

The dispersity of the molecular weight of the specific resin which is a polyimide is preferably 1.5 or more, more preferably 1.8 or more, and still more preferably 2.0 or more. The upper limit value of the dispersivity of the molecular weight of the polyimide is not particularly limited; however, it is, for example, preferably 7.0 or less, more preferably 6.5 or less, and still more preferably 6.0 or less.

In a case where the resin composition contains a plurality of kinds of polyimides as the specific resin, it is preferable that the weight-average molecular weight, the number-average molecular weight, and the dispersivity of at least one kind of polyimide are in the above ranges. It is also preferable that the weight-average molecular weight, the number-average molecular weight, and the dispersity, calculated by using the plurality of kinds of polyimides as one resin, are within the above ranges.

In a case where the first specific resin is a polyimide precursor or the second specific resin is a polyimide precursor, the weight-average molecular weight (Mw) thereof is preferably 5,000 to 100,000, more preferably 6,000 to 50,000, still more preferably 7,000 to 40,000, even more preferably 8,000 or more and less than 30,000, particularly preferably 8,000 to 26,000, and most preferably 10,000 to 25,000.

In a case where the first specific resin is a polyimide precursor or in a case where the second specific resin is a polyimide precursor, the number-average molecular weight (Mn) is preferably 2,000 to 40,000, more preferably 3,000 to 30,000, and still more preferably 4,000 to 20,000.

The dispersivity of the molecular weight of the polyimide precursor is preferably 1.5 or more, more preferably 1.8 or more, and still more preferably 2.0 or more. The upper limit value of the dispersivity of the molecular weight of the polyimide precursor is not particularly limited; however, it is, for example, preferably 7.0 or less, more preferably 6.5 or less, and still more preferably 6.0 or less.

In the present specification, the dispersity of the molecular weight is a value obtained by calculating “weight-average molecular weight/number-average molecular weight”.

In a case where the resin composition includes a plurality of kinds of polyimide precursors as the first specific resin or the second specific resin, it is preferable that the weight-average molecular weight, the number-average molecular weight, and the dispersity of at least one kind of polyimide precursor are in the above ranges. Further, it is also preferable that the weight-average molecular weight, the number-average molecular weight, and the dispersity, calculated by using the plurality of kinds of polyimide precursors as one resin, are within the above ranges.

The imidization rate (also referred to as the “ring closure rate”) of the specific resin which is a polyimide is preferably 70% or more, more preferably 80% or more, and still more preferably 90% or more, from the viewpoint of the film hardness, the insulating properties, or the like of the organic film to be obtained. The upper limit of the imidization rate is not particularly limited, and it may be any imidization rate of 100% or less.

In addition, the content of the imide structure in the specific resin which is a polyimide is preferably 3 mmol/g or less and more preferably 2.5 mmol/g or less. The lower limit of the above-described content is not particularly limited, but can be, for example, 0.5 mmol/g or more.

In a case where the specific resin of the first specific resin or the second specific resin is a polyimide precursor, from the viewpoint of film hardness, insulating properties, and the like of an organic film to be obtained, an imidization rate of the polyimide precursor (also referred to as “ring closure rate”) is preferably less than 70%, more preferably 50% or less, still more preferably 20% or less, and particularly preferably 10% or less. The lower limit of the imidization rate is not particularly limited, and it may be any imidization rate of 0% or more.

The imidization rate is measured by, for example, the following method.

The infrared absorption spectrum of the specific resin is measured, and a peak intensity P1 in the vicinity of 1,377 cm⁻¹, which is the absorption peak derived from the imide structure, is obtained. Next, the specific resin is subjected to a heat treatment at 350° C. for 1 hour, and then the infrared absorption spectrum is measured again to obtain a peak intensity P2 in the vicinity of 1,377 cm⁻¹. Using the obtained peak intensities P1 and P2, the imidization rate of the specific resin can be determined based on the following expression.

$$Imidization rate ( \% ) = ( peak intensity P 1 / peak intensity P 2 ) \times 100$$

The ethylenically unsaturated bond equivalent of the specific resin (molar amount of ethylenically unsaturated bond per 1 g of specific resin) is preferably 0.5 mmol/g or more and 2.0 mmol/g or less.

The lower limit of the ethylenically unsaturated bond equivalent is not particularly limited, but is preferably 0.6 mmol/g or more and more preferably 0.7 mmol/g or more.

The upper limit of the ethylenically unsaturated bond equivalent is not particularly limited, but is preferably 1.9 mmol/g or less and more preferably 1.8 mmol/g or less.

### [Method for Producing Specific Resin]

The specific resin can be obtained by, for example, a method of reacting a tetracarboxylic acid dianhydride with a diamine at a low temperature, a method of reacting a tetracarboxylic acid dianhydride with a diamine at a low temperature to obtain a polyamic acid and subjecting the polyamic acid to esterification by using a condensing agent or an alkylating agent, a method of obtaining a diester with a tetracarboxylic acid dianhydride and alcohol and then reacting the diester with a diamine in the presence of a condensing agent, and a method of obtaining a diester with a tetracarboxylic acid dianhydride and alcohol, subsequently subjecting the rest dicarboxylic acid to acid-halogenation using a halogenating agent, and carrying out reaction with a diamine. Among the above production methods, a method of obtaining a diester with a tetracarboxylic acid dianhydride and alcohol, subsequently subjecting the rest dicarboxylic acid to acid-halogenation using a halogenating agent, and carrying out a reaction with a diamine is more preferable.

Examples of the condensing agent include dicyclohexylcarbodiimide, diisopropylcarbodiimide, 1-ethoxycarbonyl-2-ethoxy-1,2-dihydroquinoline, 1,1-carbonyldioxy-di-1,2,3-benzotriazole, N,N′-disuccinimidyl carbonate, and trifluoroacetic anhydride.

Examples of the alkylating agent include N,N-dimethylformamide dimethyl acetal, N,N-dimethylformamide diethyl acetal, N,N-dialkylformamide dialkyl acetal, trimethyl orthoformate, triethyl orthoformate.

Examples of the halogenating agent include thionyl chloride, oxalyl chloride, and phosphorus oxychloride.

In addition, in a case where a polyimide is desired to be obtained as the specific resin, the polyimide can be synthesized by a method of completely imidizing the resin obtained by the above method using a known imidization reaction method, a method of introducing a partial imide structure by stopping the imidization reaction in the middle of the reaction, or a method of introducing a partial imide structure by blending a completely imidized polymer and a polyimide precursor thereof. In addition, another known method for synthesizing polyimide can also be applied.

In the method for producing the specific resin, it is preferable to use an organic solvent at the time of reaction. One kind of organic solvent may be used, or two or more kinds thereof may be used.

The organic solvent can be appropriately determined depending on the raw material; however, examples thereof include pyridine, diethylene glycol dimethyl ether (diglyme), N-methylpyrrolidone, N-ethylpyrrolidone, ethyl propionate, dimethylacetamide, dimethylformamide, tetrahydrofuran, and γ-butyrolactone.

In the method for producing the specific resin, it is preferable to add a basic compound in a case of carrying out the reaction. One kind of basic compound may be used, or two or more kinds thereof may be used.

The basic compound can be appropriately determined depending on the raw material; however, examples thereof include triethylamine, diisopropylethylamine, pyridine, 1,8-diazabicyclo[5.4.0]undec-7-ene, and N,N-dimethyl-4-aminopyridine.

### —Terminal Blocking Agent—

In the method for producing the specific resin, in order to further improve the storage stability, it is preferable to seal a carboxylic acid anhydride, an acid anhydride derivative, or an amino group, which remains at the resin terminal of the specific resin. In a case of blocking the carboxylic acid anhydride and the acid anhydride derivative, remaining at the resin terminal, examples of the terminal blocking agent include a monoalcohol, phenol, thiol, thiophenol, and a monoamine. It is more preferable to use a monoalcohol, phenols, or a monoamine from the viewpoint of reactivity and film stability. Examples of the preferred monoalcohol compound include primary alcohol such as methanol, ethanol, propanol, butanol, hexanol, octanol, dodecanol, benzyl alcohol, 2-phenylethanol, 2-methoxyethanol, 2-chloromethanol, and furfuryl alcohol; secondary alcohol such as isopropanol, 2-butanol, cyclohexyl alcohol, cyclopentanol, and 1-methoxy-2-propanol; and tertiary alcohol such as t-butyl alcohol and adamantane alcohol. Examples of the preferred compounds of phenols include phenols such as phenol, methoxyphenol, methylphenol, naphthalene-1-ol, naphthalene-2-ol, and hydroxystyrene. In addition, examples of the preferred monoamine compound include aniline, 2-ethynyl aniline, 3-ethynyl aniline, 4-ethynyl aniline, 5-amino-8-hydroxyquinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 2-aminobenzenesulfonic acid, 3-aminobenzenesulfonic acid, 4-aminobenzenesulfonic acid, 3-amino-4,6-dihydroxypyrimidine, 2-aminophenol, 3-aminophenol, 4-aminophenol, 2-aminothiophenol, 3-aminothiophenol, and 4-aminothiophenol. Two or more of these may be used, and a plurality of different terminal groups may be introduced by reacting a plurality of terminal blocking agents.

In addition, in a case of blocking the amino group at the terminal of the resin, it is possible to carry out blocking with a compound having a functional group capable of reacting with the amino group. The preferred terminal blocking agent for the amino group is preferably a carboxylic acid anhydride, a carboxylic acid chloride, a carboxylic acid bromide, a sulfonic acid chloride, sulfonic acid anhydride, or a sulfonic acid carboxylic acid anhydride, and more preferably a carboxylic acid anhydride or a carboxylic acid chloride. Examples of the preferred carboxylic acid anhydride compound include acetic anhydride, propionic anhydride, oxalic anhydride, succinic anhydride, maleic acid anhydride, phthalic anhydride, benzoic anhydride, and 5-norbornene-2,3-dicarboxylic acid anhydride. Examples of the preferred carboxylic acid chloride compound include acetyl chloride, acrylic acid chloride, propionyl chloride, methacrylic acid chloride, pivaloyl chloride, cyclohexanecarbonyl chloride, 2-ethylhexanoyl chloride, cinnamoyl chloride, 1-adamantanecarbonyl chloride, heptafluorobutyryl chloride, stearic acid chloride, and benzoyl chloride.

### —Solid Precipitation—

In the production method for a specific resin, a step of precipitating a solid may be included. Specifically, it is possible to obtain a specific resin by filtering out a water-absorbing by-product of the dehydration condensing agent that is present together in the reaction solution as necessary, subsequently putting the obtained polymer component in a poor solvent such as water, an aliphatic lower alcohol, or a mixed solution thereof, precipitating the polymer component to be precipitated as a solid, and then carrying out drying. In order to improve the degree of purification, operations such as redissolution, reprecipitation, and drying of the specific resin may be repeated. Further, a step of removing ionic impurities using an ion exchange resin may be included.

### SPECIFIC EXAMPLE

Specific examples of the specific resin include polyimides (P-1) to (P-3), (P-5) to (P-17), and a polyimide precursor (P-4) in Examples described later, but the present invention is not limited thereto.

### [Content]

The content of the specific resin in the resin composition according to the embodiment of the present invention is preferably 20% by mass or more, more preferably 30% by mass or more, still more preferably 40% by mass or more, and even still more preferably 50% by mass or more, with respect to the total solid content of the resin composition. In addition, the content of the resin in the resin composition according to the embodiment of the present invention is preferably 99.5% by mass or less, more preferably 99% by mass or less, still more preferably 98% by mass or less, still more preferably 97% by mass or less, and even still more preferably 95% by mass or less, with respect to the total solid content of the resin composition.

The resin composition according to the embodiment of the present invention may contain only one kind of specific resin or may contain two or more kinds thereof. In a case where two or more kinds thereof are contained, the total amount thereof is preferably within the above range.

It is also preferable that the resin composition according to the embodiment of the present invention contains at least two kinds of resins.

Specifically, the resin composition according to the embodiment of the present invention may contain in total two or more kinds of the specific resins and other resins described later or may contain two or more kinds of the specific resins; however, it is preferable to include two or more kinds of the specific resins.

In a case where the resin composition according to the embodiment of the present invention contains two or more kinds of the specific resins, it is preferable to contain, for example, two or more kinds of polyimide precursors which are polyimide precursors in which the structure derived from the dianhydride is different.

### <Another Resin>

The resin composition according to the embodiment of the present invention may contain the above-described specific resin and another resin (hereinafter, also simply referred to as “the other resin”) that is different from the specific resin.

Examples of the other resins include other polyimide precursors different from the specific resin, other polyimides different from the specific resin, polybenzoxazole precursors, polybenzoxazole, polyamideimide precursors, polyamideimide, aromatic polyether, phenol resin, polyamide, epoxy resin, polysiloxane, resin including a siloxane structure, (meth)acrylic resin, (meth)acrylamide resin, urethane resin, butyral resin, styryl resin, polyether resin, and polyester resin.

Examples of the other polyimide precursors, the other polyimides, the polybenzoxazole precursors, the polybenzoxazoles, the polyamideimide precursors, and the polyamideimides include the compounds described in paragraphs 0017 to 0138 of WO2022/145355A. The above description is incorporated in the present specification.

The aromatic polyether is not particularly limited, but is preferably a polyphenylene ether.

The polyphenylene ether preferably includes a repeating unit represented by Formula (PE).

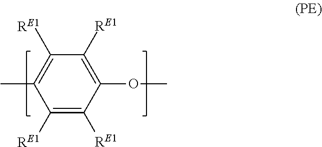

In Formula (PE), REI represents a hydrogen atom or a substituent. Examples of the substituent include a halogen atom, an alkyl group which may have a substituent, an alkoxy group which may have a substituent, an amino group which may have a substituent, a nitro group, and a carboxy group.

In addition, the polyphenylene ether is also preferably a compound having a polymerizable group.

As the polymerizable group, an epoxy group, an oxetanyl group, an oxazolyl group, a methylol group, an alkoxymethyl group, an acyloxymethyl group, a blocked isocyanate group, or a group having an ethylenically unsaturated bond is preferable, and a group having an ethylenically unsaturated bond is more preferable.

Examples of the group having an ethylenically unsaturated bond include a vinyl group, an allyl group, an isoallyl group, a 2-methylallyl group, a group (for example, a vinylphenyl group) having an aromatic ring that is directly bonded to a vinyl group, and a (meth)acrylamide group, a (meth)acryloyloxy group, where a vinylphenyl group, a (meth)acrylamide group, or a (meth)acryloyloxy group is preferable, a vinylphenyl group or a (meth)acryloyloxy group is more preferable, and a (meth)acryloyloxy group is still more preferable.

In a case where the polyphenylene ether is a compound having a polymerizable group, the position of the polymerizable group is not particularly limited, but for example, a structure in which the polymerizable group is introduced at the terminal of the main chain is preferable.

The polyphenylene ether may include other repeating units. However, the content of the other repeating units is preferably 30% by mass or less, more preferably 20% by mass or less, and still more preferably 10% by mass or less with respect to the total mass of the polyphenylene ether.

The number-average molecular weight of the polyphenylene ether is not particularly limited, but is preferably 500 to 50,000.

The lower limit of the number-average molecular weight is preferably 800 or higher, more preferably 1000 or higher, and still more preferably 1500 or higher.

The upper limit of the number-average molecular weight is preferably 30,000 or less, more preferably 20,000 or less, and still more preferably 10,000 or less.

Specific examples of the polyphenylene ether (PPE) include poly(2,6-dimethyl-1,4-phenylene ether), poly(2-methyl-6-ethyl-1,4-phenylene ether), poly(2-methyl-6-phenyl-1,4-phenylene ether), poly(2,6-dichloro-1,4-phenylene ether), a copolymer of 2,6-dimethylphenol and other phenols (for example, 2,3,6-trimethylphenol, 2-methyl-6-butylphenol, and the like), a polyphenylene ether copolymer obtained by coupling 2,6-dimethylphenol with biphenols or bisphenols, and a polyphenylene ether having a linear structure or a branched structure, which is obtained by heating poly(2,6-dimethyl-1,4-phenylene ether) and the like with phenolic compounds such as bisphenols or trisphenols in a toluene solvent in the presence of an organic peroxide and performing a redistribution reaction, but the present invention is not limited thereto.

In a case where the resin composition according to the embodiment of the present invention contains the other resin, the content of the other resin is preferably 0.01% by mass or more, more preferably 0.05% by mass or more, still more preferably 1% by mass or more, even still more preferably 2% by mass or more, even still more preferably 5% by mass or more, and even further still more preferably 10% by mass or more, with respect to the total solid content of the resin composition.

The content of the other resin in the resin composition according to the embodiment of the present invention is preferably 80% by mass or less, more preferably 75% by mass or less, still more preferably 70% by mass or less, even still more preferably 60% by mass or less, and even further still more preferably 50% by mass or less, with respect to the total solid content of the resin composition.

As one preferred aspect of the resin composition according to the embodiment of the present invention, an aspect in which the content of the other resin is a low content can be adopted. In the above aspect, the content of the other resin is preferably 20% by mass or less, more preferably 15% by mass or less, still more preferably 10% by mass or less, even still more preferably 5% by mass or less, and even further still more preferably 1% by mass or less, with respect to the total solid content of the resin composition. The lower limit of the content is not particularly limited, and it may be any content of 0% by mass or more.

The resin composition according to the embodiment of the present invention may contain only one kind of the other resin or may contain two or more kinds thereof. In a case where two or more kinds thereof are contained, the total amount thereof is preferably within the above range.

### <Polymerizable Compound>

The resin composition according to the embodiment of the present invention contains a polymerizable compound.

In addition, the resin composition according to the embodiment of the present invention preferably contains a photoradical polymerization initiator described later as the polymerization initiator, and contains a radically polymerizable compound as the polymerizable compound.

Examples of the polymerizable compound include a radically polymerizable compound (radical crosslinking agent) and other crosslinking agents.

### [Radical Crosslinking Agent]

The resin composition according to the embodiment of the present invention preferably contains a radical crosslinking agent.

The radical crosslinking agent is a compound having a radically polymerizable group. The radically polymerizable group is preferably a group containing an ethylenically unsaturated bond. Examples of the group containing an ethylenically unsaturated bond include a vinyl group, an allyl group, a vinylphenyl group, a (meth)acryloyl group, a maleimide group, and a (meth)acrylamide group.

Among these, a (meth)acryloyl group, a (meth)acrylamide group, or a vinylphenyl group is preferable, and from the viewpoint of reactivity, a (meth)acryloyl group is more preferable.

The radical crosslinking agent is preferably a compound having one or more ethylenically unsaturated bonds; however, a compound having two or more ethylenically unsaturated bonds is more preferable. The radical crosslinking agent may have three or more ethylenically unsaturated bonds.

The compound having 2 or more ethylenically unsaturated bonds is preferably a compound having 2 to 15 ethylenically unsaturated bonds, more preferably a compound having 2 to 10 ethylenically unsaturated bonds, and still more preferably a compound having 2 to 6 ethylenically unsaturated bonds.

In particular, the radical crosslinking agent preferably contains two or more (meth)acryloyl groups, more preferably contains 2 to 15 (meth)acryloyl groups, still more preferably contains 2 to 10 (meth)acryloyl groups, and particularly preferably contains 2 to 6 (meth)acryloyl groups. In the above-described aspect, the radical crosslinking agent may have a polymerizable group other than a (meth)acryloyl group, but it is preferable that the radical crosslinking agent does not have a polymerizable group other than a (meth)acryloyl group.

From the viewpoint of the film hardness of the pattern (cured substance) to be obtained, the resin composition according to the embodiment of the present invention preferably contains a compound having two ethylenically unsaturated bonds and a compound having three or more ethylenically unsaturated bonds.

The molecular weight of the radical crosslinking agent is preferably 2,000 or less, more preferably 1,500 or less, and still more preferably 900 or less. The lower limit of the molecular weight of the radical crosslinking agent is preferably 100 or more.

Specific examples of the radical crosslinking agent include unsaturated carboxylic acids (for example, acrylic acid, methacrylic acid, itaconic acid, crotonic acid, isocrotonic acid, and maleic acid), and esters and amides thereof, where esters between unsaturated carboxylic acids and polyhydric alcohol compounds or amides between unsaturated carboxylic acids and polyvalent amine compounds are preferable. In addition, addition reaction products produced by reacting unsaturated carboxylic acid esters or amides, having a nucleophilic substituent such as a hydroxy group, an amino group, or a sulfanyl group, with monofunctional or polyfunctional isocyanates or epoxies, dehydration condensation reaction products produced by reacting the above esters or amides with a monofunctional or polyfunctional carboxylic acid, or the like are also suitably used. In addition, an addition reaction product produced by reacting unsaturated carboxylic acid esters or amides, having an electrophilic substituent such as an isocyanate group or an epoxy group, with monofunctional or polyfunctional alcohols, amines, or thiols, and further, a substitution reaction product produced by reacting unsaturated carboxylic acid esters or amides, having an eliminable substituent such as a halogeno group or a tosyloxy group, with monofunctional or polyfunctional alcohols, amines, or thiols is also suitable. In addition, as other examples, it is also possible to use a group of compounds in which the unsaturated carboxylic acid described above is replaced with an unsaturated phosphonic acid, a vinylbenzene derivative such as styrene, a vinyl ether, an allyl ether, or the like. Regarding the specific examples thereof, reference can be made to the description of paragraphs 0113 to 0122 of JP2016-027357A, the content of which is incorporated in the present specification.

The radical crosslinking agent is also preferably a compound having a boiling point of 100° C. or higher under normal pressure. Examples of the compound having a boiling point of 100° C. or higher under normal pressure include the compounds described in paragraph 0203 of WO2021/112189A. The content thereof is incorporated in the present specification.

Examples of the preferred radical crosslinking agent other than those described above include the radically polymerizable compounds described in paragraphs 0204 to 0208 of WO2021/112189A. The content thereof is incorporated in the present specification.

As the radical crosslinking agent, ethoxylated glycerin triacrylate (as a commercially available product, A-GLY-3E, A-GLY-9E, or A-GLY-20E, all manufactured by Shin-Nakamura Chemical Co., Ltd.), trimethylolpropane trimethacrylate (manufactured by Shin-Nakamura Chemical Co., Ltd.), dipentaerythritol triacrylate (as a commercially available product, KAYARAD D-330 (manufactured by Nippon Kayaku Co., Ltd.)), dipentaerythritol tetraacrylate (as a commercially available product, KAYARAD D-320 (manufactured by Nippon Kayaku Co., Ltd.), A-TMMT (manufactured by Shin-Nakamura Chemical Co., Ltd.)), dipentaerythritol penta(meth)acrylate (as a commercially available product, KAYARAD D-310 (manufactured by Nippon Kayaku Co., Ltd.)), dipentaerythritol hexa(meth)acrylate (as a commercially available product, KAYARAD DPHA (manufactured by Nippon Kayaku Co., Ltd.), A-DPH (manufactured by Shin-Nakamura Chemical Co., Ltd.)), and a structure in which a (meth)acryloyl group of these is bonded through an ethylene glycol residue or a propylene glycol residue is preferable. Oligomer types thereof can also be used.

Examples of a commercially available product of the radical crosslinking agent include SR-494 which is a tetrafunctional acrylate having four ethyleneoxy chains, SR-209, 231, and 239 which are bifunctional methacrylates having four ethyleneoxy chains (all of which are manufactured by Sartomer Japan Inc.), DPCA-60 which is a hexafunctional acrylate having six pentyleneoxy chains, and TPA-330 which is a trifunctional acrylate having three isobutyleneoxy chains (both of which are manufactured by Nippon Kayaku Co., Ltd.), UAS-10 and UAB-140 which are urethane oligomers (both of which are manufactured by Nippon Paper Industries Co., Ltd.), NK ESTER M-40G, NK ESTER 4G, NK ESTER M-9300, NK ESTER A-9300, NK ESTER A-BPE-4, NK ESTER A-BPE-10, NK ESTER A-BPE-20, NK ESTER A-BPE-30, and UA-7200 (all of which are manufactured by Shin-Nakamura Chemical Co., Ltd.), DPHA-40H (manufactured by Nippon Kayaku Co., Ltd.), UA-306H, UA-306T, UA-306I, AH-600, T-600, and AI-600 (all of which are manufactured by KYOEISHA CHEMICAL Co., LTD.), and BLEMMER PME400 (manufactured by NOF Corporation).

As the radical crosslinking agent, the urethane acrylates as described in JP1973-041708B (JP-S48-041708B), JP1976-037193A (JP-S51-037193A), JP1990-032293B (JP-H02-032293B), and JP1990-016765B (JP-H02-016765B), and the urethane compounds having an ethylene oxide-based skeleton described in JP1983-049860B (JP-S58-049860B), JP1981-017654B (JP-S56-017654B), JP1987-039417B (JP-S62-039417B), and JP1987-039418B (JP-S62-039418B) are also suitable. As the radical crosslinking agent, the compounds having an amino structure or a sulfide structure in the molecule as described in JP1988-277653A (JP-S63-277653A), JP1988-260909A (JP-S63-260909A), and JP1989-105238A (JP-H01-105238A) can also be used.

The radical crosslinking agent may be a radical crosslinking agent having an acid group such as a carboxy group or a phosphoric acid group. The radical crosslinking agent having an acid group is preferably an ester between an aliphatic polyhydroxy compound and an unsaturated carboxylic acid and more preferably a radical crosslinking agent obtained by reacting an unreacted hydroxy group of an aliphatic polyhydroxy compound with a non-aromatic carboxylic acid anhydride to have an acid group. The radical crosslinking agent is particularly preferably a compound in which an aliphatic polyhydroxy compound is pentaerythritol or dipentaerythritol in a radical crosslinking agent having an acid group obtained by reacting an unreacted hydroxy group of the aliphatic polyhydroxy compound with a non-aromatic carboxylic acid anhydride. Examples of the commercially available product thereof include M-510 and M-520 as polybasic acid-modified acrylic oligomers which are manufactured by Toagosei Co., Ltd.

An acid value of the radical crosslinking agent having an acid group is preferably 0.1 to 300 mgKOH/g and more preferably 1 to 100 mgKOH/g. In a case where the acid value of the radical crosslinking agent is within the above-described range, excellent manufacturing handleability is exhibited, and excellent developability is exhibited. In addition, good polymerization properties are exhibited. The acid value is measured in accordance with the description of JIS K 0070:1992.

In the resin composition, it is preferable to use difunctional methacrylate or acrylate from the viewpoint of pattern resolution and film elasticity.

In specific examples of the compound, triethylene glycol diacrylate, triethylene glycol dimethacrylate, tetraethylene glycol dimethacrylate, tetraethylene glycol diacrylate, polyethylene glycol (PEG) 200 diacrylate, PEG 200 dimethacrylate, PEG 600 diacrylate, PEG 600 dimethacrylate, polytetraethylene glycol diacrylate, polytetraethylene glycol dimethacrylate, dipropylene glycol diacrylate, tripropylene glycol diacrylate, neopentyl glycol diacrylate, neopentyl glycol dimethacrylate, 3-methyl-1,5-pentanediol diacrylate, 1,6-hexanediol diacrylate, 1,6-hexanediol dimethacrylate, 1,7-heptanediol di(meth)acrylate, 1,8-octanediol di(meth)acrylate, 1,9-nonanediol di(meth)acrylate, 1,10-decanediol di(meth)acrylate, 1,11-undecanediol di(meth)acrylate, 1,12-dodecanediol di(meth)acrylate, dimethylol-tricyclodecane diacrylate, dimethylol-tricyclodecane dimethacrylate, bisphenol A ethylene oxide (EO) adduct diacrylate, bisphenol A EO adduct dimethacrylate, bisphenol A propylene oxide (PO) adduct diacrylate, bisphenol A PO adduct dimethacrylate, 2-hydroxy-3-acryloyloxypropyl methacrylate, isocyanuric acid EO-modified diacrylate, isocyanuric acid EO-modified dimethacrylate, other difunctional acrylates having a urethane bond, and difunctional methacrylates having a urethane bond can be used. As necessary, two or more of these can be mixedly used.

It is noted that, for example, the PEG 200 diacrylate refers to a polyethylene glycol diacrylate having a polyethylene glycol chain Formula weight of about 200.

In the photocurable resin composition according to the embodiment of the present invention, a monofunctional radical crosslinking agent can be preferably used as the radical crosslinking agent from the viewpoint of suppressing the warping of the pattern (cured substance). As the monofunctional radical crosslinking agent, (meth)acrylic acid derivatives such as n-butyl (meth)acrylate, 2-ethylhexyl (meth)acrylate, 2-hydroxyethyl(meth)acrylate; butoxyethyl (meth)acrylate, carbitol (meth)acrylate, cyclohexyl (meth)acrylate, benzyl (meth)acrylate, phenoxyethyl (meth)acrylate, N-methylol (meth)acrylamide, glycidyl (meth)acrylate, EO-modified tribromophenyl acrylate, polyethylene glycol mono (meth)acrylate, and polypropylene glycol mono(meth)acrylate, N-vinyl compounds such as N-vinylpyrrolidone and N-vinylcaprolactam, allyl glycidyl ethers, and the like are preferably used. As the monofunctional radical crosslinking agent, a compound having a boiling point of 100° C. or higher under normal pressure is also preferable in order to suppress volatilization before exposure.

In addition, examples of the bi- or higher functional radical crosslinking agent include allyl compounds such as diallyl phthalate and triallyl trimellitate.

In a case where a radical crosslinking agent is contained, the content of the radical crosslinking agent is preferably more than 0% by mass and 60% by mass or less with respect to the total solid content of the resin composition. The lower limit thereof is more preferably 5% by mass or more. The upper limit thereof is more preferably 50% by mass or less and still more preferably 30% by mass or less.

In addition, the resin composition according to the embodiment of the present invention contains a radical crosslinking agent, and the content of the radically polymerizable compound is preferably 8 parts by mass or more and 30 parts by mass or less with respect to 100 parts by mass of the specific resin.

One kind of radical crosslinking agent may be used alone, or two or more kinds thereof may be mixedly used. In a case where two or more kinds thereof are used in combination, the total amount thereof is preferably in the above range. [Another crosslinking agent]

The resin composition according to the embodiment of the present invention also preferably contains another crosslinking agent different from the radical crosslinking agent described above.

The other crosslinking agent refers to a crosslinking agent other than the above-described radical crosslinking agent, where it is preferably a compound having a plurality of groups, in the molecule, which accelerates a reaction of forming a covalent bond between other compounds in the composition or reaction products thereof, by the photosensitization of the above-described photoacid generator or photobase generator, and more preferably a compound having a plurality of groups, in the molecule, which accelerates a reaction of forming a covalent bond between other compounds in the composition or reaction products thereof, by the action of the acid or the base.

The acid or the base is preferably an acid or a base, which is generated from a photoacid generator or a photobase generator in the exposure step.

Examples of the other crosslinking agent include the compounds described in paragraphs 0179 to 0207 of WO2022/145355A. The above description is incorporated in the present specification.

### [Polymerization Initiator]

The resin composition according to the embodiment of the present invention contains a polymerization initiator. The polymerization initiator may be a thermal polymerization initiator or a photopolymerization initiator; however, it is particularly preferable to contain a photopolymerization initiator.

The photopolymerization initiator is preferably a photoradical polymerization initiator. The photoradical polymerization initiator is not particularly limited and can be appropriately selected from publicly known photoradical polymerization initiators. For example, a photoradical polymerization initiator having photosensitivity to rays ranging from the ultraviolet ray range to the visible light range is preferable. In addition, it may be an activator that acts with a sensitizing agent to generate an active radical.

The photoradical polymerization initiator preferably contains at least one compound having a molar absorption coefficient of at least about 50 L·mol⁻¹·cm⁻¹ within a range of a wavelength of about 240 to 800 nm (preferably 330 to 500 nm). The molar absorption coefficient of a compound can be measured using a well-publicly known method. For example, it is preferable to carry out a measurement at a concentration of 0.01 g/L using an ethyl acetate solvent with an ultraviolet-visible spectrophotometer (Cary-5 spectrophotometer manufactured by Varian Medical Systems, Inc.).

As a photoradical polymerization initiator, well-known compounds can be optionally used. Examples thereof include a halogenated hydrocarbon derivative (for example, a compound having a triazine skeleton, a compound having an oxadiazole skeleton, or a compound having a trihalomethyl group), an acylphosphine compound such as an acylphosphine oxide, hexaarylbiimidazole, an oxime compound such as an oxime derivative, an organic peroxide, a thio compound, a ketone compound, an aromatic onium salt, a keto oxime ether, an α-amino ketone compound such as aminoacetophenone, an α-hydroxy ketone compound such as hydroxyacetophenone, an azo-based compound, an azide compound, a metallocene compound, an organic boron compound, and an iron arene complex. With regard to details thereof, reference can be made to the description of paragraphs 0165 to 0182 of JP2016-027357A and paragraphs 0138 to 0151 of WO2015/199219A, the contents of which are incorporated in the present specification. In addition, examples thereof include the compounds described in paragraphs 0065 to 0111 of JP2014-130173A and JP6301489B, the peroxide-based photopolymerization initiator described in MATERIAL STAGE 37 to 60 p, vol. 19, No. 3, 2019, the photopolymerization initiator described in WO2018/221177A, the photopolymerization initiator described in WO2018/110179A, the photopolymerization initiator described in JP2019-043864A, the photopolymerization initiator described in JP2019-044030A, and the peroxide-based initiator described in JP2019-167313A, the contents of which are incorporated in the present specification.

Examples of the ketone compound include compounds described in paragraph 0087 of JP2015-087611A, the content of which is incorporated in the present specification. As a commercially available product thereof, KAYACURE DETX-S (manufactured by Nippon Kayaku Co., Ltd.) is also suitably used.

In one embodiment of the present invention, a hydroxyacetophenone compound, an aminoacetophenone compound, and an acylphosphine compound can be suitably used as the photoradical polymerization initiator. More specifically, for example, the aminoacetophenone-based initiator described in JP1998-291969A (JP-H10-291969A) and the acylphosphine oxide-based initiator described in JP4225898B can be used, the contents of which are incorporated in the present specification.

As the α-hydroxy ketone-based initiator, Omnirad 184, Omnirad 1173, Omnirad 2959, Omnirad 127 (all of which are manufactured by IGM Resins B.V.), IRGACURE 184 (IRGACURE is a registered trademark), DAROCUR 1173, IRGACURE 500, IRGACURE-2959, and IRGACURE 127 (all of which are manufactured by BASF SE) can be used.

As the α-amino ketone-based initiator, Omnirad 907, Omnirad 369, Omnirad 369E, Omnirad 379EG (all of which are manufactured by IGM Resins B.V.), IRGACURE 907, IRGACURE 369, and IRGACURE 379 (all of which are manufactured by BASF SE) can be used.

As the aminoacetophenone-based initiator, the acylphosphine oxide-based initiator, and the metallocene compound, it is also possible to suitably use, for example, the compounds described in paragraphs 0161 to 0163 of WO2021/112189A. The content thereof is incorporated in the present specification.

It is preferable that the photoradical polymerization initiator includes an oxime compound. In a case where an oxime compound is used, exposure latitude can be more effectively improved. The oxime compound is particularly preferable since the oxime compound has a wide exposure latitude (a wide exposure margin) and also works as a photocuring accelerator.

Among these, the resin composition preferably contains a compound having a ketoxime group as the photoradical polymerization initiator.

Specific examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2004-534797A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A, the content of which is incorporated in the present specification.

Examples of the preferred oxime compound include compounds having the following structures, 3-(benzoyloxy(imino))butan-2-one, 3-(acetoxy(imino))butan-2-one, 2-(acetoxy(imino)) pentan-3-one, 3-(propionyloxy(imino))butan-2-one, 2-(acetoxy(imino))-1-phenylpropan-1-one, 2-(benzoyloxy(imino))-1-phenylpropan-1-one, 3-((4-toluenesulfonyloxy)imino)butan-2-one, and 2-(ethoxycarbonyloxy(imino))-1-phenylpropan-1-one. In the resin composition, it is preferable to use an oxime compound, particularly as a photoradical polymerization initiator. The oxime compound as a photoradical polymerization initiator has a linking group of >C═N—O—C(═O)— in the molecule.

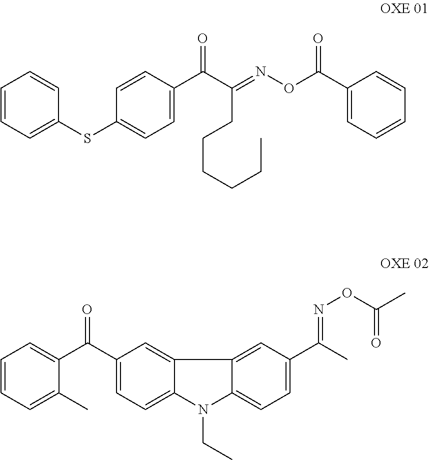 [SMILES: CCCCCC/C(=N\OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21]

Examples of the commercially available product of the oxime compound include IRGACURE OXE 01, IRGACURE OXE 02, IRGACURE OXE 03, and IRGACURE OXE 04 (all of which are manufactured by BASF SE), ADEKA OPTOMER N-1919 (manufactured by ADEKA Corporation, the photoradical polymerization initiator 2 described in JP2012-014052A), TR-PBG-304 and TR-PBG-305 (all of which are manufactured by Changzhou Tronly New Electronic Materials Co., Ltd.), ADEKA ARKLS NCI-730, NCI-831, and ADEKA ARKLS NCI-930 (all of which are manufactured by ADEKA Corporation), DFI-091 (manufactured by DAITO CHEMIX Co., Ltd.), and SpeedCure PDO (manufactured by SARTOMER ARKEMA). In addition, oxime compounds having the following structures can also be used.

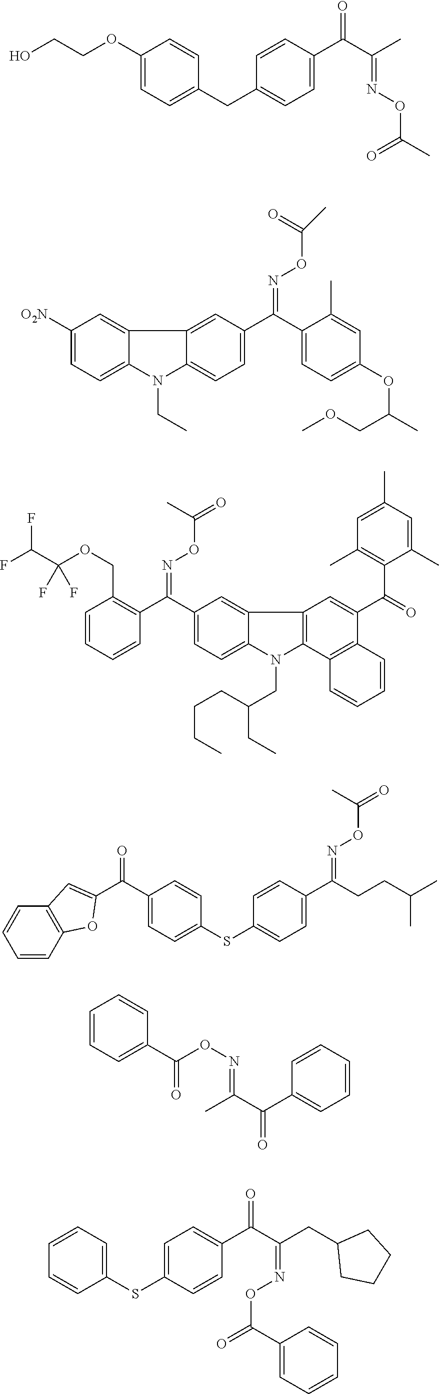 [SMILES: CC(=O)O/N=C(\C)C(=O)c1ccc(Cc2ccc(OCCO)cc2)cc1 ; CCn1c2ccc(/C(=N/OC(C)=O)c3ccc(OC(C)COC)cc3C)cc2c2cc([N+](=O)[O-])ccc21 ; CCCCC(CC)Cn1c2ccc(/C(=N\OC(C)=O)c3ccccc3COC(F)(F)C(F)F)cc2c2cc(C(=O)c3c(C)cc(C)cc3C)c3ccccc3c21 ; CC(=O)O/N=C(\CCC(C)C)c1ccc(Sc2ccc(C(=O)c3cc4ccccc4o3)cc2)cc1 ; C/C(=N\OC(=O)c1ccccc1)C(=O)c1ccccc1 ; O=C(O/N=C(/CC1CCCC1)C(=O)c1ccc(Sc2ccccc2)cc1)c1ccccc1]

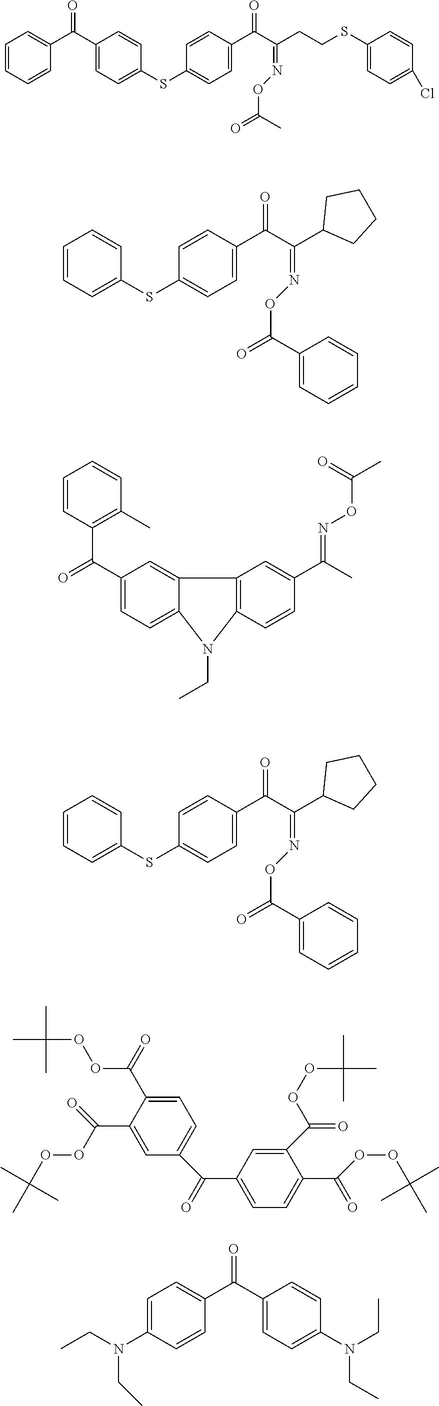

As the photoradical polymerization initiator, it is also possible to use, for example, the oxime compounds having a fluorene ring, which are described in paragraphs 0169 to 0171 of WO2021/112189A, an oxime compound having a skeleton in which at least one benzene ring of a carbazole ring is a naphthalene ring, or an oxime compound having a fluorine atom.

In addition, it is also possible to use the oxime compounds having a nitro group, which are described in paragraphs 0208 to 0210 of WO2021/020359A, an oxime compound having a benzofuran skeleton, or an oxime compound in which a substituent having a hydroxy group is bonded to a carbazole skeleton. The content thereof is incorporated in the present specification.

As the photopolymerization initiator, an oxime compound having an aromatic ring group Ar^{OX1} in which an electron withdrawing group is introduced into an aromatic ring (hereinafter, also referred to as an oxime compound OX) can also be used. Examples of the electron withdrawing group contained in the aromatic ring group Ar^{OX1} include an acyl group, a nitro group, a trifluoromethyl group, an alkylsulfinyl group, an arylsulfinyl group, an alkylsulfonyl group, an arylsulfonyl group, and a cyano group. Here, an acyl group or a nitro group is preferable, and due to the reason that a film having excellent light resistance is easily formed, an acyl group is more preferable, and a benzoyl group is still more preferable. The benzoyl group may have a substituent. The substituent is preferably a halogen atom, a cyano group, a nitro group, a hydroxy group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group, more preferably an alkyl group, an alkoxy group, an aryl group, an aryloxy group, a heterocyclic oxy group, an alkylsulfanyl group, an arylsulfanyl group, or an amino group, and still more preferably an alkoxy group, an alkylsulfanyl group, or an amino group.

The oxime compound OX is preferably at least one selected from a compound represented by Formula (OX1) or a compound represented by Formula (OX2), and more preferably a compound represented by Formula (OX2).

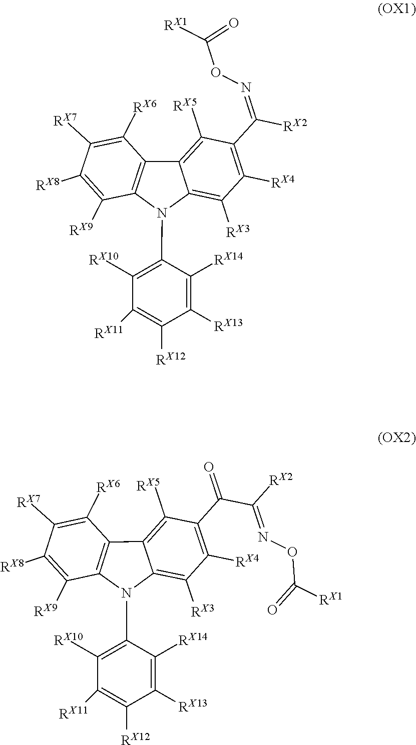

In Formulae, R^{X1} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group, R^{X2} represents an alkyl group, an alkenyl group, an alkoxy group, an aryl group, an aryloxy group, a heterocyclic group, or a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group, and R^{X3} to R^{X14} each independently represent a hydrogen atom or a substituent. However, at least one of R^{X10} . . . , or R^{X14} is an electron withdrawing group. In the above Formulae, it is preferable that R^{X12} is an electron withdrawing group, and R^{X10}, R^{X11}, R^{X13}, and R^{X14} are a hydrogen atom.

Specific examples of the oxime compound OX include the compounds described in paragraph Nos. 0083 to 0105 of JP4600600B, the content of which is incorporated in the present specification.

Examples of the particularly preferred oxime compound include the oxime compound having a specific substituent described in JP2007-269779A and the oxime compound having a thioaryl group described in JP2009-191061A, the contents of which are incorporated in the present specification.

From the viewpoint of exposure sensitivity, the photoradical polymerization initiator is preferably a compound selected from the group consisting of a trihalomethyltriazine compound, a benzyl dimethyl ketal compound, an α-hydroxy ketone compound, an α-aminoketone compound, an acylphosphine compound, a phosphine oxide compound, a metallocene compound, an oxime compound, a triaryl imidazole dimer, an onium salt compound, a benzothiazole compound, a benzophenone compound, an acetophenone compound and a derivative thereof, a cyclopentadiene-benzene-iron complex and a salt thereof, a halomethyl oxadiazole compound, and a 3-aryl substituted coumarin compound.

In addition, the photoradical polymerization initiator is a trihalomethyltriazine compound, an α-aminoketone compound, an acylphosphine compound, a phosphine oxide compound, a metallocene compound, an oxime compound, a triaryl imidazole dimer, an onium salt compound, a benzophenone compound, or an acetophenone compound. It is more preferably at least one compound selected from the group consisting of a trihalomethyltriazine compound, an α-aminoketone compound, a metallocene compound, an oxime compound, a triaryl imidazole dimer, and a benzophenone compound, and still more preferably a metallocene compound or an oxime compound.

As the photoradical polymerization initiator, the compounds described in paragraphs 0175 to 0179 of WO2021/020359A and the compounds described in paragraphs 0048 to 0055 of WO2015/125469A can also be used, the contents of which are incorporated in the present specification.

As the photoradical polymerization initiator, a photoradical polymerization initiator which is difunctional or tri- or higher functional may be used. In a case where such a photoradical polymerization initiator is used, two or more radicals are generated from one molecule of the photoradical polymerization initiator, and thus good sensitivity is obtained. Further, in a case where a compound having an asymmetric structure is used, the crystallinity is reduced, the solubility in a solvent or the like is improved, and the compound is hardly precipitated over time, which makes it possible to improve the temporal stability of the resin composition. Specific examples of the photoradical polymerization initiator which is difunctional or tri- or higher functional include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A, the compound (E) and compound (G) described in JP2013-522445A, Cmpd 1 to 7 described in WO2016/034963A, the oxime ester photoinitiators described in paragraph No. 0007 of JP2017-523465A, the photoinitiators described in paragraph Nos. 0020 to 0033 of JP2017-167399A, the photopolymerization initiator (A) described in paragraph Nos. 0017 to 0026 of JP2017-151342A, and the oxime ester photoinitiator described in JP6469669B, the contents of which are incorporated in the present specification.

In a case where the resin composition contains a photopolymerization initiator, the content thereof is preferably 0.1% to 30% by mass, more preferably 0.1% to 20% by mass, still more preferably 0.5% to 15% by mass, and even still more preferably 1.0% to 10% by mass with respect to the total solid content of the resin composition. Only one kind of photopolymerization initiator may be contained, or two or more kinds thereof may be contained. In a case where two or more kinds of photopolymerization initiators are contained, the total amount thereof is preferably within the above-described range.

It is noted that since the photopolymerization initiator may also function as a thermal polymerization initiator, crosslinking with the photopolymerization initiator may be further allowed to proceed by heating an oven, a hot plate, or the like.

### [Sensitizing Agent]

The resin composition may contain a sensitizing agent. The sensitizing agent absorbs a specific radioactive ray to be in an electronically excited state. The sensitizing agent in the electronically excited state is brought into contact with a thermal radical polymerization initiator, a photoradical polymerization initiator, or the like, to cause actions such as electron migration, energy transfer, and heat generation. As a result, the thermal radical polymerization and the photoradical polymerization initiator undergo a chemical change and decomposes to generate a radical, an acid, or a base.

In addition, as a usable sensitizing agent, a benzophenone-based, a Michler's ketone-based, a coumarin-based, a pyrazole azo-based, an anilino azo-based, a an anthraquinone-based, an anthracene-based, triphenylmethane-based, an anthrapylidene-based, a benzylidene-based, an oxonol-based, a pyrazolotriazole azo-based, a pyridone azo-based, a cyanine-based, a phenothiazine-based, a pyrrolopyrazole azomethine-based, a xanthene-based, a phthalocyanine-based, a benzopyran-based, and an indigo-based compound can be used.

Examples of the sensitizing agent include, Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobenzal)-4-methylcyclohexanone, 4,4′-bis(dimethylamino)chalcone, 4,4′-bis(diethylamino)chalcone, p-dimethylaminocinnamylidene indanone, p-dimethylamino benzylidene indanone, 2-(p-dimethylaminophenylbiphenylene)-benzothiazole, 2-(p-dimethylaminophenylvinylene)benzothiazole, 2-(p-dimethylaminophenylvinylene)isonaphtothiazole, 1,3-bis(4′-dimethylaminobenzal)acetone, 1,3-bis(4′-diethylaminobenzal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin (ethyl 7-(diethylamino)coumarin-3-carboxylate), N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethylaminostyryl)benzoxazole, 2-(p-dimethylaminostyryl)benzothiazole, 2-(p-dimethylaminostyryl)naphtho (1,2-d) thiazole, 2-(p-dimethylaminobenzoyl)styrene, diphenylacetamide, benzanilide, N-methylacetanilide, and 3′,4′-dimethylacetanilide.

In addition, other sensitizing dyes may be used.

For details of the sensitizing dye, reference can be made to the description in paragraphs 0161 to 0163 of JP2016-027357A, the content of which is incorporated in the present specification.

In a case where the resin composition contains a sensitizing agent, the content of the sensitizing agent is preferably 0.01% to 20% by mass, more preferably 0.1% to 15% by mass, and still more preferably 0.5% to 10% by mass with respect to the total solid content of the resin composition. One kind of sensitizing agent may be used alone, or two or more kinds thereof may be used in combination.

### [Chain Transfer Agent]

The resin composition according to the embodiment of the present invention may contain a chain transfer agent. The chain transfer agent is defined, for example, in Polymer Dictionary, 3rd Edition, pp. 683 to 684 (edited by The Society of Polymer Science, 2005). As the chain transfer agent, for example, the following compound is used; a group of compounds having —S—S—, —SO₂—S—, —N—O—, SH, PH, SiH, or GeH in the molecule, or a dithiobenzoate compound, a trithiocarbonate compound, dithiocarbamate, or a xanthate compound, which has a thiocarbonylthio group that is used for the reversible addition fragmentation chain transfer (RAFT) polymerization. These can donate hydrogen to a low active radical to generate a radical or can be oxidized and then deprotonated to generate a radical. In particular, a thiol compound can be preferably used.

In addition, as the chain transfer agent, the compounds described in paragraphs 0152 and 0153 of WO2015/199219A can also be used, the content of which is incorporated in the present specification.

In a case where the resin composition has a chain transfer agent, the content of the chain transfer agent is preferably 0.01 to 20 parts by mass, more preferably 0.1 to 10 parts by mass, and still more preferably 0.5 to 5 parts by mass, with respect to 100 parts by mass of the total solid content of the resin composition. Only one kind of chain transfer agent may be used alone, or two or more kinds thereof may be used. In a case where two or more kinds of chain transfer agents are used, the total thereof is preferably within the above-described range.

In addition, the polymerization initiator is preferably a photoacid generator. The photoacid generator is preferably a photoacid generator that generates a radical.

Specifically, the compound is preferably a compound that absorbs light, decomposes the absorbed light to generate a radical, and abstracts hydrogen from a solvent, an acid generator itself, or the like to generate an acid.

Examples of the photoacid generator include a quinone diazide compound, an oxime sulfonate compound, an organic halogenated compound, an organic borate compound, a disulfone compound, and an onium salt, and an onium salt is preferable.

Examples of the onium salt include a diazonium salt, a phosphonium salt, a sulfonium salt, and an iodonium salt.

Further, the onium salt is a salt of a cation having an onium structure and an anion, and the cation and the anion may be or may not be bonded through a covalent bond.

That is, the onium salt may be an intramolecular salt having a cation moiety and an anion moiety in the same molecular structure, or may be an intermolecular salt in which a cation molecule and an anion molecule, which are separate molecules, are ionically bonded; however, an intermolecular salt is preferred. Further, in the composition according to the embodiment of the present invention, the cation moiety or the cation molecule and the anion moiety or the anion molecule may be bonded by the ionic bonding or be dissociated from each other.

### [Sulfonium Salt]

In the present invention, the sulfonium salt means a salt of a sulfonium cation and an anion.

### —Sulfonium Cation—

The sulfonium cation is preferably a tertiary sulfonium cation and more preferably a triaryl sulfonium cation.

In addition, the sulfonium cation is preferably a cation represented by Formula (103).

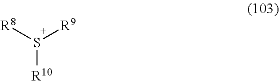

In Formula (103), R⁸ to R¹⁰ each independently represent a hydrocarbon group.

R⁸ to R¹⁰ are each independently preferably an alkyl group or an aryl group, more preferably an alkyl group having 1 to 10 carbon atoms or an aryl group having 6 to 12 carbon atoms, still more preferably an aryl group having 6 to 12 carbon atoms, and even still more preferably a phenyl group.

R⁸ to R¹⁰ may have a substituent, and examples of the substituent include a hydroxy group, an aryl group, an alkoxy group, an aryloxy group, an arylcarbonyl group, an alkylcarbonyl group, an alkoxycarbonyl group, an aryloxycarbonyl group, and an acyloxy group. Among these, R⁸ to R¹⁰ preferably have an alkyl group or an alkoxy group as the substituent, more preferably has a branched alkyl group or an alkoxy group, and still more preferably have a branched alkyl group having 3 to 10 carbon atoms or an alkoxy group having 1 to 10 carbon atoms.

R⁸ to R¹⁰ may be the same group or different groups; however, from the viewpoint of synthesis compatibility, R⁸ to R¹⁰ are preferably the same group.

### —Anion—

The anion is not particularly limited, and may be selected in consideration of the acid generated. Examples of the anion include boron-based anions such as B(C₆F₅)₄⁻ and BF₄⁻, phosphorus-based anions such as (Rf)ₙPF₆₋ₙ⁻, PF₃(C₂F₅)₃⁻ and PF₆⁻, antimony-based anions such as SbF₆⁻, and other carboxylate anions, sulfonate anions, and the like.

### [Iodonium Salt]

In the present invention, the iodonium salt means a salt of an iodonium cation and an anion. Examples of the anion include the same anions as those in the sulfonium salt described above, and the same applies to the preferred aspect.

### —Iodonium Cation—

The iodonium cation is preferably a diaryl iodonium cation.

In addition, the iodonium cation is preferably a cation represented by Formula (104).

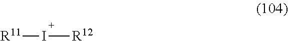

In Formula (104), R¹¹ and R¹² each independently represent a hydrocarbon group.

R¹¹ and R¹² are each independently preferably an alkyl group or an aryl group, more preferably an alkyl group having 1 to 10 carbon atoms or an aryl group having 6 to 12 carbon atoms, still more preferably an aryl group having 6 to 12 carbon atoms, and even still more preferably a phenyl group.

R¹¹ and R¹² may have a substituent, and examples of the substituent include a hydroxy group, an aryl group, an alkoxy group, an aryloxy group, an arylcarbonyl group, an alkylcarbonyl group, an alkoxycarbonyl group, an aryloxycarbonyl group, and an acyloxy group. Among these, R¹¹ to R¹² preferably have an alkyl group or an alkoxy group as the substituent, more preferably has a branched alkyl group or an alkoxy group, and still more preferably have a branched alkyl group having 3 to 10 carbon atoms or an alkoxy group having 1 to 10 carbon atoms.

R¹¹ and R¹² may be the same group or different groups; however, from the viewpoint of synthesis compatibility, R¹¹ and R¹² are preferably the same group.

### [Phosphonium Salt]

In the present invention, the phosphonium salt means a salt of a phosphonium cation and an anion. Examples of the anion include the same anions as those in the sulfonium salt described above, and the same applies to the preferred aspect.

### —Phosphonium Cation—

The phosphonium cation is preferably a quaternary phosphonium cation, and examples thereof include a tetraalkylphosphonium cation and a triarylmonoalkylphosphonium cation.

In addition, the phosphonium cation is preferably a cation represented by Formula (105).

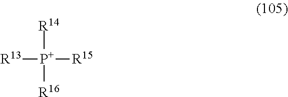

In Formula (105), R¹³ to R¹⁶ each independently represent a hydrogen atom or a hydrocarbon group.

R¹³ to R¹⁶ are each independently preferably an alkyl group or an aryl group, more preferably an alkyl group having 1 to 10 carbon atoms or an aryl group having 6 to 12 carbon atoms, still more preferably an aryl group having 6 to 12 carbon atoms, and even still more preferably a phenyl group.

R¹³ to R¹⁶ may have a substituent, and examples of the substituent include a hydroxy group, an aryl group, an alkoxy group, an aryloxy group, an arylcarbonyl group, an alkylcarbonyl group, an alkoxycarbonyl group, an aryloxycarbonyl group, and an acyloxy group. Among these, R¹³ to R¹⁶ preferably have an alkyl group or an alkoxy group as the substituent, more preferably has a branched alkyl group or an alkoxy group, and still more preferably have a branched alkyl group having 3 to 10 carbon atoms or an alkoxy group having 1 to 10 carbon atoms.

R¹³ to R¹⁶ may be the same group or different groups; however, from the viewpoint of synthesis compatibility, R¹³ to R¹⁶ are preferably the same group.

The content of the photoacid generator is preferably 0.1% to 20% by mass, more preferably 0.5% to 18% by mass, still more preferably 0.5% to 10% by mass, even more preferably 0.5% to 3% by mass, and even still more preferably 0.5% to 1.2% by mass, with respect to the total solid content of the resin composition.

One kind of photoacid generator may be used alone, or a plurality of kinds thereof may be used in combination. In the case of the combination of a plurality of kinds, it is preferable that the total amount thereof is within the above range.

In addition, in order to impart photosensitivity to a desired light source, it is also preferable to use a sensitizing agent in combination.

### [Thermal Polymerization Initiator]

Examples of the thermal polymerization initiator include a thermal radical polymerization initiator. The thermal radical polymerization initiator is a compound that generates a radical by heat energy and initiates or accelerates a polymerization reaction of a compound having polymerization properties. In a case where a thermal radical polymerization initiator is added, the polymerization reaction of the resin and the polymerizable compound can be allowed to proceed, and thus the solvent resistance can be further improved.

Specific examples of thermal radical polymerization initiator include compounds described in paragraphs 0074 to 0118 of JP2008-063554A, the content of which is incorporated in the present specification.

In a case where a thermal polymerization initiator is contained, the content thereof is preferably 0.1% to 30% by mass, more preferably 0.1% to 20% by mass, and still more preferably 0.5% to 15% by mass with respect to the total solid content of the resin composition. Only one kind of thermal polymerization initiator may be contained, or two or more kinds thereof may be contained. In a case where two or more kinds of thermal polymerization initiators are contained, the total amount thereof is preferably within the above-described range.

### <Base Generator>

The resin composition according to the embodiment of the present invention may contain a base generator. Here, the base generator is a compound that is capable of generating a base under a physical or chemical action. Examples of the preferred base generator include a thermal-base generator and a photobase generator.

In particular, in a case where the resin composition contains a precursor of a cyclization resin, it is preferable that the resin composition contains a base generator. In a case where the resin composition contains a thermal-base generator, it is possible to, for example, accelerate the cyclization reaction of the precursor by heating, whereby the mechanical properties and chemical resistance of the cured substance are improved and for example, the performance as an interlayer insulating film for a re-distribution layer, included in a semiconductor package, is improved.

The base generator may be an ionic base generator or may be a nonionic base generator. Examples of the base that is generated from the base generator include a secondary amine and a tertiary amine.

The base generator is not particularly limited, and a publicly known base generator can be used. Examples of the publicly known base generator include a carbamoyloxime compound, a carbamoylhydroxylamine compound, a carbamic acid compound, a formamide compound, an acetamide compound, a carbamate compound, a benzylcarbamate compound, a nitrobenzylcarbamate compound, a sulfonamide compound, an imidazole derivative compound, an aminimide compound, a pyridine derivative compound, an α-aminoacetophenone derivative compound, a quaternary ammonium salt derivative compound, an iminium salt, a pyridinium salt, an α-lactone ring derivative compound, a phthalimide derivative compound, and an acyloxyimino compound.

Specific examples of the nonionic base generator include the compounds described in paragraphs 0249 to 0275 of WO2022/145355A. The above description is incorporated in the present specification.

Examples of the base generator include the following compounds; however, the base generator is not limited thereto.

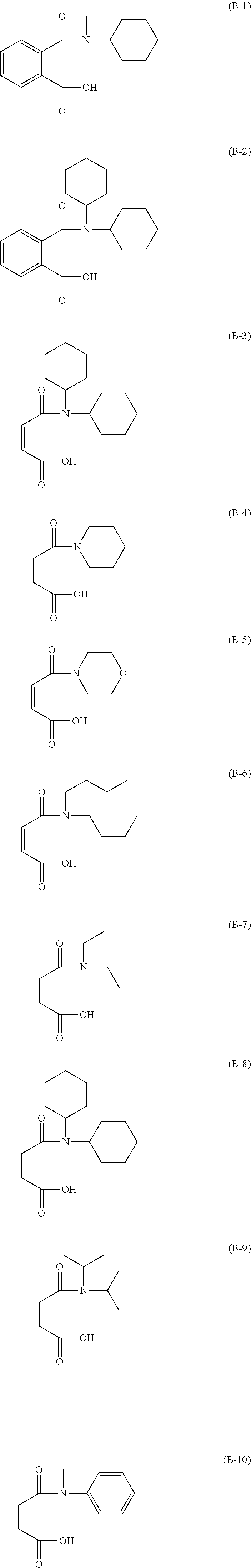

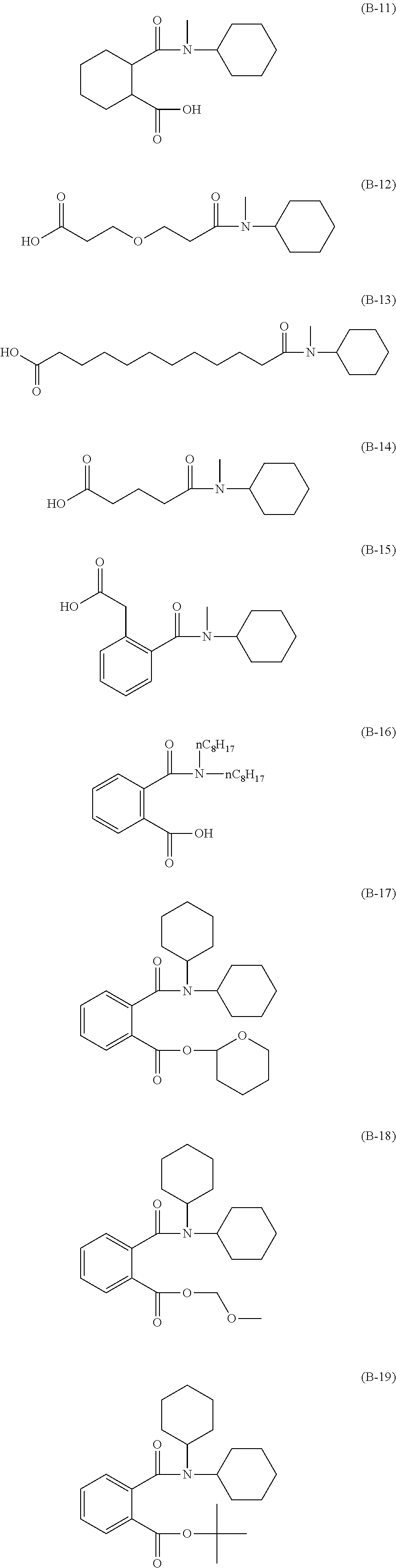

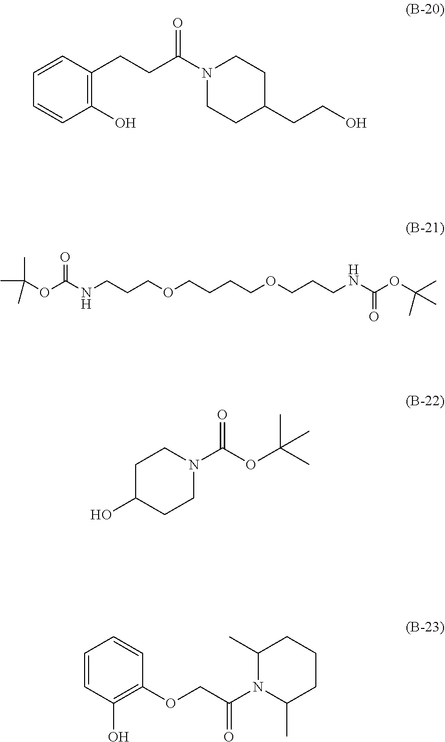 [SMILES: O=C(CCc1ccccc1O)N1CCC(CCO)CC1 ; CC(C)(C)OC(=O)NCCCOCCCCOCCCNC(=O)OC(C)(C)C ; CC(C)(C)OC(=O)N1CCC(O)CC1 ; CC1CCCC(C)N1C(=O)COc1ccccc1O]

The molecular weight of the nonionic base generator is preferably 800 or less, more preferably 600 or less, and still more preferably 500 or less. The lower limit thereof is preferably 100 or more, more preferably 200 or more, and still more preferably 300 or more.

Examples of the specific preferred compound of the ionic base generator include the compounds described in paragraphs 0148 to 0163 of WO2018/038002A.

Specific examples of the ammonium salt include the following compounds; however, the ammonium salt is not limited thereto.

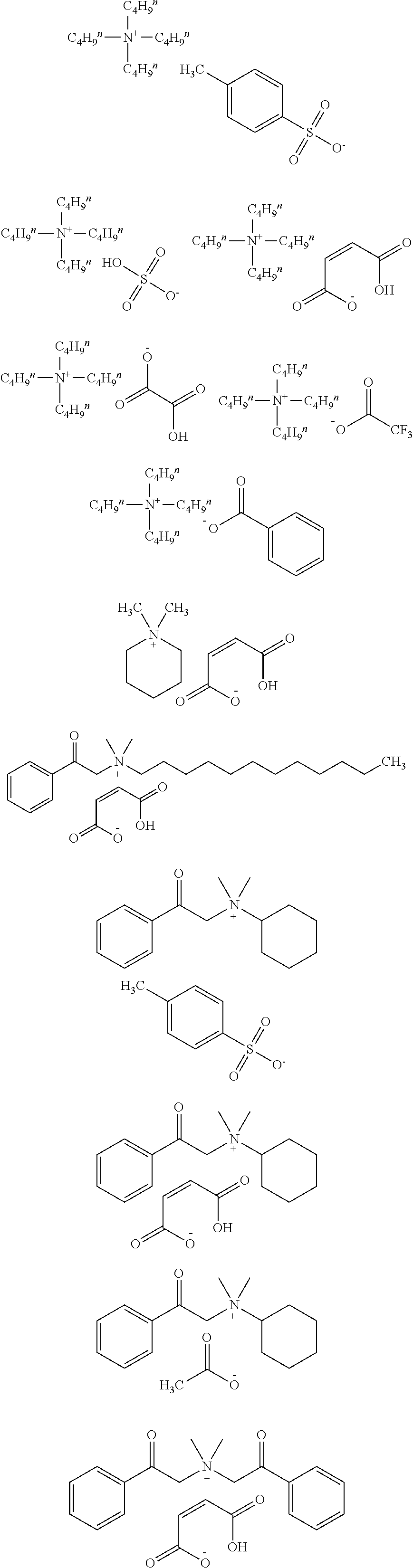

Specific examples of the iminium salt include the following compounds; however, the iminium salt is not limited thereto.

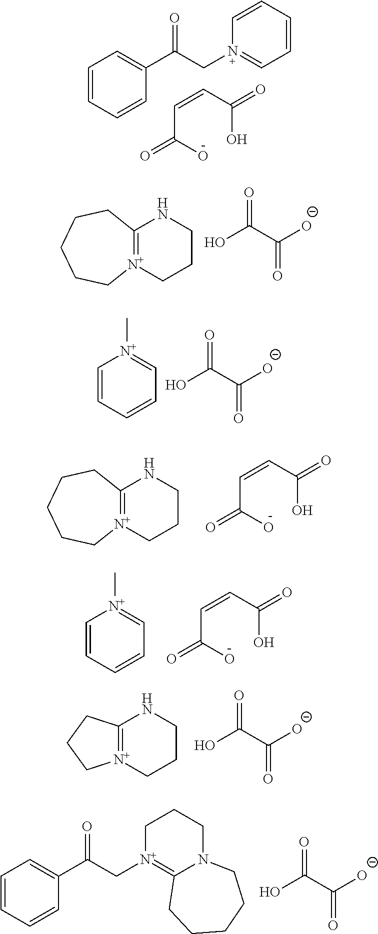

In addition, from the viewpoint of storage stability and generation of a base by deprotection during curing, the base generator is preferably an amine in which an amino group is protected by a t-butoxycarbonyl group.

Examples of the amine compound protected by a t-butoxycarbonyl group include ethanolamine, 3-amino-1-propanol, 1-amino-2-propanol, 2-amino-1-propanol, 4-amino-1-butanol, 2-amino-1-butanol, 1-amino-2-butanol, 3-amino-2,2-dimethyl-1-propanol, 4-amino-2-methyl-1-butanol, valinol, 3-amino-1,2-propanediol, 2-amino-1,3-propanediol, tyramine, norephedrine, 2-amino-1-phenyl-1,3-propanediol, 2-aminocyclohexanol, 4-aminocyclohexanol, 4-aminocyclohexanethanol, 4-(2-aminoethyl)cyclohexanol, N-methylethanolamine, 3-(methylamino)-1-propanol, 3-(isopropylamino)propanol, N-cyclohexylethanolamine, α-[2-(methylamino)ethyl]benzyl alcohol, diethanolamine, diisopropanolamine, 3-pyrrolidinol, 2-pyrrolidinomethanol, 4-hydroxypiperidine, 3-hydroxypiperidine, 4-hydroxy-4-phenylpiperidine, 4-(3-hydroxyphenyl)piperidine, 4-piperidinemethanol, 3-piperidinemethanol, 2-piperidinemethanol, 4-piperidinetanol, 2-piperidinetanol, 2-(4-piperidyl)-2-propanol, 1,4-butanol bis(3-aminopropyl)ether, 1,2-bis(2-aminoethoxy) ethane, 2,2′-oxybis(ethylamine), 1,14-diamino-3,6,9,12-tetraoxatetradecane, 1-aza-15-crown 5-ether, diethylene glycol bis(3-aminopropyl)ether, 1,11-diamino-3,6,9-trioxaundecane, or a compound in which an amino group of an amino acid and a derivative thereof is protected by a t-butoxycarbonyl group, but the present invention is not limited to these examples.

In a case where the resin composition contains a base generator, the content of the base generator is preferably 0.1 to 50 parts by mass with respect to 100 parts by mass of the resin in the resin composition. The lower limit thereof is more preferably 0.3 parts by mass or more and still more preferably 0.5 parts by mass or more. The upper limit thereof is more preferably 30 parts by mass or less, still more preferably 20 parts by mass or less, even still more preferably 10 parts by mass or less, even further still more preferably 5 parts by mass or less, and particularly preferably 4 parts by mass or less.

One kind or two or more kinds of base generators can be used. In a case where two or more kinds thereof are used, the total amount is preferably within the above-described range.

### <Solvent>

The resin composition according to the embodiment of the present invention preferably contains a solvent.

As the solvent, any publicly known solvent can be used. The solvent is preferably an organic solvent. Examples of the organic solvent include compounds such as esters, ethers, ketones, cyclic hydrocarbons, sulfoxides, amides, ureas, and alcohols.

Suitable examples of the esters include ethyl acetate, n-butyl acetate, isobutyl acetate, hexyl acetate, amyl formate, isoamyl acetate, butyl propionate, isopropyl butyrate, ethyl butyrate, butyl butyrate, methyl lactate, ethyl lactate, γ-butyrolactone, ¿-caprolactone, δ-valerolactone, γ-valerolactone, alkyl alkyloxyacetate (for example, methyl alkyloxyacetate, ethyl alkyloxyacetate, and butyl alkyloxyacetate (for example, methyl methoxyacetate, ethyl methoxyacetate, butyl methoxyacetate, methyl ethoxyacetate, and ethyl ethoxyacetate)), 3-alkyloxypropionic acid alkyl esters (for example, methyl 3-alkyloxypropionate, and ethyl 3-alkyloxypropionate (for example, methyl 3-methoxypropionate, ethyl 3-methoxypropionate, methyl 3-ethoxypropionate, and ethyl 3-ethoxypropionate)), 2-alkyloxypropionic acid alkyl esters (for example, methyl 2-alkyloxypropionate, ethyl 2-alkyloxypropionate, and propyl 2-alkyloxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-alkyloxy-2-methylpropionate and ethyl 2-alkyloxy-2-methylpropionate (for example, methyl 2-methoxy-2-methylpropionate and ethyl 2-ethoxy-2-methylpropionate), methyl pyruvate, ethyl pyruvate, propyl pyruvate, methyl acetoacetate, ethyl acetoacetate, methyl 2-oxobutanoate, ethyl 2-oxobutanoate, ethyl hexanoate, ethyl heptanoate, dimethyl malonate, and diethyl malonate.

Suitable examples of ethers include ethylene glycol dimethyl ether, diethylene glycol dimethyl ether, diethylene glycol diethyl ether, diethylene glycol ethyl methyl ether, diethylene glycol butyl methyl ether, triethylene glycol dimethyl ether, tetraethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol dimethyl ether, propylene glycol monomethyl ether acetate, propylene glycol monoethyl ether acetate, ethylene glycol monobutyl ether, ethylene glycol monobutyl ether acetate, diethylene glycol ethyl methyl ether, propylene glycol monopropyl ether acetate, and dipropylene glycol dimethyl ether.

Suitable examples of the ketones include methyl ethyl ketone, cyclohexanone, cyclopentanone, 2-heptanone, 3-heptanone, 3-methylcyclohexanone, levoglucosenone, and dihydrolevoglucosenone.

Suitable examples of the cyclic hydrocarbon include aromatic hydrocarbons such as toluene, xylene, and anisole, and cyclic terpenes such as limonene.

Suitable examples of the sulfoxides include dimethyl sulfoxide.

Suitable examples of the amide include N-methyl-2-pyrrolidone, N-ethyl-2-pyrrolidone, N-cyclohexyl-2-pyrrolidone, N,N-dimethylacetamide, N,N-dimethylformamide, N,N-dimethylisobutylamide, 3-methoxy-N,N-dimethylpropionamide, 3-butoxy-N,N-dimethylpropionamide, N-formylmorpholine, and N-acetylmorpholine.

Suitable examples of the urea include N,N,N′,N′-tetramethylurea and 1,3-dimethyl-2-imidazolidinone.

Examples of the alcohols include methanol, ethanol, 1-propanol, 2-propanol, 1-butanol, 1-pentanol, 1-hexanol, benzyl alcohol, ethylene glycol monomethyl ether, 1-methoxy-2-propanol, 2-ethoxyethanol, diethylene glycol monoethyl ether, diethylene glycol monohexyl ether, triethylene glycol monomethyl ether, propylene glycol monoethyl ether, propylene glycol monomethyl ether, polyethylene glycol monomethyl ether, polypropylene glycol, tetraethylene glycol, ethylene glycol monobutyl ether, ethylene glycol monobenzyl ether, ethylene glycol monophenyl ether, methylphenyl carbinol, n-amyl alcohol, methylamyl alcohol, and diacetone alcohol.

From the viewpoint of improving the properties of a coated surface or the like, it is also preferable to mix two or more kinds of solvents.

In the present invention, the solvent is preferably one solvent selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclopentanone, γ-butyrolactone, γ-valerolactone, 3-methoxy-N,N-dimethylpropionamide, toluene, dimethyl sulfoxide, ethyl carbitol acetate, butyl carbitol acetate, N-methyl-2-pyrrolidone, propylene glycol methyl ether, and propylene glycol methyl ether acetate, as well as levoglucosenone and dihydrolevoglucosenone, or a mixed solvent composed of two or more of these. A combined use of dimethyl sulfoxide and γ-butyrolactone, a combined use of dimethyl sulfoxide and γ-valerolactone, a combined use of 3-methoxy-N,N-dimethylpropionamide and γ-butyrolactone, a combined use of 3-methoxy-N,N-dimethylpropionamide and dimethyl sulfoxide, or, a combined use of N-methyl-2-pyrrolidone and ethyl lactate is particularly preferable. An aspect in which an amount of about 1% to 10% by mass of toluene with respect to the total mass of the solvent is further added to these combinedly used solvents is also one of the preferred aspects of the present invention.

In particular, from the viewpoint of the storage stability or the like of the resin composition, an aspect in which γ-valerolactone is included as the solvent is also one of the preferred aspects of the present invention. In such an aspect, the content of γ-valerolactone with respect to the total mass of the solvent is preferably 50% by mass or more, more preferably 60% by mass or more, and still more preferably 70% by mass or more. In addition, the upper limit of the above-described content is not particularly limited, and it may be 100% by mass. The above-described content may be determined in consideration of the solubility or the like of the component contained in the resin composition, such as the specific resin.

In addition, in a case where dimethyl sulfoxide and γ-valerolactone are used in combination, with respect to the total mass of the solvent, it is preferable to contain 60% to 90% by mass of γ-valerolactone and 10% to 40% by mass of dimethyl sulfoxide, it is more preferable to contain 70% to 90% by mass of γ-valerolactone and 10% to 30% by mass of dimethyl sulfoxide, and it is still more preferable to contain 75% to 85% by mass of γ-valerolactone and 15% to 25% by mass of dimethyl sulfoxide.

Regarding the content of the solvent, the amount of the solvent is such that, from the viewpoint of coatability, the concentration of the total solid contents of the resin composition according to the embodiment of the present invention is preferably 5% to 80% by mass, more preferably 5% to 75% by mass, still more preferably 10% to 70% by mass, and even still more preferably 20% to 70% by mass. The content of the solvent may be adjusted depending on the desired thickness of the coating film and the coating method. In a case where two or more kinds of solvents are contained, the total thereof is preferably within the above-described range.

### <Metal Adhesiveness Improving Agent>

From the viewpoint of improving adhesiveness to a metal material used for an electrode, a wire, or the like, the resin composition according to the embodiment of the present invention preferably contains a metal adhesiveness improving agent. Examples of the metal adhesiveness improving agent include a silane coupling agent having an alkoxysilyl group, an aluminum-based auxiliary adhesive agent, a titanium-based auxiliary adhesive agent, a compound having a sulfonamide structure and a compound having a thiourea structure, a phosphoric acid derivative compound, a β-ketoester compound, and an amino compound.

### [Silane Coupling Agent]

Examples of the silane coupling agent include the compounds described in paragraph 0316 of WO2021/112189A and the compounds described in paragraphs 0067 to 0078 of JP2018-173573A, the contents of which are incorporated in the present specification. In addition, it is also preferable to use two or more kinds of different silane coupling agents as described in paragraphs 0050 to 0058 of JP2011-128358A. It is also preferable to use the following compound as the silane coupling agent. In the following Formulae, Me represents a methyl group, and Et represents an ethyl group. In addition, examples of R shown below include a structure derived from a blocking agent in a blocked isocyanate group. The blocking agent may be selected depending on the desorption temperature; however, examples thereof include an alcohol compound, a phenol compound, a pyrazole compound, a triazole compound, a lactam compound, and an active methylene compound. It is preferably caprolactam or the like, for example, from the viewpoint of setting the desorption temperature to 160° C. to 180° C. Examples of the commercially available product of such a compound include X-12-1293 (manufactured by Shin-Etsu Chemical Co., Ltd.).

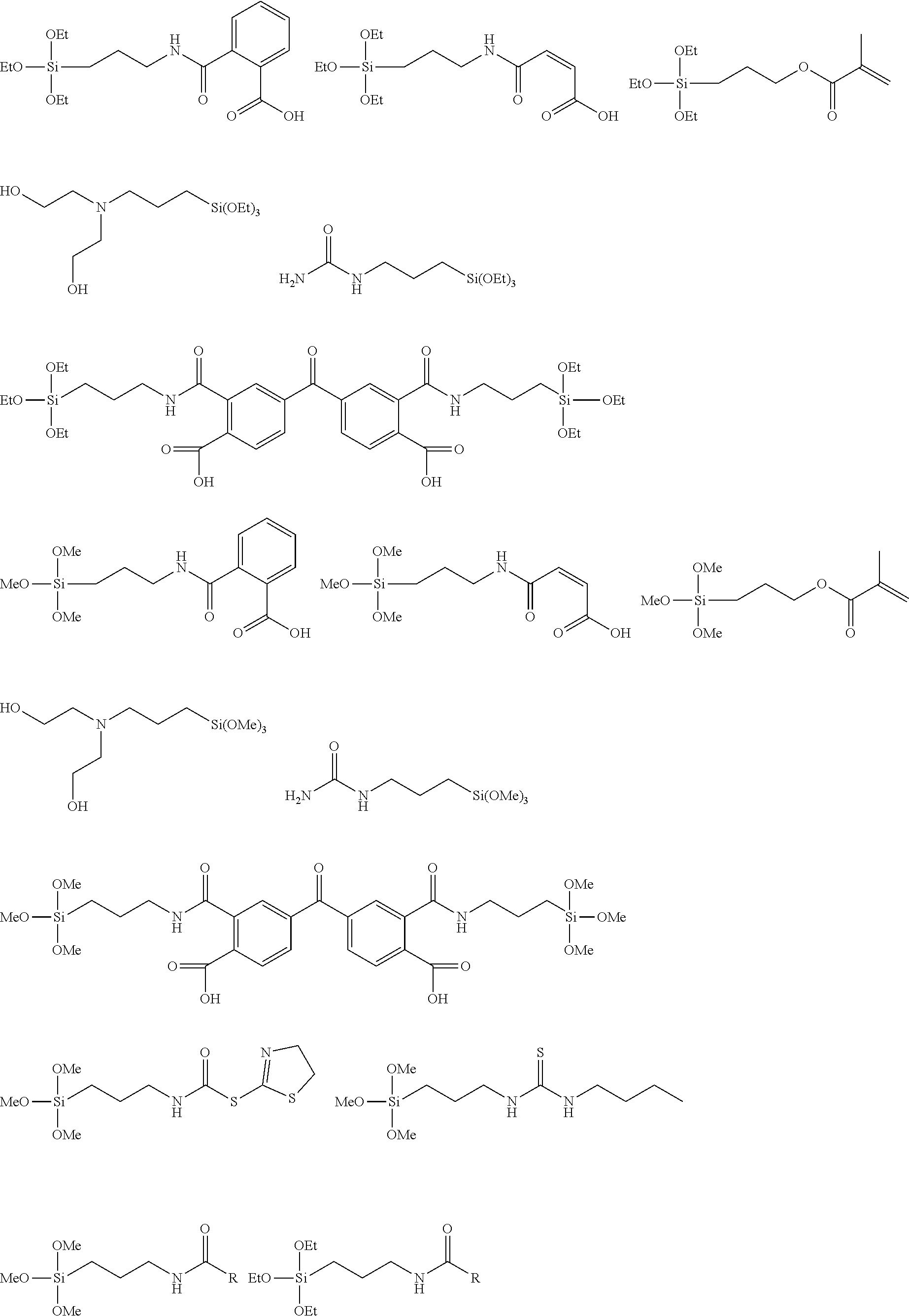

Examples of the other silane coupling agent include vinyltrimethoxysilane, vinyltriethoxysilane, 2-(3,4-epoxycyclohexyl)ethyltrimethoxysilane, 3-glycidoxypropyltrimethoxysilane, 3-glycidoxypropyltriethoxysilane, 3-methacryloxypropylmethyldimethoxysilane, 3-methacryloxypropylmethyldiethoxysilane, 3-glycidoxypropylmethyldimethoxysilane, 3-glycidoxypropylmethyldiethoxysilane, p-styryltrimethoxysilane, 3-methacryloxypropyltrimethoxysilane, 3-methacryloxypropyltriethoxysilane, 3-acryloxypropyltrimethoxysilane, N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, tris-(trimethoxysilylpropyl)isocyanurate, 3-ureidopropyltrialkoxysilane, 3-mercaptopropylmethyldimethoxysilane, 3-mercaptopropyltrimethoxysilane, 3-isocyanatepropyltriethoxysilane, and 3-trimethoxysilylpropylsuccinic acid anhydride. These can be used alone or in a combination of two or more thereof.

In addition, an oligomer type compound having a plurality of alkoxysilyl groups can also be used as the silane coupling agent.

Examples of such an oligomer type compound include a compound containing a repeating unit represented by Formula (S-1).

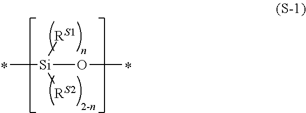

In Formula (S-1), R^{S1} represents a monovalent organic group, R^{S2} represents a hydrogen atom, a hydroxy group, or an alkoxy group, and n represents an integer of 0 to 2.

R^{S1} preferably has a structure including a polymerizable group. Examples of the polymerizable group include a group having an ethylenically unsaturated bond, an epoxy group, an oxetanyl group, a benzoxazolyl group, a blocked isocyanate group, and an amino group. Examples of the group having an ethylenically unsaturated bond include a vinyl group, an allyl group, an isoallyl group, a 2-methylallyl group, a group (for example, a vinylphenyl group) having an aromatic ring that is directly bonded to a vinyl group, and a (meth)acrylamide group, a (meth)acryloyloxy group, where a vinylphenyl group, a (meth)acrylamide group, or a (meth)acryloyloxy group is preferable, a vinylphenyl group or a (meth)acryloyloxy group is more preferable, and a (meth)acryloyloxy group is still more preferable.

R^{S2} is preferably an alkoxy group, and more preferably a methoxy group or an ethoxy group.

n represents an integer of 0 to 2, and it is preferably 1.

Here, structures of a plurality of repeating units represented by Formula (S-1) may be the same, where the plurality of repeating units are contained in the oligomer type compound.

Here, among a plurality of repeating units represented by Formula (S-1), which are contained in the oligomer type compound, it is preferable that at least one repeating unit has n of 1 or 2, it is more preferable that at least two repeating units have n of 1 or 2, and it is still more preferable that at least two repeating units have n of 1.

As such an oligomer type compound, a commercially available product can be used, and examples thereof include KR-513 (manufactured by Shin-Etsu Chemical Co., Ltd.).

### [Aluminum-Based Auxiliary Adhesive Agent]

Examples of the aluminum-based auxiliary adhesive agent include aluminum tris(ethyl acetoacetate), aluminum tris(acetyl acetate), and ethyl acetoacetate aluminum diisopropylate.

As another metal adhesiveness improving agent, the compounds described in paragraphs 0046 to 0049 of JP2014-186186A, and the sulfide-based compounds described in paragraphs 0032 to 0043 of JP2013-072935A can also be used, the contents of which are incorporated in the present specification.

The content of the metal adhesiveness improving agent is preferably 0.01 to 30 parts by mass, more preferably 0.1 to 10 parts by mass, and still more preferably 0.5 to 5 parts by mass with respect to 100 parts by mass of the specific resin. In a case where the content is set to be equal to or higher than the above lower limit value, good adhesiveness between a pattern and a metal layer is exhibited, and in a case where the content is set to be equal to or lower than the above upper limit value, good heat resistance of the pattern and good mechanical characteristics are exhibited. Only one kind of metal adhesiveness improving agent may be used, or two or more kinds thereof may be used. In a case where two or more kinds thereof are used, the total content thereof is preferably within the above-described range.

### <Migration Suppressing Agent>

The resin composition according to the embodiment of the present invention preferably further contains a migration suppressing agent. For example, in a case where the resin composition is applied to a metal layer (or a metal wiring line) to form a film, it is possible to effectively suppress the migration of metal ions derived from the metal layer (or the metal wiring line) into the film, in a case where a migration suppressing agent is contained.

The migration suppressing agent is not particularly limited; however, examples thereof include a compound having a heterocyclic ring (a pyrrole ring, a furan ring, a thiophene ring, an imidazole ring, an oxazole ring, a thiazole ring, a pyrazole ring, an isoxazole ring, an isothiazole ring, a tetrazole ring, a pyridine ring, a pyridazine ring, a pyrimidine ring, a pyrazine ring, a piperidine ring, a piperazine ring, a morpholine ring, a 2H-pyran ring and a 6H-pyran ring, or a triazine ring), a compound having thioureas and a sulfanyl group, a hindered phenol-based compound, a salicylic acid derivative-based compound, and a hydrazide derivative-based compound. In particular, it is possible to preferably use a triazole-based compound such as 1,2,4-triazole, benzotriazole, 3-amino-1,2,4-triazole, or 3,5-diamino-1,2,4-triazole, or a tetrazole-based compound such as 1H-tetrazole, 5-phenyltetrazole or 5-amino-1H-tetrazole.

As the migration suppressing agent, an ion trap agent that captures an anion such as a halogen ion can also be used.

The rust inhibitors described in paragraph 0094 of JP2013-015701A, the compounds described in paragraphs 0073 to 0076 of JP2009-283711A, the compounds described in paragraph 0052 of JP2011-059656A, the compounds described in paragraphs 0114, 0116, and 0118 of JP2012-194520A, the compounds described in paragraph 0166 of WO2015/199219A, or the like can be used as the other migration suppressing agents, the contents of which are incorporated in the present specification.

Specific examples of the migration suppressing agent include the following compounds.

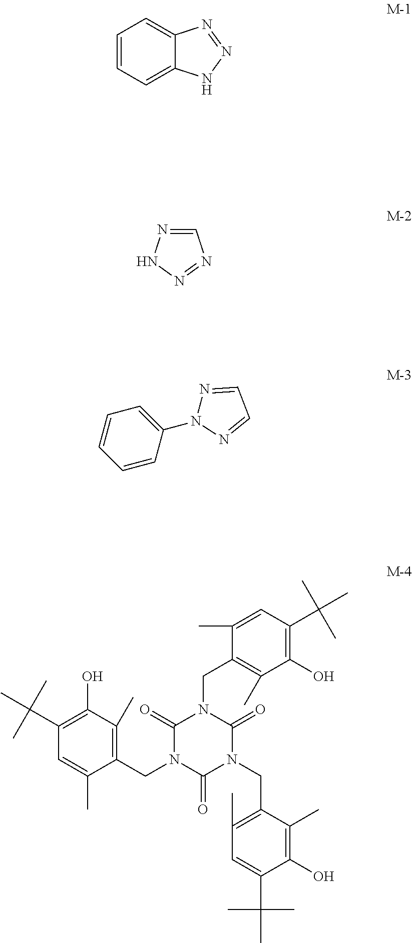 [SMILES: c1ccc2[nH]nnc2c1 ; c1nn[nH]n1 ; c1ccc(-n2nccn2)cc1 ; Cc1cc(C(C)(C)C)c(O)c(C)c1Cn1c(=O)n(Cc2c(C)cc(C(C)(C)C)c(O)c2C)c(=O)n(Cc2c(C)cc(C(C)(C)C)c(O)c2C)c1=O]

In a case where the resin composition according to the embodiment of the present invention contains the migration suppressing agent, the content of the migration suppressing agent is preferably 0.01% to 5.0% by mass, more preferably 0.05% to 2.0% by mass, and still more preferably 0.1% to 1.0% by mass, with respect to the total solid content of the resin composition.

Only one kind of migration suppressing agent may be used alone, or two or more kinds thereof may be used. In a case where two or more kinds of migration suppressing agents are used, the total thereof is preferably within the above-described range.

### <Light Absorbing Agent>

The resin composition according to the embodiment of the present invention also preferably contains a compound (a light absorbing agent) having a small absorbance at an exposure wavelength thereof upon exposure.

Whether or not a certain compound a contained in the resin composition corresponds to a light absorbing agent (that is, whether or not the absorbance thereof at the exposure wavelength decreases upon exposure) can be determined by the following method.

First, a solution of the compound a having the same concentration as the concentration of the compound contained in the resin composition is prepared, and the molar absorption coefficient of the compound a at the wavelength of the exposure light (mol⁻¹·L·cm⁻¹; also referred to as a “molar absorption coefficient 1”) is measured. The above measurement is carried out quickly so that an influence of a change such as a decrease in the molar absorption coefficient of the compound a is small. As a solvent in the above solution, a solvent of the resin composition is used in a case where the resin composition contains a solvent, and N-methyl-2-pyrrolidone is used in a case where the resin composition does not contain a solvent.

Next, the solution of the compound a is irradiated with exposure light. The exposure amount is 500 mJ, in terms of the integrated amount, with respect to 1 mol of the compound a.

Then, using the exposed solution of the compound a, the molar absorption coefficient of the compound a at the wavelength of the exposure light (mol⁻¹·L·cm⁻¹; also referred to as a “molar absorption coefficient 2”) is measured.

From the above-described molar absorption coefficient 1 and molar absorption coefficient 2, a decay rate (%) is calculated based on the following expression, and in a case where the decay rate (%) is 5% or more, it is determined that the compound a is a compound (that is, a light absorbing agent) in which the absorbance at the exposure wavelength decreases due to the exposure.

$$Attenuation rate ( \% ) = 1 - molar absorption coefficient 2 / molar absorption coefficient 1 \times 100$$

The attenuation rate is preferably 10% or more and more preferably 20% or more. In addition, the lower limit of the attenuation rate is not particularly limited, and it may be any attenuation rate of 0% by mass or more.

In a case where the resin composition is used for forming a photosensitive film, the wavelength of the exposure light may be any wavelength at which the photosensitive film is exposed.

In addition, the wavelength of the exposure light is preferably a wavelength at which the photopolymerization initiator contained in the resin composition has sensitivity. The fact that the photopolymerization initiator has sensitivity to a certain wavelength refers to that a polymerization initiation species is generated in a case where the photopolymerization initiator is exposed at a certain wavelength.

Examples of the wavelength of the exposure light, which are mentioned in the relationship with the light source, include (1) a semiconductor laser (wavelength: 830 nm, 532 nm, 488 nm, 405 nm, 375 nm, 355 nm, or the like); (2) a metal halide lamp; (3) a high-pressure mercury lamp, a g-line (wavelength: 436 nm), an h-line (wavelength: 405 nm), an i-line (wavelength: 365 nm), or broadband light (three wavelengths of the g, h, and i-line); (4) an excimer laser, a KrF excimer laser (wavelength: 248 nm), an ArF excimer laser (wavelength: 193 nm), or an F₂ excimer laser (wavelength: 157 nm); (5) an extreme ultraviolet (EUV) ray (wavelength: 13.6 nm); (6) an electron beam; and (7) a second harmonic wave of 532 nm and a third harmonic wave of 355 nm of a YAG laser.

As the wavelength of the exposure light, for example, any wavelength at which the photopolymerization initiator has sensitivity may be selected; however, an h-line (wavelength: 405 nm) or an i-line (wavelength: 365 nm) is preferable, and an i-line (wavelength: 365 nm) is more preferable.

The light absorbing agent may be a compound that generates a radical polymerization initiation species upon exposure; however, it is preferably a compound that does not generate a radical polymerization initiation species upon exposure from the viewpoint of resolution and chemical resistance.

Whether or not the light absorbing agent is a compound that generates a radical polymerization initiation species upon exposure is determined according to the following method.

A solution, which contains the light absorbing agent having the same concentration as the concentration of the compound contained in the resin composition and contains a radical crosslinking agent, is prepared. In a case where the resin composition contains a radical crosslinking agent, as the radical crosslinking agent in the solution, the same compound as the radical crosslinking agent contained in the resin composition is used at the same concentration. In a case where the resin composition does not contain a radical crosslinking agent, methyl methacrylate is used at a concentration 5 times that of the light absorbing agent.

Then, the irradiation with the exposure light is carried out. The exposure amount is 500 mJ in terms of the integrated amount.

After the exposure, the polymerization of the polymerizable compound is determined by, for example, high performance liquid chromatography, and in a case where the proportion of the molar amount of the polymerized polymerizable compound to the total molar amount of the polymerizable compound is 10% or less, it is determined that the light absorbing agent is a compound that does not generate a radical polymerization initiation species upon exposure.

The proportion of the molar amount is preferably 5% or less and more preferably 3% or less. In addition, the lower limit of the proportion of the molar amount is not particularly limited and may be 0%.

In a case where the resin composition is used for forming a photosensitive film, the wavelength of the exposure light may be any wavelength at which the photosensitive film is exposed.

In addition, the wavelength of the exposure light is preferably a wavelength at which the photopolymerization initiator contained in the resin composition has sensitivity.

Examples of the compound that generates a radical polymerization initiation species upon exposure include the same compound as the photoradical polymerization initiator described above. In a case where the composition contains a photoradical polymerization initiator as the light absorbing agent, the light absorbing agent shall be a light absorbing agent, where a radical species generated has the lowest polymerization initiation ability, and the photopolymerization initiator shall be the other ones.

Examples of the compound that does not generate a radical polymerization initiation species upon exposure include a photoacid generator, a photobase generator, and a coloring agent having a changed absorption wavelength upon exposure.

Among these, the light absorbing agent is preferably a naphthoquinone diazide compound or a coloring agent having a changed absorbance upon exposure, and it is more preferably a naphthoquinone diazide compound.

In addition, for example, it is also conceivable to use, as the light absorbing agent, a photoacid generator or photobase generator in combination with a compound of which an absorbance is reduced at the exposure wavelength depending on the pH.

### [Naphthoquinone Diazide Compound]

Examples of the naphthoquinone diazide compound include a compound of which an absorbance is reduced at an exposure wavelength due to generation of an indene carboxylic acid upon exposure, where a compound having a 1,2-naphthoquinone diazide structure is preferable.

The naphthoquinone diazide compound is preferably a naphthoquinone diazide sulfonic acid ester of a hydroxy compound.

The hydroxy compound is preferably a compound represented by any one of Formulae (H1) to (H6).

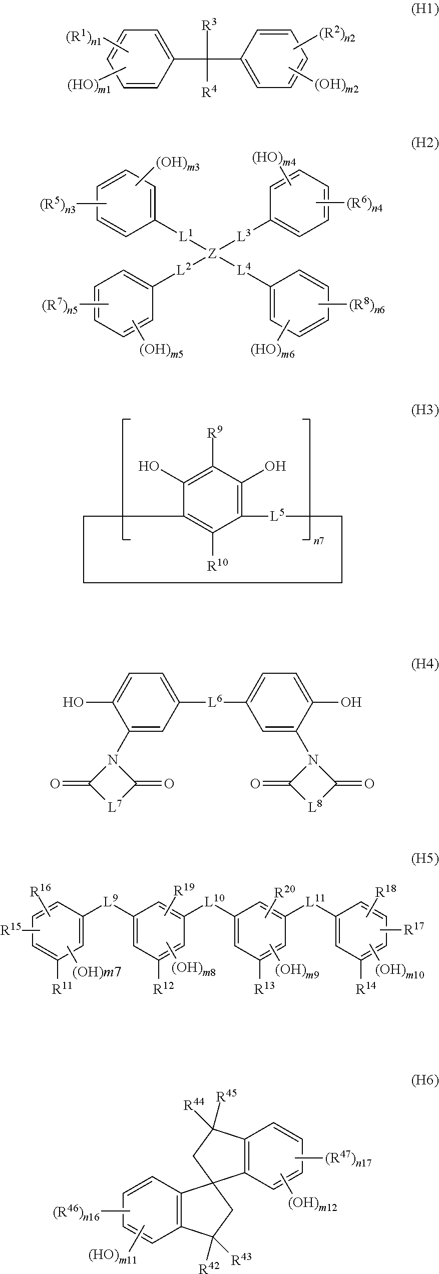

In Formula (H1), R¹ and R² each independently represent a monovalent organic group, R³ and R⁴ each independently represent a hydrogen atom or a monovalent organic group, and n1, n2, m1, and m2 are each independently an integer of 0 to 5, where at least one of m1 or m2 is an integer of 1 to 5.

In Formula (H2), Z represents a tetravalent organic group, L¹, L², L³, and L⁴ each independently represent a single bond or a divalent organic group, R⁵, R⁶, and R⁷ and R⁸ each independently represent a monovalent organic group, n3, n4, n5, and n6 are each independently an integer of 0 to 3, and m3, m4, m5, and m6 are each independently an integer of 0 to 2 where at least one of m3, m4, m5, or m6 is 1 or 2.

In Formula (H3), R⁹ and R¹⁰ each independently represent a hydrogen atom or a monovalent organic group, L⁵'s each independently represent a di valent organic group, and n7 represents an integer of 3 to 8.

In Formula (H4), L⁶ represents a divalent organic group, and L⁷ and L⁸ each independently represent a divalent organic group containing an aliphatic tertiary or quaternary carbon.

In Formula (H5), R¹¹, R¹², R¹³, R¹⁴, R¹⁵, R¹⁶, R¹⁷, R¹⁸, R¹⁹, and R²⁰ each independently represent a hydrogen atom, a halogen atom, or a monovalent organic group, L⁹, L¹⁰, and L¹¹ each independently represent a single bond or a divalent organic group, and m7, m8, m9, and m10 each independently represent an integer of 0 to 2, where at least one of m7, m8, m9, or m10 is 1 or 2.

In Formula (H6), R⁴², R⁴³, R⁴⁴, and R⁴⁵ each independently represent a hydrogen atom or a monovalent organic group, R⁴⁶ and R⁴⁷ each independently represent a monovalent organic group, n16 and n17 each independently represent an integer of 0 to 4, and m11 and m12 each independently represent an integer of 0 to 4, where at least one of m11 or m12 is an integer of 1 to 4.

In Formula (H1), R¹ and R² are each independently preferably a monovalent organic group having 1 to 60 carbon atoms, and more preferably a monovalent organic group having 1 to 30 carbon atoms. Examples of the monovalent organic group as R¹ and R² include a hydrocarbon group which may have a substituent, and examples of the hydrocarbon group include an aromatic hydrocarbon group which may have a substituent such as a hydroxy group.

In Formula (H1), R³ and R⁴ are each independently preferably a monovalent organic group having 1 to 60 carbon atoms, and more preferably a monovalent organic group having 1 to 30 carbon atoms. Examples of the monovalent organic group as R³ and R⁴ include a hydrocarbon group which may have a substituent, and examples of the hydrocarbon group include a hydrocarbon group which may have a substituent such as a hydroxy group.

In Formula (H1), n1 and n2 are each independently preferably 0 or 1, and more preferably 0.

In Formula (H1), both m1 and m2 are preferably 1.

The compound represented by Formula (H1) is preferably a compound represented by any one of Formulae (H1-1) to (H1-5).

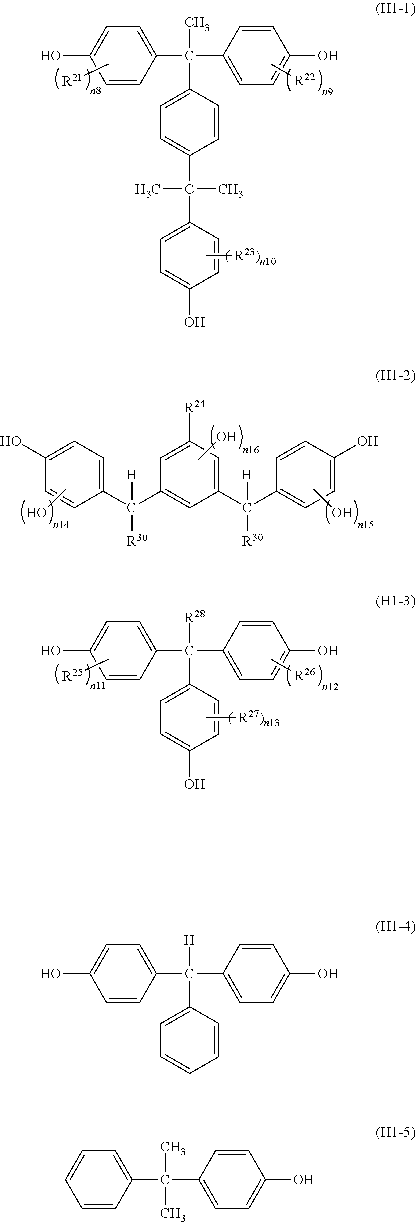

In Formula (H1-1), R²¹, R²², and R²³ each independently represent a hydrogen atom or a monovalent organic group, and it is preferably a hydrogen atom or a monovalent organic group having 1 to 20 carbon atoms, and more preferably a hydrogen atom or a group represented by Formula (R-1).

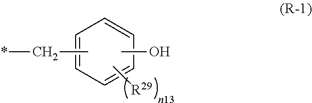

In Formula (R-1), R²⁹ represents a hydrogen atom, an alkyl group, or an alkoxy group, n13 represents an integer of 0 to 2, and * represents a bonding site to another structure.

In Formula (H1-1), n8, n9, and n10 each independently represent an integer of 0 to 2, where 0 or 1 is preferable.

In Formula (H1-2), R²⁴ represents a hydrogen atom or a monovalent organic group, and it is preferably a hydrogen atom, an alkyl group having 1 to 20 carbon atoms, or an alkoxy group having 1 to 20 carbon atoms. n14, n15, and n16 each independently represent an integer of 0 to 2. R³⁰ represents a hydrogen atom or an alkyl group.

In Formula (H1-3), R²⁵, R²⁶, R²⁷, and R²⁸ each independently represent a monovalent organic group, and they are preferably a hydrogen atom, an alkyl group, or a group represented by Formula (R-1).

In Formula (H1-3), n11, n12, and n13 each independently represent an integer of 0 to 2, where 0 or 1 is preferable.

The compound represented by Formula (H1-1) is preferably a compound represented by any one of Formulae (H1-1-1) to (H1-1-4).

The compound represented by Formula (H1-2) is preferably a compound represented by Formula (H1-2-1) or (H1-2-2).

The compound represented by Formula (H1-3) is preferably a compound represented by Formulae (H1-3-1) to (H1-3-3).

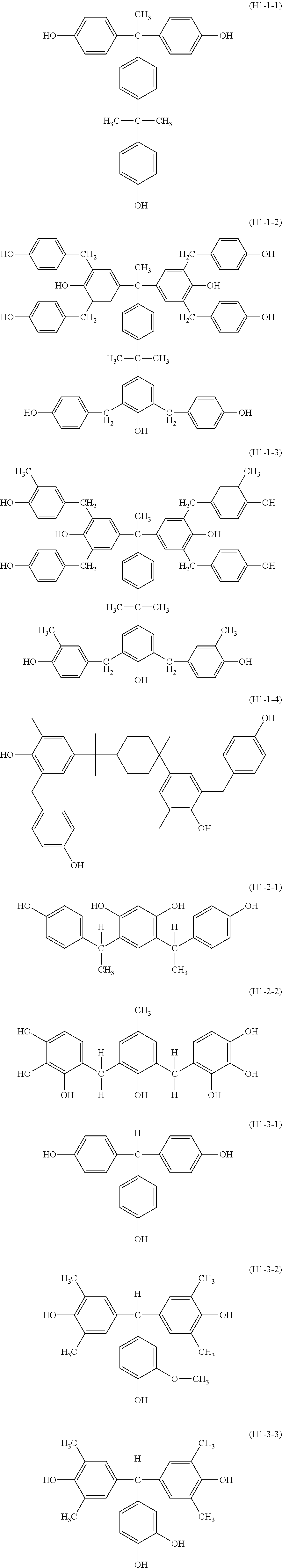

In Formula (H2), Z is preferably a tetravalent group having 1 to 20 carbon atoms, and more preferably a group represented by any one of Formulae (Z-1) to (Z-4). In Formulae (Z-1) to (Z-4), * represents a bonding site to another structure.

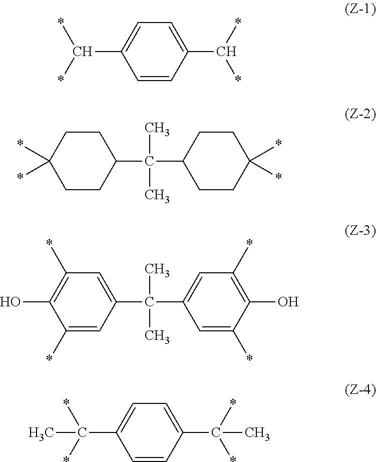

In Formula (H2), L¹, L², L³, and L⁴ are each independently preferably a single bond or a methylene group.

In Formula (H2), R⁵, R⁶, R⁷, and R⁸ are each independently preferably an organic group having 1 to 30 carbon atoms.

In Formula (H2), n3, n4, n5, and n6 are each independently preferably an integer of 0 to 2, and more preferably 0 or 1.

In Formula (H2), m3, m4, m5, and m6 are each independently preferably 1 or 2, and more preferably 1.

Examples of the compound represented by Formula (H2) include compounds having the following structures.

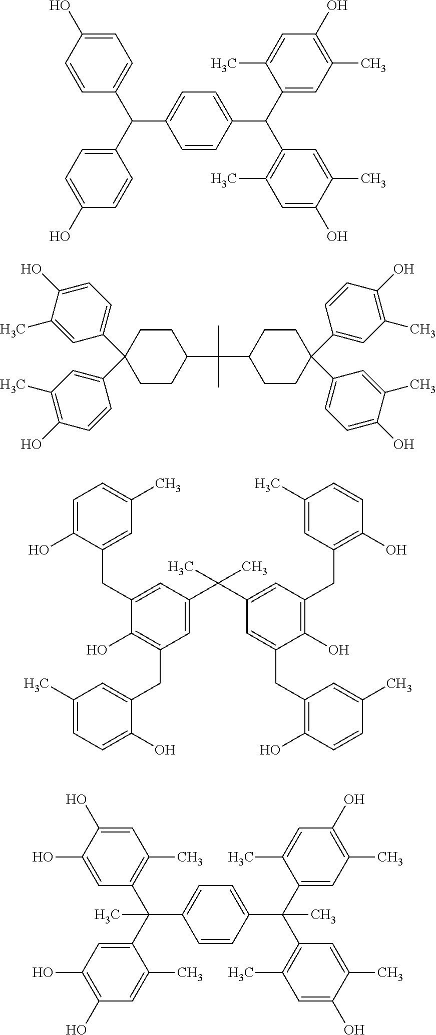

In Formula (H3), R⁹ and R¹⁰ each independently preferably represent a hydrogen atom or a monovalent organic group having 1 to 20 carbon atoms.

In Formula (H3), L⁵'s are each independently preferably a group represented by Formula (L-1).

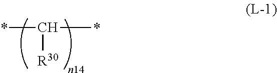

In Formula (L-1), R³⁰ represents a monovalent organic group having 1 to 20 carbon atoms, n14 represents an integer of 1 to 5, and * represents a bonding site to another structure.

In Formula (H3), n7 is preferably an integer of 4 to 6.

Examples of the compound represented by Formula (H3) include the following compounds. In the following Formula, n's each independently represent an integer of 0 to 9.

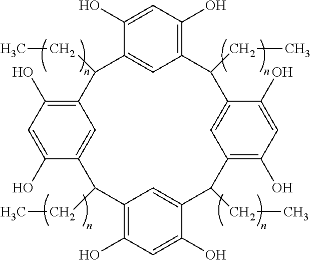

In Formula (H4), L⁶ is preferably —C(CF₃)₂—, —S(═O)₂—, or —C(═O)—.

In Formula (H4), L⁷ and L⁸ are each independently preferably a divalent organic group having 2 to 20 carbon atoms.

Examples of the compound represented by Formula (H4) include the following compounds.

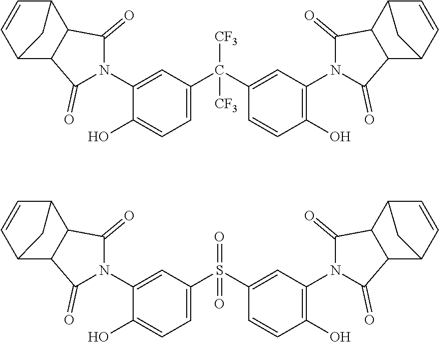

In Formula (H5), R¹¹, R¹², R¹³, R¹⁴, R¹⁵, R¹⁶, R¹⁷, R¹⁸, R¹⁹, and R²⁰ are each independently preferably a hydrogen atom, a halogen atom, an alkyl group, an alkenyl group, an alkoxy group, an allyl group, or an acyl group.

In Formula (H5), L⁹, L¹⁰, and L¹¹ are each independently preferably a single bond, —O—, —S—, —S(═O)₂—, —C(═O)—, —C(═O)O—, cyclopentylidene, cyclohexylidene, phenylene, or a divalent organic group having 1 to 20 carbon atoms, and they are more preferably a group represented by any one of Formula (L-2) to (L-4).

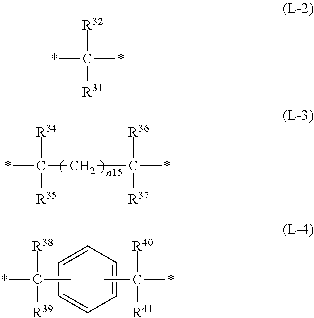

In Formulae (L-2) to (L-4), R³¹ and R³² each independently represent a hydrogen atom, an alkyl group, an alkenyl group, or an aryl group, R³⁴, R³⁵, R³⁶, and R³⁷ each independently represent a hydrogen atom or an alkyl group, n15 is an integer of 1 to 5, R³⁸, R³⁹, R⁴⁰, and R⁴¹ each independently represent a hydrogen atom or an alkyl group, and * represents a bonding site to another structure.

Examples of the compound represented by Formula (H5) include the following compounds.

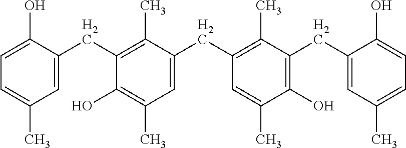

In Formula (H6), R⁴², R⁴³, R⁴⁴, and R⁴⁵ each independently represent a hydrogen atom or a monovalent organic group and are preferably a hydrogen atom or a monovalent organic group having 1 to 20 carbon atoms, more preferably a hydrogen atom or an alkyl group having 1 to 20 carbon atoms, and more preferably an alkyl group having 1 to 4 carbon atoms.

In Formula (H6), R⁴⁶ and R⁴⁷ are each independently preferably an alkyl group, an alkoxy group, or an aryl group, and more preferably an alkyl group.

In Formula (H6), n16 and n17 are each independently preferably an integer of 0 to 2, and more preferably 0 or 1.

In Formula (H6), n16 and n17 are each independently preferably an integer of 1 to 3, and more preferably 2 or 3.

Examples of the compound represented by Formula (H6) include the following compounds.

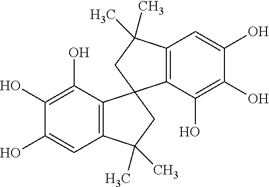 [SMILES: CC1(C)CC2(CC(C)(C)c3cc(O)c(O)c(O)c32)c2c1cc(O)c(O)c2O]

In addition, examples of the hydroxy compound include polyhydroxybenzophenones as 2,3,4-trihydroxybenzophenone, 2,4,4′-trihydroxybenzophenone, 2,3,4-trihydroxy-2′-methylbenzophenone, 2,4,6-trihydroxybenzophenone, 2,2′,4,4′-tetrahydroxybenzophenone, 2,3,4,4′-tetrahydroxybenzophenone, 2,3,4,2′,4′-pentahydroxybenzophenone, 2,4,6,3′,4′-pentahydroxybenzophenone, such 2,3,4,2′,5′-pentahydroxybenzophenone, 2,4,6,3′,4′,5′-hexahydroxybenzophenone, and 2,3,4,3′,4′,5′-hexahydroxybenzophenone; polyhydroxyphenylalkyl ketones such as 2,3,4-trihydroxyacetophenone, 2,3,4-trihydroxyphenylpentyl ketone, and 2,3,4-trihydroxyphenylhexyl ketone; bis((poly)hydroxyphenyl)alkanes such as bis(2,4-dihydroxyphenyl)methane, bis(2,3,4-trihydroxyphenyl)methane, bis(2,4-dihydroxyphenyl)propane-1, bis(2,3,4-trihydroxyphenyl)propane-1, nordihydroguaiaretic acid, and 1,1-bis(4-hydroxyphenyl)cyclohexane;
polyhydroxybenzenes such as 3,4,5-trihydroxybenzoic acid propyl, 2,3,4-trihydroxybenzoic acid phenyl, and 3,4,5-trihydroxybenzoic acid phenyl, bis(polyhydroxybenzoyl)alkanes or bis(polyhydroxybenzoyl)aryls such as bis(2,3,4-trihydroxybenzoyl)methane, bis(3-acetyl-4,5,6-trihydroxyphenyl)-methane, bis(2,3,4-trihydroxybenzoyl)benzene, and bis(2,4,6-trihydroxybenzoyl)benzene, alkylene-di(polyhydroxybenzoate) such as ethylene glycol-di(3,5-dihydroxybenzoate) or ethylene glycol-di(3,4,5-trihydroxybenzoate), polyhydroxybiphenyl such as 2,3,4-biphenyltriol, 3,4,5-biphenyltriol, 3,5,3′,5′-biphenyltetrol, 2,4,2′,4′-biphenyltetrol, 2,4,6,3′,5′-biphenylpentol, 2,4,6,2′,4′,6′-biphenylhexol, or 2,3,4,2′,3′,4′-biphenylhexol, bis(polyhydroxy)sulfide such as 4,4′-thiobis(1,3-dihydroxy)benzene, bis(polyhydroxyphenyl) ether,
bis(polyhydroxyphenyl)ethers such as 2,2′,4,4′-tetrahydroxydiphenyl ether, bis(polyhydroxyphenyl)sulfoxides such as 2,2′,4,4′-tetrahydroxydiphenyl sulfoxide, bis(polyhydroxyphenyl)sulfones such as 2,2′,4,4′-diphenyl sulfone, polyhydroxytriphenylmethanes such as tris(4-hydroxyphenyl)methane, 4,4′,4″-trihydroxy-3,5,3′,5′-tetramethyltriphenylmethane, 4,4′,3″,4″-tetrahydroxy-3,5,3′,5′-tetramethyltriphenylmethane, 4-[bis(3,5-dimethyl-4-hydroxyphenyl)methyl]-2-methoxy-phenol, 4,4′-(3,4-diol-benzylidene)bis[2,6-dimethylphenol], 4,4′-[(2-hydroxy-phenyl)methylene]bis[2-cyclohexyl-5-methyl]phenol, 4,4′,2″,3″,4″-pentahydroxy-3,5,3′,5′-trimethyltriphenylmethane, 2,3,4,2′,3′,4′-hexahydroxy-5,5′-diacetyltriphenylmethane, 2,3,4,2′,3′,4′,3″,4″-octahydroxy-5,5′-diacetyltriphenylmethane, 2,4,6,2′,4′,6′-hexahydroxy-5,5′-dipropionyltriphenylmethane, and polyhydroxytriphenylethanes such as 4,4′-(phenylmethylene)bisphenol, 4,4′-(1-phenyl-ethylidene)bis[2-methylphenol], 4,4′,4″-ethylidene-trisphenol,
polyhydroxyspirobiindanes such as 3,3,3′,3′-tetramethyl-1,1′-spirobiindane-5,6,5′,6′-tetrol, 3,3,3′,3′-tetramethyl-1,1′-spirobiindane-5,6,7,5′,6′,7′-hexool, 3,3,3′,3′-tetramethyl-1,1′-spirobiindane-4,5,6,4′,5′,6′-hexool, and 3,3,3′,3′-tetramethyl-1,1′-spirobiindane-4,5,6,5′,6′,7′-hexool, polyhydroxyflavans such as 2,4,4-trimethyl-2′,4′,7′-trihydroxyflavan, polyhydroxyphthalides such as 3,3-bis(3,4-dihydroxyphenyl)phthalide, 3,3-bis(2,3,4-trihydroxyphenyl)phthalide, and 3′,4′,5′,6′-tetrahydroxyspiro[phthalido-3,9′-xanthene], flavonoid coloring agents such as morin, quercetin, and rutin,
α,α′,α″-tris(4-hydroxyphenyl) 1,3,5-triisopropylbenzene, α,α′,α″-tris(3,5-dimethyl-4-hydroxyphenyl) 1,3,5-triisopropylbenzene, α,α′,α″-tris(3,5-diethyl-4-hydroxyphenyl) 1,3,5-triisopropylbenzene, α,α′,α″-tris(3,5-di-n-propyl-4-hydroxyphenyl) 1,3,5-triisopropylbenzene, α,α′,α″-tris(3,5-diisopropyl-4-hydroxyphenyl) 1,3,5-triisopropylbenzene, α,α′,α″-tris(3,5-di-n-butyl-4-hydroxyphenyl) 1,3,5-triisopropylbenzene, α,α′,α″-tris(3-methyl-4-hydroxyphenyl) 1,3,5-triisopropylbenzene, α,α′,α″-tris(3-methoxy-4-hydroxyphenyl) 1,3,5-triisopropylbenzene, α,α′,α″-tris(2,4-dihydroxyphenyl) 1,3,5-triisopropylbenzene, 1,3,5-tris(3,5-dimethyl-4-hydroxyphenyl)benzene, 1,3,5-tris(5-methyl-2-hydroxyphenyl)benzene, 2,4,6-tris(3,5-dimethyl-4-hydroxyphenylthiomethyl)mesitylene, polyhydroxy compounds described in JP1992-253058A (JP-H4-253058A) such as 1-[α-methyl-α-(4′-hydroxyphenyl)ethyl]-4-[α,α′-bis(4″-hydroxyphenyl)ethyl]benzene, 1-[α-methyl (4′-hydroxyphenyl)ethyl]-3-[α,α′-bis(4″-hydroxyphenyl)ethyl]benzene, 1-[α-methyl-α-(3′,5′-dimethyl-4′-hydroxyphenyl)ethyl]-4-[α,α′-bis(3″,5″-dimethyl-4″-hydroxy phenyl)ethyl]benzene, 1-[α-methyl (3′-methyl-4′-hydroxyphenyl)ethyl]-4-[α′,α′-bis(3″-methyl-4″-hydroxyphenyl)ethyl]benzene, 1-[α-methyl-α-(3′-methoxy-4′-hydroxyphenyl)ethyl]-4-[α′,α′-bis(3″-methoxy-4″-hydroxyphenyl)ethyl]benzene, 1-[α-methyl-α-(2′,4′-dihydroxyphenyl)ethyl]-4-[α′,α′-bis(4″-hydroxyphenyl)ethyl]benzene, and 1-[α-methyl (2′,4′-dihydroxyphenyl)ethyl]-3-[α′,α′-bis(4″-hydroxyphenyl)ethyl]benzene, polyhydroxy compounds described in JP1993-224410A (JP-H5-224410A) such as α,α,α′,α′,α″,α″-hexakis-(4-hydroxyphenyl)-1,3,5-triethylbenzene, and poly(hydroxyphenyl)alkanes described in JP1993-303200A (JP-H5-303200A) and EP-530148 such as 1,2,2,3-tetra(p-hydroxyphenyl)propane and 1,3,3,5-tetra(p-hydroxyphenyl)pentane, p-bis(2,3,4-trihydroxybenzoyl)benzene, p-bis(2,4,6-trihydroxybenzoyl)benzene, m-bis(2,4,6-trihydroxybenzoyl)benzene, m-bis(2,3,4-trihydroxybenzoyl)benzene, p-bis(2,5-dihydroxy-3-bromobenzoyl)benzene, p-bis(2,3,4-trihydroxy-5-methylbenzoyl)benzene, p-bis(2,3,4-trihydroxy-5-methoxybenzoyl)benzene, p-bis(2,3,4-trihydroxy-5-nitrobenzoyl)benzene, p-bis(2,3,4-trihydroxy-5-cyanobenzoyl)benzene, 1,3,5-tris(2,5-dihydroxybenzoyl)benzene, 1,3,5-tris(2,3,4-trihydroxybenzoyl)benzene, 1,2,3-tris(2,3,4-trihydroxybenzoyl)benzene, 1,2,4-tris(2,3,4-trihydroxybenzoyl)benzene, 1,2,4,5-tetrakis(2,3,4-trihydroxybenzoyl)benzene, α,α′-bis(2,3,4-trihydroxybenzoyl)p-xylene, α,α′,α′-tris(2,3,4-trihydroxybenzoyl)mesitylene, 2,6-bis-(2-hydroxy-3,5-dimethylbenzyl)-p-cresol, 2,6-bis-(2-hydroxy-5′-methylbenzyl)-p-cresol, 2,6-bis-(2,4,6-trihydroxybenzyl)-p-cresol, 2,6-bis-(2,3,4-trihydroxybenzyl)-p-cresol, 2,6-bis(2,3,4-trihydroxybenzyl)-3,5-dimethyl-phenol, 4,6-bis-(4-hydroxy-3,5-dimethylbenzyl)-pyrogallol, 2,6-bis-(4-hydroxy-3,5-dimethylbenzyl)-1,3,4-trihydroxy-phenol, 4,6-bis-(2,4,6-trihydroxybenzyl)-2,4-dimethyl-phenol, 4,6-bis-(2,3,4-trihydroxybenzyl)-2,5-dimethyl-phenol, 2,6-bis-(4-hydroxybenzyl)-p-cresol, 2,6-bis(4-hydroxybenzyl)-4-cyclohexylphenol, 2,6-bis(4-hydroxy-3-methylbenzyl)-p-cresol, 2,6-bis(4-hydroxy-3,5-dimethylbenzyl)-p-cresol, 2,6-bis(4-hydroxy-2,5-dimethylbenzyl)-p-cresol, 2,6-bis(4-hydroxy-3-methylbenzyl)-4-phenyl-phenol, 2,2′,6,6′-tetrakis[(4-hydroxyphenyl)methyl]-4,4′-methylenediphenol, 2,2′,6,6′-tetrakis[(4-hydroxy-3,5-dimethylphenyl)methyl]-4,4′-methylenediphenol, 2,2′,6,6′-tetrakis[(4-hydroxy-3-methylphenyl)methyl]-4,4′-methylenediphenol, 2,2′-bis[(4-hydroxy-3,5-dimethylphenyl)methyl] 6,6′-dimethyl-4,4′-methylenediphenol, 2,2′,3,3′-tetrahydro-3,3,3′,3′-tetramethyl-1,1′-spiro-bi (1H-indene)-5,5′,6,6′,7,7′-hexanol, and bis(4-hydroxy-3,5-dimethylphenyl)-(4-hydroxy-3-methoxyphenyl)methane.

In addition, a hyponuclear form of a phenol resin, such as a novolak resin, can also be used.

Examples of the naphthoquinone diazide sulfonic acid include 6-diazo 5,6-dihydro-5-oxo-1-naphthalenesulfonic acid and 1,2-naphthoquinone-(2)-diazo-5-sulfonic acid, where these may be mixedly used.

A production method for a naphthoquinone diazide sulfonic acid ester of a hydroxy compound is not particularly limited. However, it is obtained, for example, by converting naphthoquinone diazide sulfonic acid into a sulfonyl chloride with chlorosulfonic acid or thionyl chloride, and subjecting the obtained naphthoquinone diazide sulfonyl chloride to a condensation reaction with the hydroxy compound.

For example, it can be obtained by subjecting a hydroxy compound and a predetermined amount of naphthoquinone diazide sulfonyl chloride to a reaction in a solvent such as dioxane, acetone, or tetrahydrofuran, in the presence of a basic catalyst such as triethylamine to carry out esterification, washing the obtained product with water, and carrying out drying.

The esterification rate for the naphthoquinone diazide sulfonic acid ester is not particularly limited; however, it is preferably 10% or more, and more preferably 20% or more. The upper limit of the esterification rate is not particularly limited and may be 100%.

The esterification rate can be checked by ¹H-NMR or the like as a proportion of the esterified groups among the hydroxy groups contained in the hydroxy compound.

In addition, as the light absorbing agent, compounds described in paragraphs 0088 to 0108 of JP2019-206689A can also be used.

The content of the light absorbing agent with respect to the total solid content of the resin composition according to the embodiment of the present invention is not particularly limited, but is preferably 0.1% to 20% by mass, more preferably 0.5% to 10% by mass, and still more preferably 1% to 5% by mass.

### <Polymerization Inhibitor>

The resin composition according to the embodiment of the present invention preferably contains a polymerization inhibitor. Examples of the polymerization inhibitor include a phenol-based compound, a quinone-based compound, an amino-based compound, an N-oxyl-free radical-based compound, a nitro-based compound, a nitroso-based compound, a heteroaromatic ring-based compound, and a metal compound.

Specific examples of the compound of the polymerization inhibitor include the compounds described in paragraph 0310 of WO2021/112189A, p-hydroquinone, o-hydroquinone, a 4-hydroxy-2,2,6,6-tetramethylpiperidine-1-oxyl free radical, phenoxazine, and 1,4,4-trimethyl-2,3-diazabicyclo[3.2.2]nona-2-en-N,N-dioxide. The content thereof is incorporated in the present specification.

In a case where the resin composition according to the embodiment of the present invention has a polymerization inhibitor, the content of the polymerization inhibitor is preferably 0.01% to 20% by mass, more preferably 0.02% to 15% by mass, and still more preferably 0.05% to 10% by mass, with respect to the total solid content of the resin composition.

Only one kind of polymerization inhibitor may be used, or two or more kinds thereof may be used. In a case where two or more kinds of polymerization inhibitors are used, the total thereof is preferably within the above-described range.

### <Other Additives>

The resin composition according to the embodiment of the present invention may contain various additives as necessary, for example, a surfactant, a higher fatty acid derivative, a thermal polymerization initiator, inorganic particles, an ultraviolet absorbing agent, an organic titanium compounds, an antioxidant, a photoacid generator, an aggregation inhibitor, a phenol-based compound, another polymer compound, a plasticizer, and other auxiliary agents (for example, an anti-foaming agent, and a flame retardant) within the scope in which the effect of the present invention is obtained. By appropriately containing these components, properties such as film properties can be adjusted. The details of the components can be found in, for example, paragraph “0183” and subsequent paragraphs of JP2012-003225A (corresponding to paragraph 0237 of US2013/0034812A) and paragraphs 0101 to 0104 and 0107 to 0109 of JP2008-250074A, the contents of which are incorporated in the present specification. In a case where these additives are blended, the total content thereof is preferably 3% by mass or less of the solid content of the resin composition according to the embodiment of the present invention.

### [Organic Titanium Compound]

In a case where the resin composition contains an organic titanium compound, it is possible to form a resin layer having excellent chemical resistance even in a case where curing is carried out at a low temperature.

Examples of the usable organic titanium compound include those in which an organic group is bonded to a titanium atom through a covalent bond or an ionic bond.

Specific examples of the organic titanium compound are described in I) to VII) below.
I) Titanium chelate compounds: a titanium chelate compound having two or more alkoxy groups is more preferable since the resin composition has good storage stability and a good curing pattern is obtained. Specific examples thereof include titanium bis(triethanolamine)diisopropoxide, titanium di(n-butoxide) bis(2,4-pentanedionate), titanium diisopropoxide bis(2,4-pentanedionate), titanium diisopropoxide bis(tetramethylheptandionate), and titanium diisopropoxide bis(ethyl acetoacetate).
II) Tetraalkoxytitanium compounds: examples thereof include titanium tetra(n-butoxide), titanium tetraethoxide, titanium tetra(2-ethylhexoxide), titanium tetraisobutoxide, titanium tetraisopropoxide, titanium tetramethoxide, titanium tetramethoxypropoxide, titanium tetramethylphenoxide, titanium tetra(n-nonyloxide), titanium tetra(n-propoxide), titanium tetrastearyloxide, and titanium tetrakis[bis {2,2-(aryloxymethyl)butoxide}].
III) Titanocene compounds: examples thereof include pentamethylcyclopentadienyl titanium trimethoxide, bis(η5-2,4-cyclopentadien-1-yl)bis(2,6-difluorophenyl)titanium, and bis(η5-2,4-cyclopentadien-1-yl)bis(2,6-difluoro-3-(1H-pyrrol-1-yl)phenyl)titanium.
IV) Monoalkoxytitanium compounds: examples thereof include titanium tris(dioctyl phosphate)isopropoxide, and titanium tris(dodecylbenzene sulfonate)isopropoxide.
V) Titanium oxide compounds: examples thereof include titanium oxide bis(pentanedionate), titanium oxide bis(tetramethylheptandionate), and phthalocyanine titanium oxide.
VI) Titanium tetraacetylacetonate compounds: examples thereof include titanium tetraacetylacetonate.
VII) Titanate coupling agents: examples thereof include isopropyltridodecylbenzenesulfonyl titanate.

Among these, it is preferable that the organic titanium compound is at least one compound selected from the group consisting of the above-described I) titanium chelate compound, II) tetraalkoxytitanium compound, and III) titanocene compound, from the viewpoint of more favorable chemical resistance. In particular, titanium diisopropoxide bis(ethyl acetoacetate), titanium tetra(n-butoxide), or bis(η5-2,4-cyclopentadiene-1-yl) bis(2,6-difluoro-3-(1H-pyrrole-1-yl)phenyl)titanium is preferable.

In addition, it is also preferable that a compound represented by Formula (T-1) is contained as the organic titanium compound or instead of the organic titanium compound.

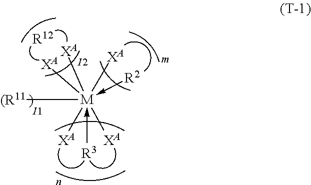

In Formula (T-1), M is titanium, zirconium, or hafnium, 11 is an integer of 0 to 2, 12 is 0 or 1, 11+12× 2 is an integer of 0 to 2, m is an integer of 0 to 4, n is an integer of 0 to 2, 11+12+m+n×2=4 is satisfied, R¹¹'s are each independently a substituted or unsubstituted cyclopentadienyl group, a substituted or unsubstituted alkoxy group, or a substituted or unsubstituted phenoxy group, R¹² is a substituted or unsubstituted hydrocarbon group, R²'s are each independently a group including a structure represented by Formula (T-2), R³'s are each independently a group including a structure represented by Formula (T-2), and X^{A}'s are each independently an oxygen atom or a sulfur atom.

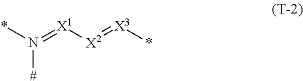

In Formula (T-2), X¹ to X³ each independently represent —C(—*)═ or —N═, *'s each represent a bonding site to another structure, and #represents a bonding site to a metal atom.

In Formula (T-1), it is preferable that M represents titanium from the viewpoint of the storage stability of the composition.

An aspect in which 11 and 12 in Formula (T-1) are 0 is also one of the preferred aspects of the present invention.

In Formula (T-1), m is preferably 2 or 4, and more preferably 2.

In Formula (T-1), n is preferably 1 or 2, and more preferably 1.

Here, in Formula (T-1), it is also preferable that 11 and 12 are 0 and m is 0, 2, or 4.

In Formula (T-1), R¹¹ is preferably a substituted or unsubstituted cyclopentadienyl ligand from the viewpoint of the stability of the specific metal complex.

In addition, the cyclopentadienyl group, the alkoxy group, and the phenoxy group as R¹¹ may be substituted; however, an aspect in which these are unsubstituted is also one of the preferred aspects of the present invention.

In Formula (T-1), R¹² is preferably a hydrocarbon group having 1 to 20 carbon atoms and more preferably a hydrocarbon group having 2 to 10 carbon atoms.

The hydrocarbon group as R¹² may be any of an aliphatic hydrocarbon group or an aromatic hydrocarbon group; however, it is preferably an aromatic hydrocarbon group.

The aliphatic hydrocarbon group may be a saturated aliphatic hydrocarbon group or an unsaturated aliphatic hydrocarbon group; however, it is preferably a saturated aliphatic hydrocarbon group.

The aromatic hydrocarbon group is preferably an aromatic hydrocarbon group having 6 to 20 carbon atoms, more preferably an aromatic hydrocarbon group having 6 to 10 carbon atoms, and still more preferably a phenylene group.

The substituent as R¹² is preferably a monovalent substituent, and examples thereof include a halogen atom. In addition, in a case where R¹² is an aromatic hydrocarbon group, it may have an alkyl group as a substituent.

Among these, in Formula (T-1), R¹² is preferably an unsubstituted phenylene group. In addition, the phenylene group as R¹² is preferably a 1,2-phenylene group.

In Formula (T-1), in a case where m is 2 or more and two or more R²'s contained, the structures of the two or more R²'s may be the same or different from each other.

In Formula (T-1), in a case where n is 2 or more and two or more R³'s contained, the structures of the two or more R³'s may be the same or different from each other.

In Formula (T-2), X¹ to X³ each independently represent —C(—*)═ or —N═. It is preferable that at least one thereof represents —C(—*)═, and it is more preferable that at least two thereof represent —C(—*)═.

Specific examples of the compound represented by Formula (T-1) include compounds corresponding to I-5 to I-8 in Examples, but the present invention is not limited thereto.

In a case of containing an organic titanium compound, the content thereof is preferably 0.05 to 10 parts by mass and more preferably 0.1 to 5 parts by mass with respect to 100 parts by mass of the specific resin. In a case where the content thereof is 0.05 parts by mass or more, the heat resistance and the chemical resistance of the cured pattern to be obtained are further improved, and in a case where the content thereof is 10 parts by mass or less, the storage stability of the composition is more excellent.

In a case of containing an organic titanium compound, the content thereof is preferably 0.05 to 10 parts by mass and more preferably 0.1 to 2 parts by mass with respect to 100 parts by mass of the specific resin. In a case where the content thereof is 0.05 parts by mass or more, the heat resistance and the chemical resistance of the cured pattern to be obtained are further improved, and in a case where the content thereof is 10 parts by mass or less, the storage stability of the composition is more excellent.

Examples of the other additives include the compounds described in paragraphs 0316 to 0358 of WO2022/145355A. The above description is incorporated in the present specification.

### <Characteristics of Resin Composition>

The viscosity of the resin composition according to the embodiment of the present invention can be adjusted by adjusting the concentration of solid contents of the resin composition. From the viewpoint of the coating film thickness, it is preferably 1,000 mm²/s to 12,000 mm²/s, more preferably 2,000 mm²/s to 10,000 mm²/s, and still more preferably 2,500 mm²/s to 8,000 mm²/s. Within the above range, it is easy to obtain a coating film having high uniformity. In a case of being 1,000 mm²/s or more, it is easy to carry out coating at a film thickness to be required as, for example, an insulating film for re-distribution of a wiring line, and in a case of being 12,000 mm²/s or less, a coating film having an excellent coating surface shape is obtained.

### <Restrictions on Substances Contained in Resin Composition>

The moisture content of the resin composition according to the embodiment of the present invention is preferably less than 2.0% by mass, more preferably less than 1.5% by mass, and still more preferably less than 1.0% by mass. In a case of being less than 2.0%, the storage stability of the resin composition is improved.

Examples of the method of maintaining the moisture content include adjusting the humidity under storage conditions and reducing the void ratio of the storage container during storage.

From the viewpoint of insulating properties, the metal content of the resin composition according to the embodiment of the present invention is preferably less than 5 parts per million (ppm) by mass, more preferably less than 1 ppm by mass, and still more preferably less than 0.5 ppm by mass. Examples of the metal include sodium, potassium, magnesium, calcium, iron, copper chromium, and nickel, however, a metal contained as a complex of an organic compound and a metal is excluded. In a case where a plurality of metals are contained, the total of these metals is preferably within the above-described range.

In addition, as a method of reducing metal impurities which are unintentionally contained in the resin composition according to the embodiment of the present invention, a method of selecting a raw material containing a low metal content as the raw material that constitutes the resin composition according to the embodiment of the present invention, a method of filtering a raw material constituting the resin composition according to the embodiment of the present invention, a method of distilling under the conditions in which the inside of the device is lined with polytetrafluoroethylene or the like to suppress the contamination as little as possible, and the like can be mentioned.

In the resin composition according to the embodiment of the present invention, in a case of considering the use application as a semiconductor material, the content of halogen atoms is preferably less than 500 ppm by mass, more preferably less than 300 ppm by mass, and still more preferably less than 200 ppm by mass, from the viewpoint of wire corrosiveness. Among these, in a case of being present in a halogen ion state, the content is preferably less than 5 ppm by mass, more preferably less than 1 ppm by mass, and still more preferably less than 0.5 ppm by mass. Examples of the halogen atom include a chlorine atom and a bromine atom. It is preferable that the total content of the chlorine atom and the bromine atom, or the total content of the chlorine ion and the bromine ion is within the above-described range.

Preferred examples of the method of adjusting the content of halogen atoms include ion exchange treatment.

A storage container publicly known in the related art can be used as a storage container for the resin composition according to the embodiment of the present invention. As the storage container, for the intended purpose of suppressing the incorporation of impurities into the raw materials and the resin composition according to the embodiment of the present invention, a multilayer bottle in which an inner wall of a container is composed of six kinds of six layers of resin, and a bottle with six kinds of resin being made as a seven-layer structure are preferably used. Examples of such a container include the container described in JP2015-123351A.

### <Cured Substance of Resin Composition>

In a case of curing the resin composition according to the embodiment of the present invention, it is possible to obtain a cured substance of the resin composition.

The cured substance according to the embodiment of the present invention is a cured substance formed by curing the resin composition.

The curing of the resin composition is preferably carried out by heating. The heating temperature is more preferably 120° C. to 400° C., still more preferably 140° C. to 380° C., and particularly preferably 170° C. to 350° C. The form of the cured substance of the resin composition is not particularly limited and can be selected depending on the use application, where the form includes a film shape, a rod shape, a spherical shape, a pellet shape, and the like. In the present invention, the cured substance preferably has a film shape. The shape of the cured substance can also be selected depending on the use application by the pattern processing of the resin composition, where the use application includes the formation of a protective film on a wall surface, formation of via holes for conduction, adjustment of impedance, electrostatic capacity, or internal stress, impartment of heat radiation function, and the like. The film thickness of the cured substance (the film consisting of the cured substance) is preferably 0.5 μm or more and 150 μm or less.

The shrinkage ratio of the resin composition according to the embodiment of the present invention after curing is preferably 50% or less, more preferably 45% or less, and still more preferably 40% or less. Here, the shrinkage ratio refers to a percentage of a change in the volume of the resin composition before and after curing, and it can be calculated according to the following expression.

$$Shrinkage ratio [ \% ] = 100 - ( volume after curing / volume before curing ) \times 100$$

### <Characteristics of Cured Substance of Resin Composition>

The imidization reaction rate of the cured substance of the resin composition according to the embodiment of the present invention is preferably 70% or more, more preferably 80% or more, and still more preferably 90% or more. In a case of being 70% or more, a cured substance having excellent mechanical properties may be obtained.

The breaking elongation of the cured substance of the resin composition according to the embodiment of the present invention is preferably 30% or more, more preferably 40% or more, and still more preferably 50% or more.

The glass transition temperature (Tg) of the cured substance of the resin composition according to the embodiment of the present invention is preferably 180° C. or higher, more preferably 210° C. or higher, and still more preferably 230° C. or higher.

### <Preparation of Resin Composition>

The resin composition according to the embodiment of the present invention can be prepared by mixing the above-described components. The mixing method is not particularly limited, and mixing can be carried out by methods publicly known in the related art.

Examples of the mixing method include mixing with a stirring blade, mixing with a ball mill, and mixing by rotating a tank.

The temperature during the mixing is preferably 10° C. to 30° C., and more preferably 15° C. to 25° C.

It is preferable to carry out filtration using a filter for the intended purpose of removing foreign substances such as dust and fine particles in the resin composition according to the embodiment of the present invention. The filter pore diameter is, for example, preferably 5 μm or less, more preferably 1 μm or less, still more preferably 0.5 μm or less, and even still more preferably 0.1 μm or less. The material of the filter is preferably polytetrafluoroethylene, polyethylene, or nylon. In a case where the material of the filter is polyethylene, it is more preferable to use high density polyethylene (HDPE). As the filter, a filter which has been washed with an organic solvent in advance may be used. In the filtration step using the filter, a plurality of kinds of filters may be connected in series or in parallel and used. In a case where a plurality of kinds of filters are used, filters having different pore diameters or different materials may be used in combination. Examples of the connection aspect include an aspect in which an HDPE filter having a pore diameter of 1 μm is connected in series as the first stage and an HDPE filter having a pore diameter of 0.2 μm is connected in series as the second stage. In addition, various materials may be filtered a plurality of times. In a case of being filtered a plurality of times, circulation filtration may be used. In addition, filtration may be carried out under pressure. In a case of carrying out pressurization to carry out filtration, the pressure for pressurization is, for example, preferably 0.01 MPa or more and 1.0 MPa or less, more preferably 0.03 MPa or more and 0.9 MPa or less, still more preferably 0.05 MPa or more and 0.7 MPa or less, and even still more preferably 0.05 MPa or more and 0.5 MPa or less.

In addition to filtration using a filter, impurity removal treatment using an adsorbing material may be carried out. The filtration using a filter and the impurity removal treatment using an adsorbing material may be combined. As the adsorbing material, a publicly known adsorbing material can be used. Examples thereof include an inorganic adsorbing material such as silica gel and zeolite and an organic adsorbing material such as activated carbon.

After filtration using a filter, a step of placing a bottle filled with the resin composition under reduced pressure to carry out degassing may be provided.

### (Manufacturing Method for Cured Substance)

The manufacturing method for a cured substance according to the embodiment of the present invention preferably includes a film forming step of applying a resin composition onto a base material to form a film.

The manufacturing method for a cured substance more preferably includes the above-described film forming step, an exposure step of selectively exposing the film formed by the film forming step, and a development step of developing the film exposed by the exposure step using a developer to form a pattern.

It is particularly preferable that the manufacturing method for a cured substance includes the film forming step, the exposure step, the development step, and at least one of a heating step of heating a pattern obtained by the development step or a post-development exposure step of exposing the pattern obtained by the development step.

In addition, it is also preferable that the manufacturing method for a cured substance includes the above-described film forming step and a step of heating the film.

Hereinafter, details of each step will be described.

### <Film Forming Step>

The resin composition according to the embodiment of the present invention can be applied onto a base material, thereby being used in a film forming step of forming a film.

The manufacturing method for a cured substance according to the embodiment of the present invention preferably includes a film forming step of applying a resin composition onto a base material to form a film.

### [Base Material]

The kind of the base material can be appropriately determined depending on the use application and is not particularly limited. Examples of the base material include a base material for semiconductor production, such as silicon, silicon nitride, polysilicon, silicon oxide, or amorphous silicon, quartz, glass, an optical film, a ceramic material, a vapor-deposited film, a magnetic film, a reflective film, a metal base material (for example, it may be any one of a base material formed from a metal or a base material having a metal layer formed by plating, vapor deposition, or the like) such as Ni, Cu, Cr, or Fe, paper, spin-on-glass (SOG), a thin film transistor (TFT) array base material, a mold base material, and an electrode plate of a plasma display panel (PDP). In particular, the base material is preferably a base material for semiconductor production, and more preferably a silicon base material, a Cu base material, or a mold base material.

A layer such as an intimate attachment layer made of hexamethyl disilazane (HMDS) or the like, or an oxide layer may be provided on the surface of these base materials.

The shape of the base material is not particularly limited, and it may be a circular shape or may be a rectangular shape.

In a case where the base material has a circular shape, the size of the base material is, for example, preferably a diameter of 100 to 450 mm and more preferably 200 to 450 mm. In a case of a rectangular shape, the length of the short side is, for example, preferably 100 to 1,000 mm and more preferably 200 to 700 mm.

As the base material, for example, a base material having a plate shape and preferably a base material (a substrate) having a panel shape are used.

In a case where the resin composition is applied to form a film on a surface of a resin layer (for example, a layer consisting of a cured substance) or on a surface of a metal layer, the resin layer or the metal layer serves as the base material.

The means for applying the resin composition onto a base material is preferably coating.

Specific examples of the means for application include a dip coating method, an air knife coating method, a curtain coating method, a wire bar coating method, a gravure coating method, an extrusion coating method, a spray coating method, a spin coating method, a slit coating method, and an ink jet method. From the viewpoint of the uniformity of the film thickness, a spin coating method, a slit coating method, a spray coating method, or an ink jet method is more preferable, and from the viewpoint of the uniformity of the film thickness and the viewpoint of productivity, a spin coating method or a slit coating method is more preferable. A film having a desired thickness can be obtained by adjusting the concentration of solid contents of the resin composition and application conditions according to the means to be applied. In addition, the coating method can be appropriately selected depending on the shape of the base material. In a case where a circular base material such as a wafer is used, a spin coating method, a spray coating method, an ink jet method, or the like is preferable, and in a case where a rectangular base material is used, a slit coating method, a spray coating method, an ink jet method, or the like is preferable. For example, the spin coating method can be applied at a rotation speed of 500 to 3,500 rpm for about 10 seconds to 3 minutes.

In addition, it is also possible to apply a method of transferring a coating film formed in advance on a temporary support by the above-described coating method, onto a base material.

Regarding the transfer method, the production methods described in paragraphs 0023 and 0036 to 0051 of JP2006-023696A and paragraphs 0096 to 0108 of JP2006-047592A can also be suitably used.

In addition, a step of removing an unnecessary film at the end part of the base material may be carried out. Examples of such a step include edge bead rinsing (EBR) and back rinsing.

A pre-wetting step of applying various solvents onto the base material before applying the resin composition onto the base material to improve the wettability of the base material and then applying the resin composition may be adopted.

### <Drying Step>

The above film may be subjected to a step (a drying step) of drying the film (or the layer) formed for removing the solvent, after the film forming step (the layer forming step).

That is, the manufacturing method for a cured substance according to the embodiment of the present invention may include a drying step of drying the film formed by the film forming step.

It is preferable that the drying step is carried out after the film forming step and before the exposure step.

The drying temperature of the film in the drying step is preferably 50° C. to 150° C., more preferably 70° C. to 130° C., and still more preferably 90° C. to 120° C. In addition, the drying may be carried out by reducing the pressure. Examples of the drying time include 30 seconds to 20 minutes, and the drying time is preferably 1 minute to 10 minutes and more preferably 2 minutes to 7 minutes.

### <Exposure Step>

The film may be subjected to an exposure step of selectively exposing the film.

The manufacturing method for a cured substance may include an exposure step of selectively exposing the film formed by the film forming step.

The selective exposure means that a part of the film is exposed. In addition, by selectively exposing the film, an exposed region (an exposed portion) and an unexposed region (a non-exposed portion) are formed in the film.

The exposure amount is not particularly limited as long as the resin composition according to the embodiment of the present invention can be cured; however, it is, for example, preferably 50 to 10,000 mJ/cm² and more preferably 200 to 8,000 mJ/cm² in terms of conversion of exposure energy at a wavelength of 365 nm.

The exposure wavelength can be appropriately determined in a range of 190 to 1,000 nm and preferably in a range of 240 to 550 nm.

Examples of the exposure wavelength, which are mentioned in the relationship with the light source, include (1) a semiconductor laser (wavelength: 830 nm, 532 nm, 488 nm, 405 nm, 375 nm, 355 nm, or the like); (2) a metal halide lamp; (3) a high pressure mercury lamp, a g-line (wavelength: 436 nm), an h-line (wavelength: 405 nm), an i-line (wavelength: 365 nm), or broadband light (three wavelengths of the g, h, and i-line); (4) an excimer laser, a KrF excimer laser (wavelength: 248 nm), an ArF excimer laser (wavelength: 193 nm), or an F₂ excimer laser (wavelength: 157 nm); (5) an extreme ultraviolet ray: EUV (wavelength: 13.6 nm); (6) an electron beam; and (7) a second harmonic wave of 532 nm and a third harmonic wave of 355 nm of a YAG laser. Regarding the resin composition according to the embodiment of the present invention, exposure with a high pressure mercury lamp is particularly preferable, and from the viewpoint of exposure sensitivity, exposure with an i-line is more preferable.

The exposure method is not particularly limited as long as at least a part of the film consisting of the resin composition according to the embodiment of the present invention is exposed; however, examples thereof include exposure using a photo mask and exposure by a laser direct imaging method.

### <Post-Exposure Heating Step>

The film may be subjected to a step of carrying out heating after the exposure (a post-exposure heating step).

That is, the manufacturing method for a cured substance according to the embodiment of the present invention may include a post-exposure heating step of heating the film exposed in the exposure step.

The post-exposure heating step can be carried out after the exposure step and before the development step.

The heating temperature in the post-exposure heating step is preferably 50° C. to 140° C. and more preferably 60° C. to 120° C.

The heating time in the post-exposure heating step is preferably 30 seconds to 300 minutes and more preferably 1 minute to 10 minutes.

In the post-exposure heating step, the temperature rising rate from the temperature at the start of heating to the maximum heating temperature is preferably 1 to 12° C./min, more preferably 2 to 10° C./min, and still more preferably 3 to 10° C./min.

In addition, the temperature rising rate may be appropriately changed during heating.

The heating means in the post-exposure heating step is not particularly limited, and a publicly known hot plate, oven, infrared heater, or the like can be used.

In addition, it is also preferable to carry out the heating in an atmosphere having a low oxygen concentration by allowing an inert gas such as nitrogen, helium, argon, or the like to flow.

### <Development Step>

The exposed film may be subjected to a development step of carrying out development using a developer to form a pattern.

That is, the manufacturing method for a cured substance according to the embodiment of the present invention may include a development step of developing the film exposed in the exposure step using a developer to form a pattern.

By carrying out the development, one of the exposed portion and the non-exposed portion of the film is removed, and a pattern is formed.

Here, the development in which the non-exposed portion of the film is removed by the development step is referred to as negative-tone development, and the development in which the exposed portion of the film is removed by the development step is referred to as positive-tone development.

### [Developer]

Examples of the developer that is used in the development step include a developer containing an alkaline aqueous solution or an organic solvent.

In a case where the developer is an alkaline aqueous solution, examples of the basic compound that can be contained in the alkaline aqueous solution include inorganic alkalis, primary amines, secondary amines, tertiary amines, and a quaternary ammonium salt. The basic compound is preferably tetramethylammonium hydroxide (TMAH), potassium hydroxide, sodium carbonate, sodium hydroxide, sodium silicate, sodium metasilicate, ammonia, ethylamine, n-propylamine, diethylamine, di-n-butylamine, triethylamine, methyldiethylamine, dimethylethanolamine, triethanolamine, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, dibutyldipentylammonium hydroxide, dimethylbis(2-hydroxyethyl)ammonium hydroxide, trimethylphenylammonium hydroxide, trimethylbenzylammonium hydroxide, triethylbenzylammonium hydroxide, pyrrole, or piperidine, and it is more preferably TMAH. The content of the basic compound in the developer is preferably 0.01% to 10% by mass, more preferably 0.1% to 5% by mass, and still more preferably 0.3% to 3% by mass in the total mass of the developer.

In a case where the developer contains an organic solvent, the compounds described in paragraph 0387 of WO2021/112189A can be used as the organic solvent. The content thereof is incorporated in the present specification. In addition, suitable examples of the alcohols include methanol, ethanol, propanol, isopropanol, butanol, pentanol, octanol, diethylene glycol, propylene glycol, methyl isobutyl carbinol, and triethylene glycol, and suitable examples of the amides include N-methylpyrrolidone, N-ethylpyrrolidone, and dimethylformamide.

In a case where the developer contains an organic solvent, one kind of organic solvent can be used, or two or more kinds thereof can be mixedly used. In the present invention, in particular, a developer containing at least one selected from the group consisting of cyclopentanone, γ-butyrolactone, dimethyl sulfoxide, N-methyl-2-pyrrolidone, and cyclohexanone is preferable, a developer containing at least one selected from the group consisting of cyclopentanone, γ-butyrolactone, and dimethyl sulfoxide is more preferable, and a developer containing cyclopentanone is particularly preferable.

In a case where the developer contains an organic solvent, the content of the organic solvent with respect to the total mass of the developer is preferably 50% by mass or more, more preferably 70% by mass or more, still more preferably 80% by mass or more, and particularly preferably 90% by mass or more. In addition, the above content may be 100% by mass.

In a case where the developer contains an organic solvent, the developer may further contain at least one of a basic compound or a base generator. In a case where at least one of the basic compound or the base generator in the developer permeates into the pattern, the performance such as the breaking elongation of the pattern may be improved.

The basic compound is preferably an organic base from the viewpoint of the reliability in a case of being remained in the cured film (the adhesiveness to the base material in a case where the cured substance is further heated).

The basic compound is preferably a basic compound having an amino group and preferably a primary amine, a secondary amine, a tertiary amine, an ammonium salt, a tertiary amide, or the like. However, in order to accelerate the imidization reaction, it is preferably a primary amine, a secondary amine, a tertiary amine, or an ammonium salt, more preferably a secondary amine, a tertiary amine, or an ammonium salt, still more preferably a secondary amine or a tertiary amine, and particularly preferably a tertiary amine.

From the viewpoint of mechanical characteristics (the breaking elongation) of the cured substance, it is preferable that the basic compound hardly remains in the cured film (the obtained cured substance), and from the viewpoint of accelerating cyclization, it is preferable that the residual amount of the basic compound hardly decreases due to vaporization or the like before heating.

Therefore, the boiling point of the basic compound is preferably 30° C. to 350° C., more preferably 80° C. to 270° C., and still more preferably 100° C. to 230° C. at normal pressure (101,325 Pa).

The boiling point of the basic compound is preferably higher than the temperature obtained by subtracting 20° C. from the boiling point of the organic solvent contained in the developer, and it is more preferably higher than the boiling point of the organic solvent contained in the developer.

For example, in a case where the boiling point of the organic solvent is 100° C., the basic compound to be used preferably has a boiling point of 80° C. or higher and more preferably a boiling point of 100° C. or higher.

The developer may contain only one kind of basic compound having an amide group or may contain two or more kinds thereof.

Specific examples of the basic compound include ethanolamine, diethanolamine, triethanolamine, ethylamine, diethylamine, triethylamine, hexylamine, dodecylamine, cyclohexylamine, cyclohexylmethylamine, cyclohexyldimethylamine, aniline, N-methylaniline, N,N-dimethylaniline, diphenylamine, pyridine, butylamine, isobutylamine, dibutylamine, tributylamine, dicyclohexylamine, diazabicycloundecene (DBU), 1,4-diazabicyclo[2.2.2]octane (DABCO), N,N-diisopropylethylamine, tetramethylammonium hydroxide, tetrabutylammonium hydroxide, ethylenediamine, butanediamine, 1,5-diaminopentane, N-methylhexylamine, N-methyldicyclohexylamine, trioctylamine, N-ethylethylenediamine, N,N-diethylethylenediamine, N,N,N′,N′-tetrabutyl-1,6-hexanediamine, spermidine, diaminocyclohexane, bis(2-methoxyethyl)amine, piperidine, methylpiperidine, dimethylpiperidine, piperazine, tropane, N-phenylbenzylamine, 1,2-dianilinoethane, 2-aminoethanol, toluidine, aminophenol, hexylaniline, phenylene diamine, phenylethylamine, dibenzylamine, pyrrole, N-methylpyrrole, N,N,N,N-tetramethylethylenediamine, and N,N,N,N-tetramethyl-1,3-propanediamine.

A preferred aspect of the base generator is the same as the preferred aspect of the base generator contained in the above-described composition. In particular, the base generator is preferably a thermal-base generator.

In a case where the developer contains at least one of a basic compound or a base generator, the content of the basic compound or the base generator is preferably 10% by mass or less, and more preferably 5% by mass or less with respect to the total mass of the developer. The lower limit of the content is not particularly limited; however, it is, for example, preferably 0.1% by mass or more.

In a case where the basic compound or the base generator is a solid in an environment where the developer is used, the content of the basic compound or the base generator is also preferably 70% to 100% by mass with respect to the total solid content of the developer.

The developer may contain only one kind of at least one of the basic compound or base generator or may contain two or more kinds thereof. In a case where at least one of the basic compound or the base generator is two or more kinds, the total thereof is preferably within the above-described range.

The developer may further contain another component.

Examples of the other component include a publicly known surfactant and a publicly known anti-foaming agent.

### [Method of Supplying Developer]

The method of supplying a developer is not particularly limited as long as a desired pattern can be formed, and it includes a method of immersing a base material on which a film has been formed in a developer, puddle development of supplying a developer to a film formed on a base material using a nozzle, and a method of continuously supplying a developer. The kind of nozzle is not particularly limited, and examples thereof include a straight nozzle, a shower nozzle, and a spray nozzle.

From the viewpoint of the permeability of the developer, the removability of the non-image area, and the manufacturing efficiency, a method of supplying a developer with a straight nozzle or a method of continuously supplying a developer with a spray nozzle is preferable, and from the viewpoint of the permeability of the developer into the image area, a method of supplying a developer with a spray nozzle is more preferable.

In addition, after the continuous supply by a straight nozzle, the base material is spun to remove the developer from the base material, and then the developer is continuously supplied by the straight nozzle again after the spin drying, a step of spinning the base material to remove the developer from the base material may be adopted, and this step may be repeated a plurality of times.

Examples of the method of supplying a developer in the development step include a step of continuously supplying a developer to a base material, a step of keeping a developer in a substantially stationary state on a base material, a step of vibrating a developer on a base material by ultrasonic waves or the like, and a step obtained by combining these steps.

The development time is preferably 10 seconds to 10 minutes and more preferably 20 seconds to 5 minutes. The temperature of the developer during development is not particularly determined; however, it is preferably 10° C. to 45° C. and more preferably 18° C. to 30° C.

In the development step, washing (rinsing) of the pattern with a rinsing liquid may be further carried out after the treatment with the developer. In addition, a method such as supplying a rinsing liquid before the developer which is in contact with the pattern is completely dried may be adopted.

### [Rinsing Liquid]

In a case where the developer is an alkaline aqueous solution, it is possible to use, for example, water as the rinsing liquid. In a case where the developer is a developer containing an organic solvent, it is possible to use as the rinsing liquid, for example, a solvent (for example, water, an organic solvent different from the organic solvent contained in the developer) different from the solvent contained in the developer.

Examples of the organic solvent in a case where the rinsing liquid contains an organic solvent include the same organic solvents as the organic solvents exemplified in the above-described case where the developer contains an organic solvent.

The organic solvent contained in the rinsing liquid is preferably an organic solvent different from the organic solvent contained in the developer, and it is more preferably an organic solvent having a solubility of the pattern, which is lower than that of the organic solvent contained in the developer.

In a case where the rinsing liquid contains an organic solvent, one kind of organic solvent can be used, or two or more kinds thereof can be mixedly used. The organic solvent is preferably cyclopentanone, γ-butyrolactone, dimethyl sulfoxide, N-methylpyrrolidone, cyclohexanone, PGMEA, or PGME, more preferably cyclopentanone, γ-butyrolactone, dimethyl sulfoxide, PGMEA, or PGME, and still more preferably cyclohexanone or PGMEA.

In a case where the rinsing liquid contains an organic solvent, the organic solvent is preferably 50% by mass or more, more preferably 70% by mass or more, and still more preferably 90% by mass or more with respect to the total mass of the rinsing liquid. In addition, the organic solvent may be 100% by mass with respect to the total mass of the rinsing liquid.

The rinsing liquid may contain at least one of a basic compound or a base generator.

Although not particularly limited, in a case where the developer contains an organic solvent, an aspect in which the rinsing liquid contains at least one of an organic solvent, a basic compound, or a base generator is also one of the preferred aspects of the present invention.

Examples of the basic compound and the base generator which are contained in the rinsing liquid include the compounds exemplified as the basic compound and the base generator which may be contained in a case where the developer contains an organic solvent, and the same applies to the preferred aspects thereof.

The basic compound and the base generator, which are contained in the rinsing liquid, may be selected in consideration of the solubility in the solvent in the rinsing liquid.

In a case where the rinsing liquid contains at least one of a basic compound or a base generator, the content of the basic compound or the base generator is preferably 10% by mass or less, and more preferably 5% by mass or less with respect to the total mass of the rinsing liquid. The lower limit of the content is not particularly limited; however, it is, for example, preferably 0.1% by mass or more.

In a case where the basic compound or the base generator is a solid in an environment where the rinsing liquid is used, the content of the basic compound or the base generator is also preferably 70% to 100% by mass with respect to the total solid content of the rinsing liquid.

In a case where the rinsing liquid contains at least one of a basic compound or a base generator, the rinsing liquid may contain only one kind of at least one of the basic compound or base generator or may contain two or more kinds thereof. In a case where at least one of the basic compound or the base generator is two or more kinds, the total thereof is preferably within the above-described range.

The rinsing liquid may further contain another component.

Examples of the other component include a publicly known surfactant and a publicly known anti-foaming agent.

### [Method of Supplying Rinsing Liquid]

The method of supplying a rinsing liquid is not particularly limited as long as a desired pattern can be formed and includes a method of immersing a base material in a rinsing liquid, a method of supplying a rinsing liquid to a base material by liquid filling, a method of supplying a rinsing liquid to a base material with a shower, and a method of continuously supplying a rinsing liquid to a base material by means such as a straight nozzle.

From the viewpoint of the permeability of the rinsing liquid, the removability of non-image area, and the manufacturing efficiency, there is a method of supplying a rinsing liquid with a shower nozzle, a straight nozzle, a spray nozzle, or the like, and a method of continuously supplying a rinsing liquid with a spray nozzle is preferable. From the viewpoint of the permeability of the rinsing liquid into the image area, a method of supplying a rinsing liquid with a spray nozzle is more preferable. The kind of nozzle is not particularly limited, and examples thereof include a straight nozzle, a shower nozzle, and a spray nozzle.

That is, the rinsing step is preferably a step of supplying, with a straight nozzle, or continuously supplying a rinsing liquid to the exposed film, and it is more preferably a step of supplying a rinsing liquid with a spray nozzle.

In the method of supplying a rinsing liquid in the rinsing step, a step of continuously supplying a rinsing liquid to a base material, a step of keeping a rinsing liquid in a substantially stationary state on a base material, a step of vibrating a rinsing liquid on the base material by ultrasonic waves or the like, and a step obtained by combining these steps can be adopted.

The rinsing time is preferably 10 seconds to 10 minutes and more preferably 20 seconds to 5 minutes. The temperature of the rinsing liquid during rinsing is not particularly determined; however, it is preferably 10° C. to 45° C. and more preferably 18° C. to 30° C.

The development step may include a step of bringing the treatment liquid into contact with the pattern after the treatment using the developer or after the pattern is washed with the rinsing liquid. In addition, such a method of supplying a treatment liquid before the developer or rinsing liquid which is in contact with the pattern is completely dried may be adopted.

Examples of the treatment liquid include a treatment liquid containing at least one of water or an organic solvent and at least one of a basic compound or a base generator. Preferred aspects of the organic solvent and at least one of the basic compound or the base generator are the same as the preferred aspects of the organic solvent and at least one of the basic compound or the base generator, which are used in the above-described rinsing liquid.

As a method of supplying the treatment liquid to the pattern, the same method as the above-described method of supplying the rinsing liquid can be used, and the same applies to the preferred aspect thereof.

The content of the basic compound or the base generator in the treatment liquid is preferably 10% by mass or less and more preferably 5% by mass or less with respect to the total mass of the treatment liquid. The lower limit of the content is not particularly limited; however, it is, for example, preferably 0.1% by mass or more.

In addition, in a case where the basic compound or the base generator is a solid in an environment where the treatment liquid is used, the content of the basic compound or the base generator is also preferably 70% to 100% by mass with respect to the total solid content of the treatment liquid.

In a case where the treatment liquid contains at least one of a basic compound or a base generator, the treatment liquid may contain only one kind of at least one of the basic compound or the base generator, or may contain two or more kinds thereof. In a case where at least one of the basic compound or the base generator is two or more kinds, the total thereof is preferably within the above-described range.

### <Heating Step>

The pattern obtained by the development step (a pattern after the rinsing in a case where the rinsing step is carried out) may be subjected to a heating step of heating the pattern obtained by the development.

That is, the manufacturing method for a cured substance according to the embodiment of the present invention may include a heating step of heating the pattern obtained by the development step.

In addition, the manufacturing method for a cured substance according to the embodiment of the present invention may include a pattern obtained by another method without carrying out the development step, or a heating step of heating a film obtained by the film forming step.

In the heating step, the resin such as the polyimide precursor is cyclized to be a resin such as polyimide.

In addition, the crosslinking of unreacted crosslinkable groups in the specific resin or a crosslinking agent other than the specific resin also proceeds.

The heating temperature (the maximum heating temperature) in the heating step is preferably 50° C. to 450° C., more preferably 150° C. to 350° C., still more preferably 150° C. to 250° C., even still more preferably 160° C. to 250° C., and particularly preferably 160° C. to 230° C.

The heating step is preferably a step of accelerating the cyclization reaction of the polyimide precursor in the pattern under the action of the base or the like generated from the base generator by heating.

The heating in the heating step is preferably carried out at a temperature rising rate of 1 to 12° C./min from the temperature at the start of heating to the maximum heating temperature. The temperature rising rate is more preferably 2 to 10° C./min and still more preferably 3 to 10° C./min. In a case where the above temperature rising rate is set to 1° C./min or higher, the excessive volatilization of the acid or solvent can be prevented while securing productivity, and in a case where the above temperature rising rate is to 12° C./min or lower, the residual stress of the cured substance can be relaxed.

In addition, in a case of an oven that enables rapid heating, the heating is preferably carried out at a temperature rising rate of 1 to 8° C./sec from the temperature at the start of heating to the maximum heating temperature, more preferably 2 to 7° C./sec, and still more preferably 3 to 6° C./sec.

The temperature at the start of heating is preferably 20° C. to 150° C., more preferably 20° C. to 130° C., and still more preferably 25° C. to 120° C. The temperature at the start of heating refers to a temperature at which the step of heating to the maximum heating temperature is started. For example, in a case where the resin composition according to the embodiment of the present invention is applied on a base material and then dried, the temperature at the start of heating is the temperature of the film (the layer) after drying, and for example, it is preferable to raise the temperature from a temperature lower by 30° C. to 200° C. than the boiling point of the solvent contained in the resin composition.

The heating time (the heating time at the maximum heating temperature) is preferably 5 to 360 minutes, more preferably 10 to 300 minutes, and still more preferably 15 to 240 minutes.

In particular, in a case of forming a multilayered laminate, the heating temperature is preferably 30° C. or higher, more preferably 80° C. or higher, still more preferably 100° C. or higher, and particularly preferably 120° C. or higher, from the viewpoint of adhesiveness between layers.

The upper limit of the heating temperature is preferably 350° C. or lower, more preferably 250° C. or lower, and still more preferably 240° C. or lower.

The heating may be carried out stepwise. For example, a step in which the temperature is raised from 25° C. to 120° C. at 3° C./min, held at 120° C. for 60 minutes, raised from 120° C. to 180° C. at 2° C./min, and held at 180° C. for 120 minutes, may be carried out. In addition, it is also preferable to carry out the treatment while carrying out irradiation with ultraviolet rays as described in U.S. Pat. No. 9,159,547B. By such a pretreatment step, it is possible to improve the properties of the film. The pretreatment step may be carried out for a short time of about 10 seconds to 2 hours and more preferably 15 seconds to 30 minutes. The pretreatment step may be carried out as a step of two or more stages, for example, a first stage pretreatment step may be carried out in a range of 100° C. to 150° C., and then a second stage pretreatment step may be carried out in a range of 150° C. to 200° C.

Further, cooling may be carried out after heating, and the cooling rate, in this case, is preferably 1 to 5° C./min.

From the viewpoint of preventing the decomposition of the specific resin, it is preferable that the heating step is carried out in an atmosphere of a low oxygen concentration, for example, by allowing an inert gas such as nitrogen, helium, argon, or the like to flow, or carrying out heating under reduced pressure. The oxygen concentration is preferably 50 ppm (volume ratio) or lower, and more preferably 20 ppm (volume ratio) or lower.

The heating means in the heating step is not particularly limited; however, examples thereof include a hot plate, an infrared furnace, an electric heating oven, a hot air oven, and an infrared oven.

### <Post-Development Exposure Step>

The pattern obtained by the development step (a pattern after the rinsing in a case where the rinsing step is carried out) may be subjected to a post-development exposure step of exposing the pattern after the development step, instead of the heating step or in addition to the heating step.

That is, the manufacturing method for a cured substance according to the embodiment of the present invention may include a post-development exposure step of exposing the pattern obtained by the development step. The manufacturing method for a cured substance according to the embodiment of the present invention may include the heating step and the post-development exposure step or may include only one of the heating step and the post-development exposure step.

In the post-development exposure step, it is possible to accelerate, for example, a reaction in which the cyclization of a polyimide precursor or the like proceeds by photosensitization of a photobase generator.

In the post-development exposure step, it is sufficient that at least a part of the pattern obtained in the development step is exposed; however, it is preferable that the whole of the above pattern is exposed.

The exposure amount in the post-development exposure step is preferably 50 to 20,000 mJ/cm² and more preferably 100 to 15,000 mJ/cm² in terms of conversion of exposure energy at the wavelength at which the photosensitive compound has a sensitivity.

The post-development exposure step can be carried out using, for example, the light source in the above-described exposure step, and it is preferable to use broadband light.

### <Metal Layer Forming Step>

The pattern (preferably a pattern that has been subjected to at least one of the heating step or the post-development exposure step) obtained by the development step may be subjected to a metal layer forming step of forming a metal layer on the pattern.

That is, it is preferable that the manufacturing method for a cured substance according to the embodiment of the present invention includes a metal layer forming step of forming a metal layer on the pattern (preferably a pattern that has been subjected to at least one of the heating step or the post-development exposure step) obtained by the development step.

For the metal layer, existing metal kinds can be used without particular limitations. Examples thereof include copper, aluminum, nickel, vanadium, titanium, chromium, cobalt, gold, tungsten, tin, silver, and an alloy including these metals, where copper or aluminum is more preferable, and copper is still more preferable.

The forming method for the metal layer is not particularly limited, and the existing method can be applied. For example, the methods described in JP2007-157879A, JP2001-521288A, JP2004-214501A, JP2004-101850A, U.S. Pat. No. 7,888,181B2, and U.S. Pat. No. 9,177,926B2 can be used. For example, photolithography, physical vapor deposition method (PVD), chemical vapor phase growth method (CVD), lift-off, electrolytic plating, electroless plating, etching, printing, and a method obtained by combining these may be conceivable. More specific examples of the forming method for the metal layer include a patterning method obtained by combining sputtering, photolithography, and etching, and a patterning method combining photolithography and electrolytic plating. Examples of the preferred aspect of the plating include electrolytic plating using a copper sulfate plating liquid or a copper cyanide plating liquid.

The thickness of the metal layer at the thickest portion is preferably 0.01 to 50 μm and more preferably 1 to 10 μm.

### <Use Application>

Examples of the field to which the manufacturing method for a cured substance according to the embodiment of the present invention or the cured substance according to the embodiment of the present invention can be applied include an insulating film of an electronic device, an interlayer insulating film for a re-distribution layer, and a stress buffer film. In addition, a sealing film, a substrate material (a base film or cover lay of a flexible print substrate, an interlayer insulating film), or such an insulating film in a use application for mounting as described above, which is patterned by etching, is mentioned. For these use applications, for example, Science & Technology Co., Ltd., “High functionality and applied technology of polyimide” April 2008, Technical library CMC TL “Basics and development of polyimide materials” supervised by Masaaki Kakimoto, published in November 2011, “Latest Polyimide Basics and Applications” edited by Japan Polyimide & Aromatic Polymers Study Group, NTS Inc., August 2010, or the like can be referred to.

The manufacturing method for a cured substance according to the embodiment of the present invention and the cured substance according to the embodiment of the present invention can also be used for the production of board surfaces such as an offset board surface or a screen board surface, for etching of molded parts, for the production of protective lacquers and dielectric layers in electronics, in particular, microelectronics.

### (Laminate and Manufacturing Method for Laminate)

A laminate according to the embodiment of the present invention refers to a structure body having a plurality of layers consisting of the cured substance according to the embodiment of the present invention.

The laminate is a laminate including two or more layers consisting of a cured substance, and it may be a laminate in which three or more layers are laminated.

At least one of the two or more layers consisting of a cured substance, which are included in the laminate, is a layer consisting of the cured substance according to the embodiment of the present invention, and from the viewpoint of suppressing the shrinkage of the cured substance, the deformation of the cured substance due to the shrinkage, or the like, it is also preferable that all the layers consisting of a cured substance which are included in the laminate are layers consisting of the cured substance according to the embodiment of the present invention.

That is, it is preferable that the manufacturing method for a laminate according to the embodiment of the present invention includes the manufacturing method for a cured substance according to the embodiment of the present invention, and it is more preferable to include repeating, a plurality of times, the manufacturing method for a cured substance according to the embodiment of the present invention.

In the laminate according to the embodiment of the present invention, an aspect in which two or more layers of layers consisting of a cured substance are included and a metal layer is provided between any of the layers consisting of the cured substance is preferable. The metal layer is preferably formed in the metal layer forming step.

That is, it is preferable that the manufacturing method for a laminate according to the embodiment of the present invention further includes a metal layer forming step of forming a metal layer on a layer consisting of the cured substance, between the manufacturing methods for a cured substance which are carried out a plurality of times. The preferred aspect of the metal layer forming step is as described above.

Examples of the preferred laminate include a laminate including at least a layer structure in which three layers of a layer consisting of a first cured substance, a metal layer, and a layer consisting of a second cured substance are laminated in order.

It is preferable that both the layer consisting of the first cured substance and the layer consisting of the second cured substance are layers consisting of the cured substance according to the embodiment of the present invention. The resin composition according to the embodiment of the present invention which is used for forming a layer consisting of the first cured substance and the resin composition according to the embodiment of the present invention which is used for forming a layer consisting of the second cured substance may have the same composition or may have compositions different from each other. The metal layer in the laminate according to the embodiment of the present invention is preferably used as the metal wiring line of the re-distribution layer or the like.

### <Laminating Step>

The manufacturing method for a laminate according to the embodiment of the present invention preferably further includes a laminating step.

The laminating step is a series of steps including carrying out again, in the following order on the surface of the pattern (the resin layer) or the metal layer, at least one of (a) the film forming step (the layer forming step), (b) the exposure step, (c) the development step, or (d) the heating step and the post-development exposure step. However, the aspect thereof may be such that at least one of (a) the film forming step or (d) the heating step and the post-development exposure step is repeated. In addition, (e) the metal layer forming step may be included after at least one of the heating step or the post-development exposure step of (d). It is needless to say that the laminating step may further include appropriately the above-described drying step or the like.

In a case where another laminating step is further carried out after the laminating step, a surface activation treatment step may be further carried out after the exposure step, the heating step, or the metal layer forming step. Examples of the surface activation treatment include plasma treatment. Details of the surface activation treatment will be described later.

The laminating step is preferably carried out 2 to 20 times and more preferably 2 to 9 times.

For example, a configuration having resin layers of 2 or more layers and 20 or fewer layers, such as a resin layer/a metal layer/a resin layer/a metal layer/a resin layer/a metal layer, is preferable, and a configuration having resin layers of 2 or more layers and 9 or fewer layers is still more preferable.

In the above layers, the compositions, shapes, film thicknesses, and the like may be the same or may be different from each other.

In the present invention, an aspect in which a metal layer is provided, and then furthermore, a cured substance (a resin layer) of the resin composition according to the embodiment of the present invention is formed to cover the metal layer is particularly preferable. Specific examples thereof include an aspect in which (a) the film forming step, (b) the exposure step, (c) the development step, (d) at least one of the heating step or the post-development exposure step, (e) the metal layer forming step are repeated in this order, and an aspect in which (a) the film forming step, (d) at least one of the heating step or the post-development exposure step, and (e) the metal layer forming step are repeated in order. By alternately carrying out the laminating step of laminating the resin composition layer (the resin layer) according to the embodiment of the present invention and the metal layer forming step, the resin composition layer (the resin layer) according to the embodiment of the present invention and the metal layer can be alternately laminated.

### (Surface Activation Treatment Step)

The manufacturing method for a laminate according to the embodiment of the present invention preferably includes a surface activation treatment step of subjecting at least a part of the metal layer or a part of the resin composition layer to a surface activation treatment. The surface activation treatment step is usually carried out after the metal layer forming step (preferably, after at least one of the heating step or the post-development exposure step). However, after the development step, the metal layer forming step may be carried out after the resin composition layer is subjected to the surface activation treatment step.

Only at least a part of the metal layer may be subjected to the surface activation treatment, only at least a part of the resin composition layer after the exposure may be subjected to the surface activation treatment, or both at least a part of the metal layer and at least a part of the resin composition layer after the exposure may be subjected to the surface activation treatment. It is preferable to carry out the surface activation treatment on at least a part of the metal layer, and it is preferable to carry out the surface activation treatment on a part or whole of the region of the metal layer having a surface on which the resin composition layer is formed. In a case where a surface of the metal layer is subjected to the surface activation treatment in this manner, it is possible to improve the adhesiveness to the resin composition layer (film) to be provided on the surface thereof.

It is preferable that the surface activation treatment is carried out on a part or whole of the resin composition layer (the resin layer) after the exposure. In a case where a surface of the resin composition layer is subjected to the surface activation treatment in this manner, it is possible to improve the adhesiveness to a metal layer or a resin layer to be provided on the surface that has been subjected to the surface activation treatment. In particular, in a case where the resin composition layer is cured, such as in a case where negative-tone development is carried out, it is less likely to be damaged by the surface treatment, and thus the adhesiveness is likely to be improved.

The surface activation treatment can be carried out, for example, according to the method described in paragraph 0415 of WO2021/112189A. The content thereof is incorporated in the present specification.

### (Semiconductor Device and Manufacturing Method Therefor)

The present invention also discloses a semiconductor device, which includes the cured substance according to the embodiment of the present invention or the laminate.

In addition, the present invention also discloses a manufacturing method for a semiconductor device, which includes the manufacturing method for a cured substance according to the embodiment of the present invention or the manufacturing method for a laminate according to the embodiment of the present invention.

As the specific examples of the semiconductor device using the resin composition according to the embodiment of the present invention for forming an interlayer insulating film for a re-distribution layer, the description in paragraphs 0213 to 0218 and the description of FIG. 1 of JP2016-027357A can be referred to, the content of which is incorporated in the present specification.

### EXAMPLES

Hereinafter, the present invention will be described in detail using examples. Materials, using amounts, proportions, treatment details, treatment content, and the like shown in the following examples can be appropriately changed without departing from the gist of the present invention. Accordingly, the scope of the present invention is not limited to the following specific examples. Unless otherwise specified, “parts” and “%” are based on mass.

### <Synthesis of Resin>

### Synthesis Example P-1: Synthesis of Polyimide (P-1)

20.80 g (40 mmol) of 4,4′-(4,4′-isopropylidenediphenoxy)diphtalic acid anhydride was dissolved in 70 g of N-methylpyrrolidone (NMP). Subsequently, 3.81 g (17.6 mmol) of 3,3′-dihydroxybenzidine and 3.74 g (17.6 mmol) of 2,2′-dimethylbenzidine were dissolved in 50 g of NMP, and the solution was added dropwise thereto over 1 hour at a temperature of 10° C. to 25° C., stirred at 25° C. for 30 minutes, 10 g of toluene was added thereto, the mixture was reacted at 200° C. for 4 hours while flowing nitrogen, and cooled to 25° C. Subsequently, 15.3 g (50 mmol) of 4-(chloromethyl)styrene, 16.6 g (120 mmol) of potassium carbonate, 1.66 g (12 mmol) of potassium iodide, and 0.08 g of 2,2,6,6-tetramethylpiperidine 1-oxide free radical were added thereto, the mixture was reacted at 95° C. for 15 hours, cooled to 25° C., and diluted with 120 g of tetrahydrofuran. Subsequently, the reaction solution was added dropwise to a mixed solution of 1.8 L of methanol and 0.6 L of water, and the mixture was stirred for 15 minutes and a polyimide resin was filtered. Next, the resin was subjected to reslurrying with 1 L of water, filtered, reslurried again with 1 L of methanol, filtered, and dried at 40° C. for 8 hours under reduced pressure. Subsequently, the resin dried as described above was dissolved in 250 g of tetrahydrofuran, 40 g of an ion exchange resin (MB-1: manufactured by ORGANO CORPORATION) was added thereto, the mixture was stirred for 4 hours, the ion exchange resin was filtered and removed, and then the polyimide resin was precipitated in 2 L of methanol and stirred for 15 minutes. The polyimide resin was filtered and acquired, and dried at 45° C. for 1 day under reduced pressure to obtain polyimide (P-1). As polyimide (P-1), five kinds of polyimides having a weight-average molecular weight (Mw) of 7,500, 35,000, 8,500, 28,000, and 22,000 were synthesized by adjusting the amounts of 3,3′-dihydroxybenzidine and 2,2′-dimethylbenzidine. Which of the polyimide was used in the composition is shown in the table described later. The polyimide (P-1) is a resin having a repeating unit represented by Formula (P-1). The subscript in parentheses of the following repeating unit represents content molar ratios of each repeating unit. The structure of the repeating unit was determined from a ¹H-NMR spectrum.

In addition, the value of the ethylenically unsaturated bond equivalent (mmol/g) of the polyimide (P-1) and the value of the molar amount of oxygen atoms/weight-average molecular weight (mmol/g) are shown in the table described later.

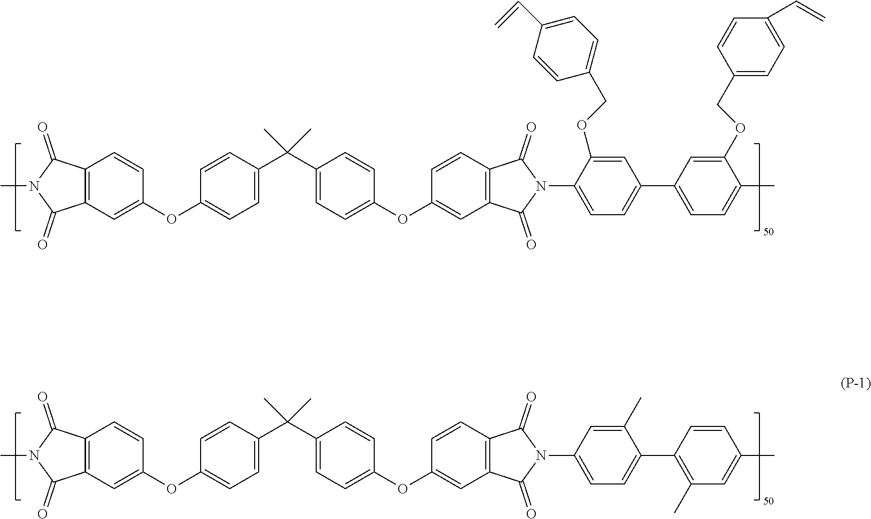

### Synthesis Examples P-2 to P-16: Synthesis of Polyimides (P-2) and (P-3), Polyimide Precursor (P-4), and Polyimides (P-5) to (P-16)

Polyimides (P-2) and (P-3), a polyimide precursor (P-4), and polyimides (P-5) to (P-16) were synthesized by the same method as that for the polyimide (P-1), except that the raw materials used were appropriately changed.

Each of the polyimides (P-2) and (P-3), the polyimide precursor (P-4), and the polyimides (P-5) to (P-16) is a resin having a repeating unit represented by any one of Formulae (P-2) to (P-16). The structure of each repeating unit was determined from a ¹H-NMR spectrum. In the following structures, the subscript in parentheses represents the content molar ratios of each structure.

In addition, the values of the ethylenically unsaturated bond equivalents (mmol/g) of the polyimides (P-2) and (P-3), the polyimide precursor (P-4), and the polyimides (P-5) to (P-16), and the molar amount of the oxygen atoms/weight-average molecular weight (mmol/g) are shown in the table described later.

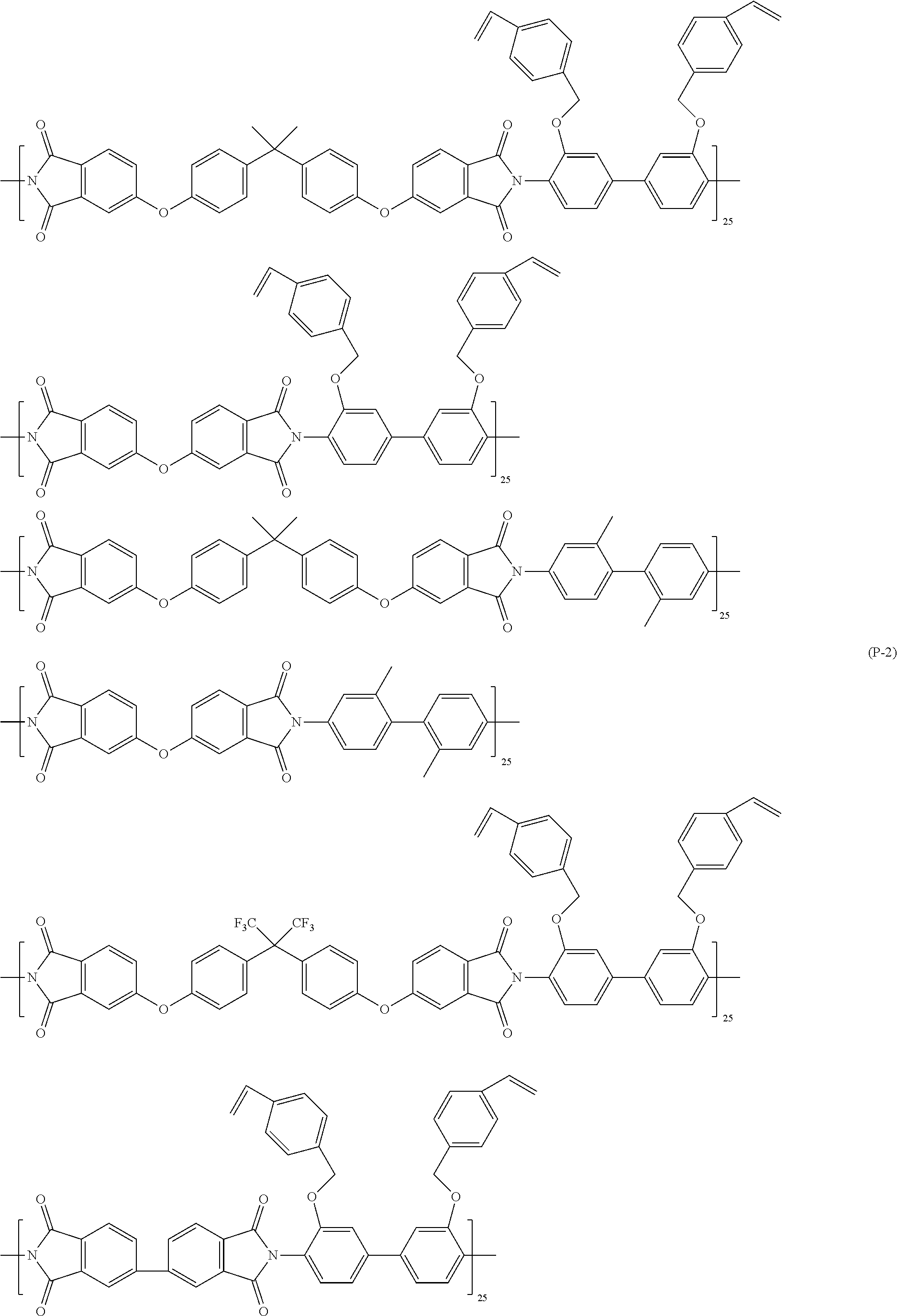

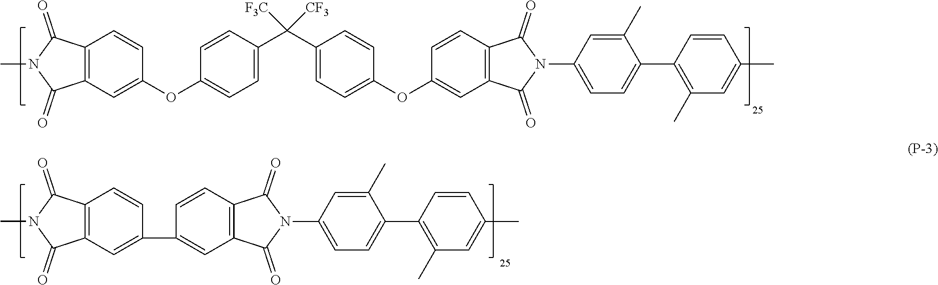

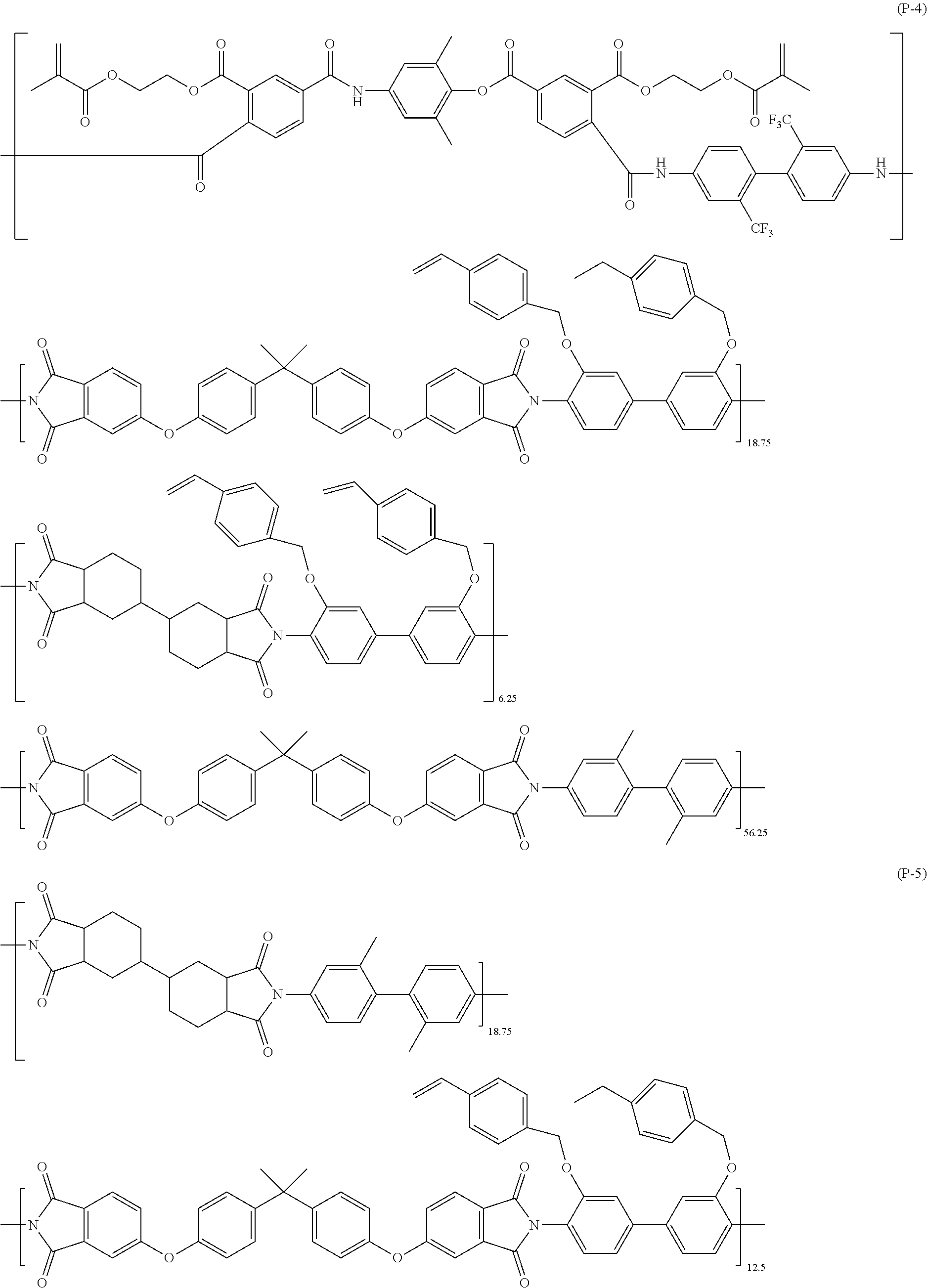

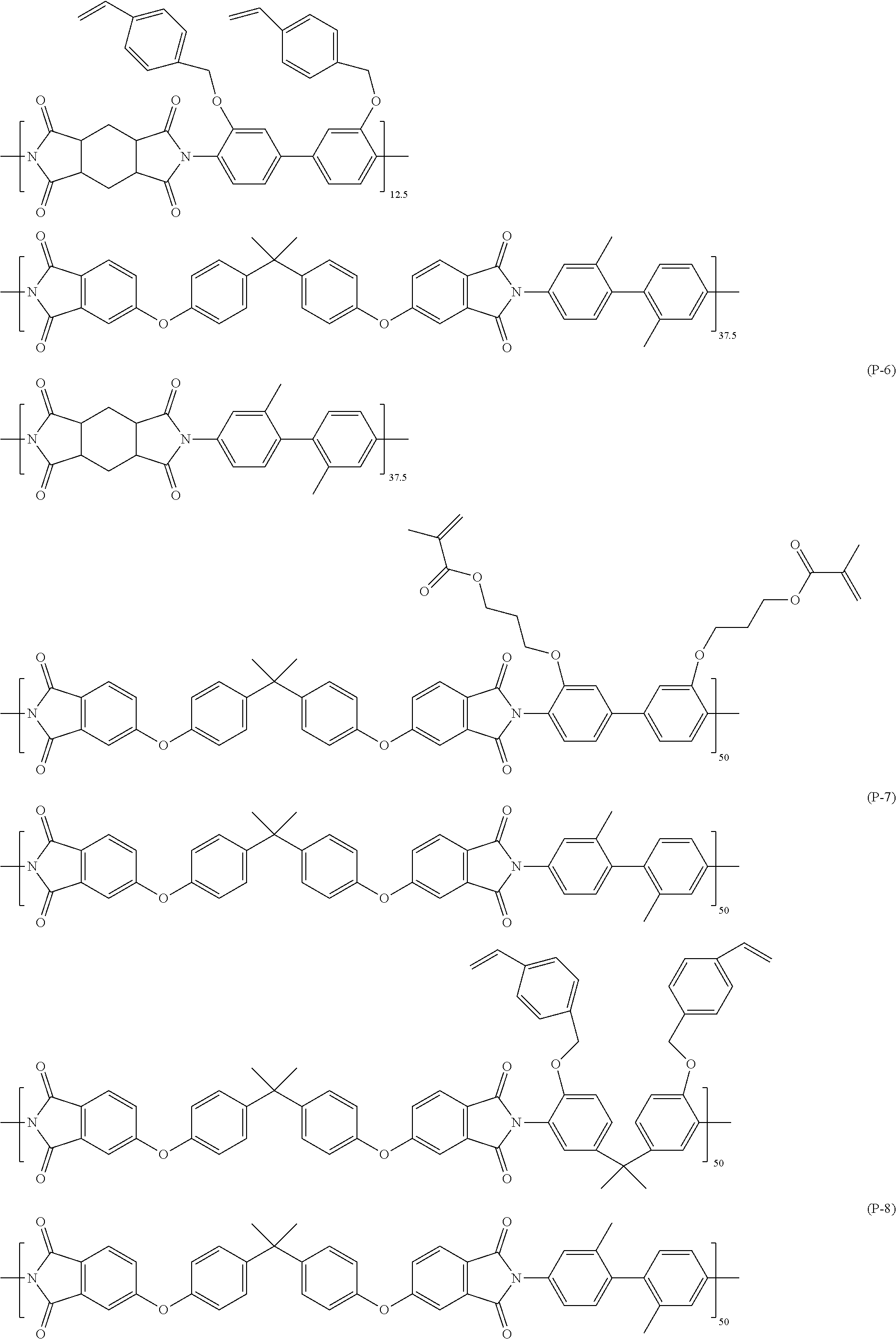

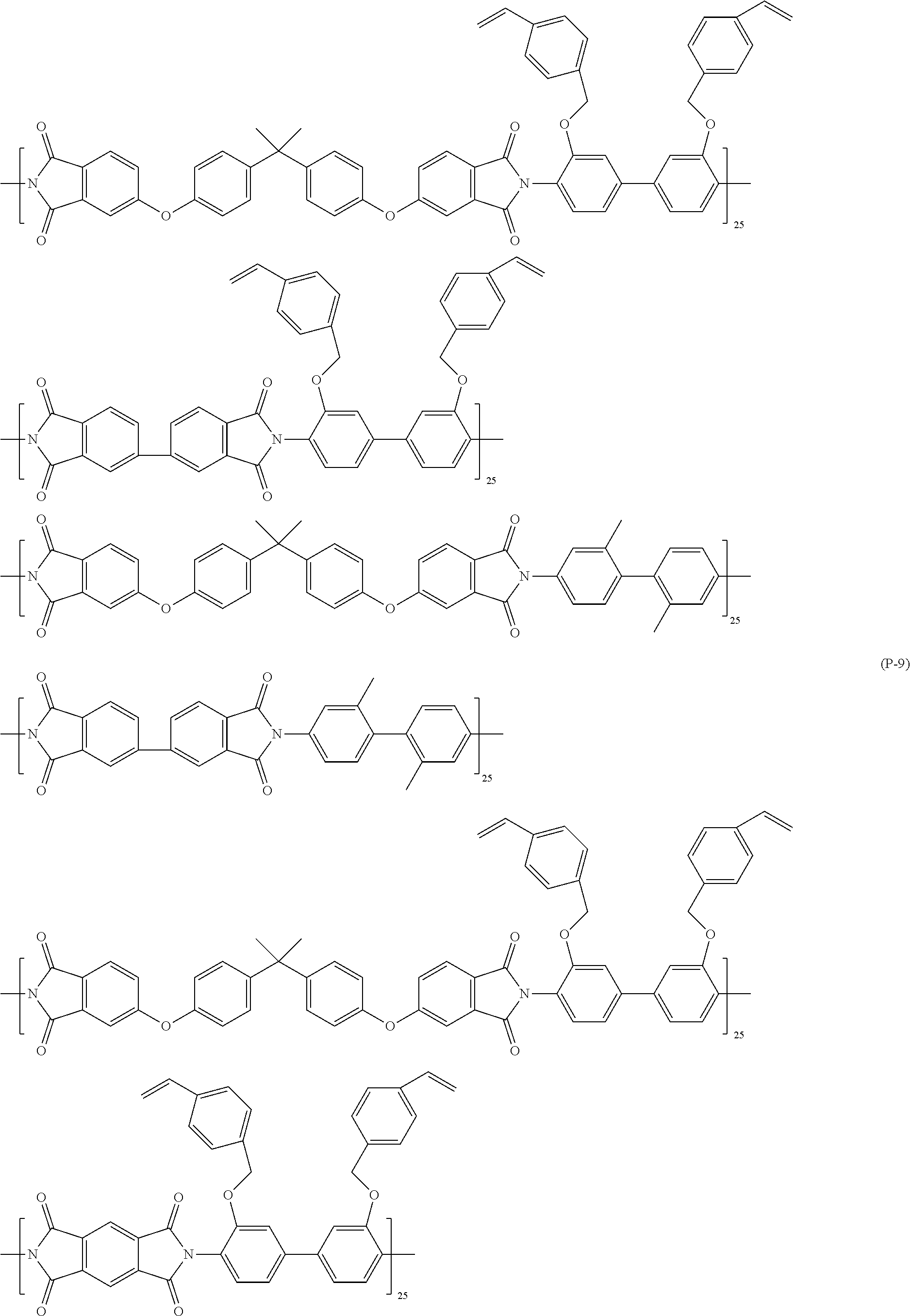

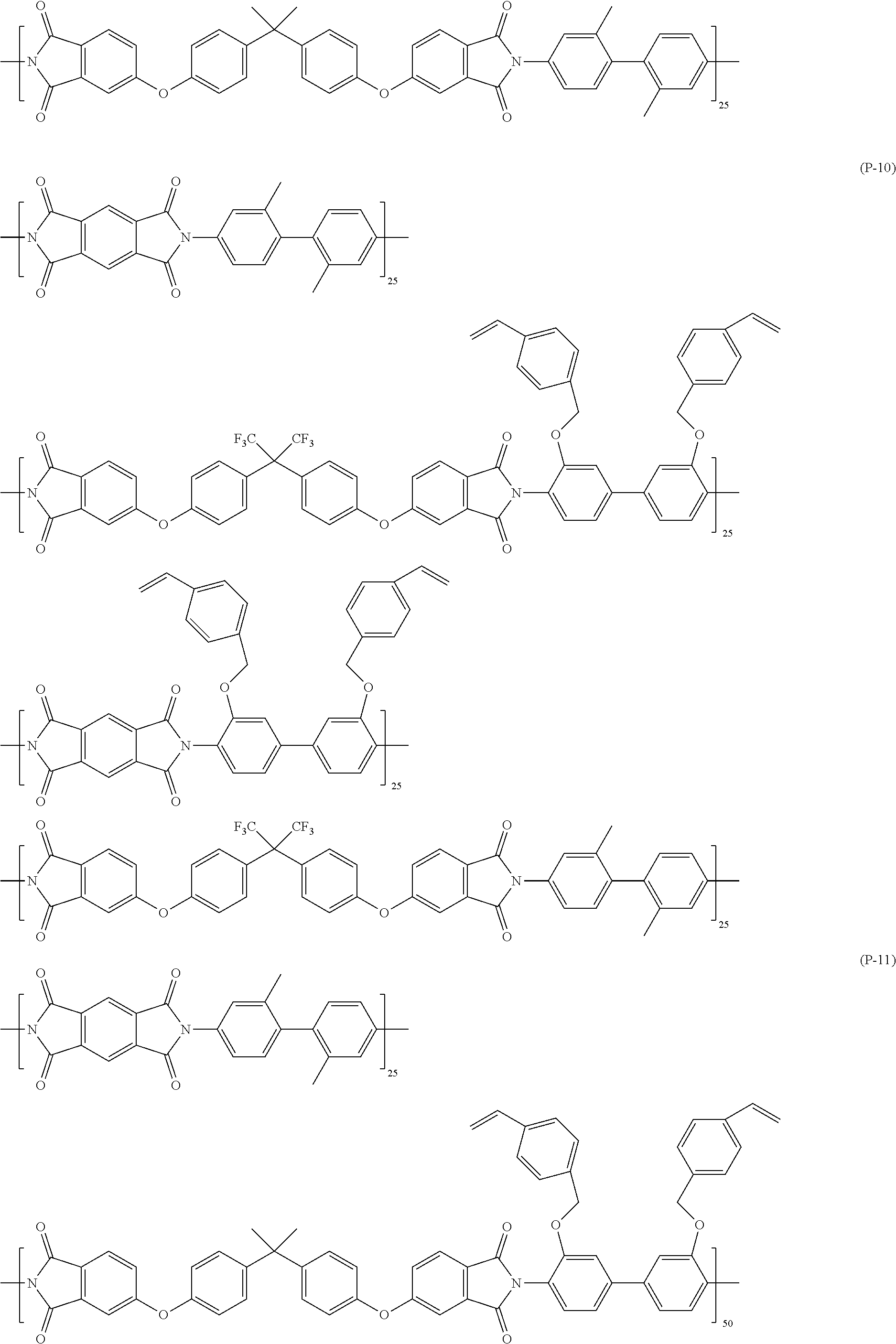

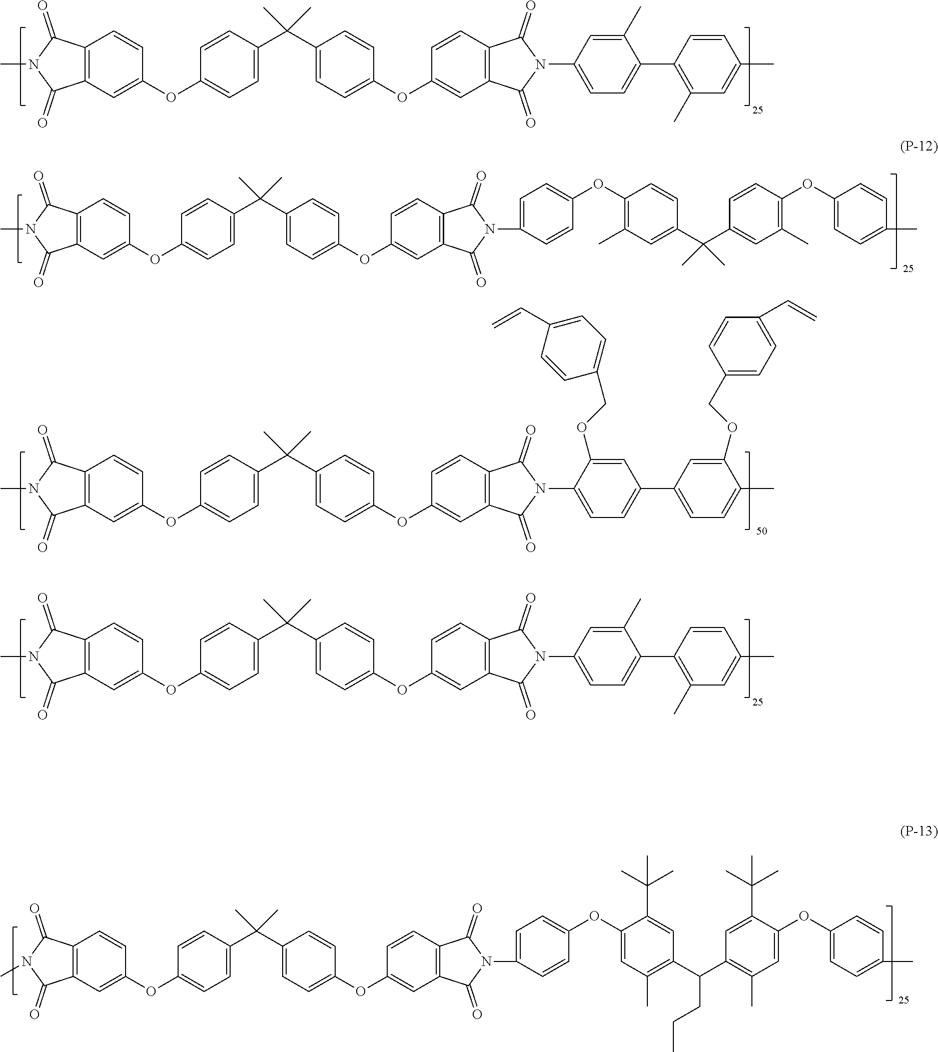

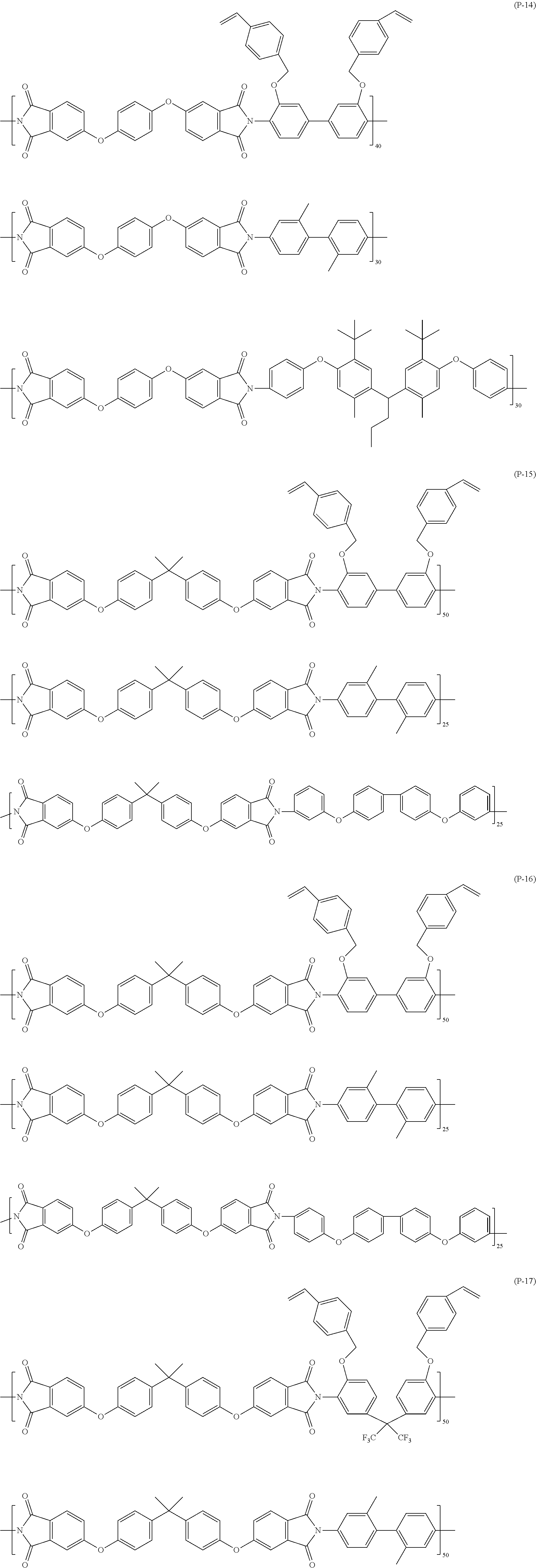

### Synthesis Example B-1: Synthesis of Comparative Polyimides (B-1) and (B-2)

Comparative polyimides (B-1) and (B-2) were synthesized by the same method as that for the polyimide (P-1), except that the raw materials used were appropriately changed.

The comparative polyimides (B-1) and (B-2) are resins having repeating units represented by Formulae (B-1) and (B-2). The structure of each repeating unit was determined from a ¹H-NMR spectrum. In the following structures, the subscript in parentheses represents the content molar ratios of each structure.

The weight-average molecular weight (Mw) of the comparative polyimide (B-1) was 7,500, and the Mw of the comparative polyimide (B-2) was 50,000.

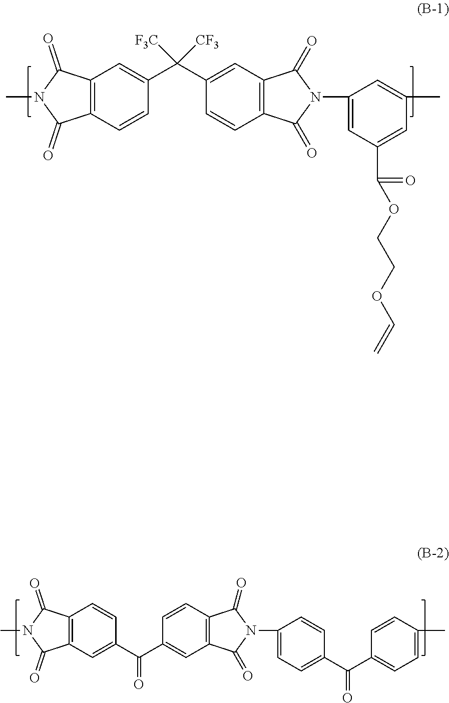

TABLE 1

| | | Value of molar amount of |
|---|---|---|
| | Ethylenically unsaturated | oxygen atoms/weight-average |
| Resin | bond equivalent (mmol/g) | molecular weight (mmol/g) |
| P-1 | 1.23 | 8.6 |
| P-2 | 1.41 | 9.2 |
| P-3 | 1.32 | 7.9 |
| P-4 | 1.94 | — |
| P-5 | 0.71 | 8.6 |
| P-6 | 0.83 | 9.1 |
| P-7 | 1.21 | 10.9 |
| P-8 | 1.20 | 8.4 |
| P-9 | 1.43 | 8.6 |
| P-10 | 1.51 | 9.0 |
| P-11 | 1.39 | 8.4 |
| P-12 | 1.15 | 8.6 |
| P-13 | 1.11 | 8.3 |
| P-14 | 1.03 | 9.5 |
| P-15 | 1.17 | 8.8 |
| P-16 | 1.17 | 8.8 |
| P-17 | 1.12 | 7.9 |
| B-1 | 1.23 | 11.1 |
| B-2 | 0.00 | 12.0 |

### Examples and Comparative Examples

In each of Examples, the components shown in the table below were mixed to obtain each of the resin compositions. Further, in each Comparative Example, components shown in the following table were mixed to obtain each of the comparative compositions.

Specifically, the content of each component described in the table was set to the amount (in terms of parts by mass) described in the column of “Parts by mass” of each column of the table.

The obtained resin composition and the comparative composition were filtered under pressure using a filter made of polytetrafluoroethylene, having a micropore width of 0.5 μm.

In addition, in the table, the description of “-” indicates that the corresponding component is not contained in the composition.

TABLE 2

| | | | Example | | | | | | | |
|---|---|---|---|---|---|---|---|---|---|---|
| | | | 1 | 2 | 3 | 4 | 5 | 6 | 7 | 8 |
| Composition | Resin | Type | P1 | P1 | P1 | P1 | P1 | P2 | P3 | P4 |
| | | Mw | 7,500 | 35,000 | 8,500 | 28,000 | 22,000 | 22,000 | 22,000 | 22,000 |
| | | Parts by mass | 28.00 | 23.00 | 28.00 | 23.00 | 23.00 | 23.00 | 23.00 | 23.00 |
| | | Dissolution rate | 0.14 | 0.06 | 0.13 | 0.08 | 0.1 | 0.09 | 0.12 | 0.18 |
| | | Type | — | — | — | — | — | — | — | — |
| | | Mw | — | — | — | — | — | — | — | — |
| | | Parts by mass | — | — | — | — | — | — | — | — |
| | | Dissolution rate | — | — | — | — | — | — | — | — |
| | Polymerization | Type | C-1 | C-1 | C-1 | C-1 | C-1 | C-1 | C-1 | C-1 |
| | initiator | Parts by mass | 1.09 | 0.89 | 1.09 | 0.89 | 0.89 | 0.89 | 0.89 | 0.89 |
| | | Type | — | — | — | — | — | — | — | — |
| | | Parts by mass | — | — | — | — | — | — | — | — |
| | Polymerizable | Type | D-1 | D-1 | D-1 | D-1 | D-1 | D-1 | D-1 | D-1 |
| | compound | Parts by mass | 6.52 | 5.36 | 6.52 | 5.36 | 5.36 | 5.36 | 5.36 | 4.91 |
| | | Type | — | — | — | — | — | — | — | — |
| | | Parts by mass | — | — | — | — | — | — | — | — |
| | Thermal-base | Type | — | — | — | — | — | — | — | E-1 |
| | generator | Parts by mass | — | — | — | — | — | — | — | 0.45 |
| | Silane coupling | Type | F-1 | F-1 | F-1 | F-1 | F-1 | F-1 | F-1 | F-1 |
| | agent | Parts by mass | 0.54 | 0.45 | 0.54 | 0.45 | 0.45 | 0.45 | 0.45 | 0.45 |
| | Polymerization | Type | G-1 | G-1 | G-1 | G-1 | G-1 | G-1 | G-1 | G-1 |
| | inhibitor | Parts by mass | 0.04 | 0.03 | 0.04 | 0.03 | 0.03 | 0.03 | 0.03 | 0.03 |
| | Migration | Type | H-1 | H-1 | H-1 | H-1 | H-1 | H-1 | H-1 | H-1 |
| | suppressing | Parts by mass | 0.04 | 0.03 | 0.04 | 0.03 | 0.03 | 0.03 | 0.03 | 0.03 |
| | agent | | | | | | | | | |
| | Other additives | Type | — | — | — | — | — | — | — | — |
| | | Parts by mass | — | — | — | — | — | — | — | — |
| | Solvent | Type | GBL | GBL | GBL | GBL | GBL | GBL | GBL | GBL |
| | | Parts by mass | 63.78 | 70.24 | 63.78 | 70.24 | 70.24 | 70.24 | 70.24 | 56.19 |
| | | Type | — | — | — | — | — | — | — | DMSO |
| | | Parts by mass | — | — | — | — | — | — | — | 14.05 |
| Process | Coating method | | Spin | Spin | Spin | Spin | Spin | Spin | Spin | Spin |
| | | | coating | coating | coating | coating | coating | coating | coating | coating |
| | SB | Temperature | 110 | 110 | 110 | 110 | 110 | 110 | 110 | 110 |
| | | [° C.] | | | | | | | | |
| | | Time [min] | 5 | 5 | 5 | 5 | 5 | 5 | 5 | 5 |
| | Exposure | | i-ray | i-ray | i-ray | i-ray | i-ray | i-ray | i-ray | i-ray |
| | Development | Method | Spray | Spray | Spray | Spray | Spray | Spray | Spray | Spray |
| | Curing | Method | N₂ oven | N₂ oven | N₂ oven | N₂ oven | N₂ oven | N₂ oven | N₂ oven | N₂ oven |
| | | Temperature | 230 | 230 | 230 | 230 | 230 | 230 | 230 | 230 |
| | | [° C.] | | | | | | | | |
| | | Time [min] | 180 | 180 | 180 | 180 | 180 | 180 | 180 | 180 |

| | | | | | | | | | |
|---|---|---|---|---|---|---|---|---|---|
| Result | Composition dissolution rate | 0.40 | 0.32 | 0.39 | 0.34 | 0.36 | 0.35 | 0.38 | 0.44 |
| | Resolution | B | B | A | A | A | A | A | B |
| | Pattern collapse resistance | B | B | A | A | A | A | A | B |
| | Pattern shape | A | A | A | A | A | A | A | A |

TABLE 3

| | | | Example | | | | | | | |
|---|---|---|---|---|---|---|---|---|---|---|
| | | | 9 | 10 | 11 | 12 | 13 | 14 | 15 | 16 |
| Composition | Resin | Type | P5 | P6 | P7 | P8 | P9 | P10 | P11 | P12 |
| | | Mw | 22,000 | 22,000 | 22,000 | 22,000 | 22,000 | 22,000 | 22,000 | 22,000 |
| | | Parts by mass | 23.00 | 23.00 | 23.00 | 23.00 | 23.00 | 23.00 | 23.00 | 23.00 |
| | | Dissolution rate | 0.07 | 0.07 | 0.17 | 0.1 | 0.08 | 0.07 | 0.12 | 0.14 |
| | | Type | — | — | — | — | — | — | — | — |
| | | Mw | — | — | — | — | — | — | — | — |
| | | Parts by mass | — | — | — | — | — | — | — | — |
| | | Dissolution rate | — | — | — | — | — | — | — | — |
| | Polymerization | Type | C-1 | C-1 | C-1 | C-1 | C-1 | C-1 | C-1 | C-1 |
| | initiator | Parts by mass | 0.89 | 0.89 | 0.89 | 0.89 | 0.89 | 0.89 | 0.89 | 0.89 |
| | | Type | — | — | — | — | — | — | — | — |
| | | Parts by mass | — | — | — | — | — | — | — | — |
| | Polymerizable | Type | D-1 | D-1 | D-1 | D-1 | D-1 | D-1 | D-1 | D-1 |
| | compound | Parts by mass | 5.36 | 5.36 | 5.36 | 5.36 | 5.36 | 5.36 | 5.36 | 5.36 |
| | | Type | — | — | — | — | — | — | — | — |
| | | Parts by mass | — | — | — | — | — | — | — | — |
| | Thermal-base | Type | — | — | — | — | — | — | — | — |
| | generator | Parts by mass | — | — | — | — | — | — | — | — |
| | Silane | Type | F-1 | F-1 | F-1 | F-1 | F-1 | F-1 | F-1 | F-1 |
| | coupling agent | Parts by mass | 0.45 | 0.45 | 0.45 | 0.45 | 0.45 | 0.45 | 0.45 | 0.45 |
| | Polymerization | Type | G-1 | G-1 | G-1 | G-1 | G-1 | G-1 | G-1 | G-1 |
| | inhibitor | Parts by mass | 0.03 | 0.03 | 0.03 | 0.03 | 0.03 | 0.03 | 0.03 | 0.03 |
| | Migration | Type | H-1 | H-1 | H-1 | H-1 | H-1 | H-1 | H-1 | H-1 |
| | suppressing | Parts by mass | 0.03 | 0.03 | 0.03 | 0.03 | 0.03 | 0.03 | 0.03 | 0.03 |
| | agent | | | | | | | | | |
| | Other additives | Type | — | — | — | — | — | — | — | — |
| | | Parts by mass | — | — | — | — | — | — | — | — |
| | Solvent | Type | GBL | GBL | GBL | GBL | GBL | GBL | GBL | GBL |
| | | Parts by mass | 70.24 | 70.24 | 70.24 | 70.24 | 70.24 | 70.24 | 70.24 | 70.24 |
| | | Type | — | — | — | — | — | — | — | — |
| | | Parts by mass | — | — | — | — | — | — | — | — |
| Process | Coating method | | Spin | Spin | Spin | Spin | Spin | Spin | Spin | Spin |
| | | | coating | coating | coating | coating | coating | coating | coating | coating |
| | SB | Temperature | 110 | 110 | 110 | 110 | 110 | 110 | 110 | 110 |
| | | [° C.] | | | | | | | | |
| | | Time [min] | 5 | 5 | 5 | 5 | 5 | 5 | 5 | 5 |
| | Exposure | | i-ray | i-ray | i-ray | i-ray | i-ray | i-ray | i-ray | i-ray |
| | Development | Method | Spray | Spray | Spray | Spray | Spray | Spray | Spray | Spray |
| | Curing | Method | N₂ oven | N₂ oven | N₂ oven | N₂ oven | N₂ oven | N₂ oven | N₂ oven | N₂ oven |
| | | Temperature | 230 | 230 | 230 | 230 | 230 | 230 | 230 | 230 |
| | | [° C.] | | | | | | | | |
| | | Time [min] | 180 | 180 | 180 | 180 | 180 | 180 | 180 | 180 |

| | | | | | | | | | |
|---|---|---|---|---|---|---|---|---|---|
| Result | Composition dissolution rate | 0.33 | 0.33 | 0.43 | 0.36 | 0.34 | 0.33 | 0.38 | 0.40 |
| | Resolution | A | A | B | A | A | A | A | A |
| | Pattern collapse resistance | A | A | B | A | A | A | A | A |
| | Pattern shape | A | A | A | A | A | A | A | A |

TABLE 4

| | | | Example | | | | | | | |
|---|---|---|---|---|---|---|---|---|---|---|
| | | | 17 | 18 | 19 | 20 | 21 | 22 | 23 | 24 |
| Composition | Resin | Type | P13 | P14 | P15 | P16 | P17 | P1 | P1 | P1 |
| | | Mw | 22,000 | 22,000 | 22,000 | 22,000 | 22,000 | 22,000 | 22,000 | 22,000 |
| | | Parts by mass | 23.00 | 23.00 | 23.00 | 23.00 | 23.00 | 16.10 | 16.10 | 16.10 |
| | | Dissolution rate | 0.14 | 0.14 | 0.12 | 0.12 | 0.13 | 0.1 | 0.1 | 0.1 |
| | | Type | — | — | — | — | — | P4 | P7 | P8 |
| | | Mw | — | — | — | — | — | 22,000 | 22,000 | 22,000 |
| | | Parts by mass | — | — | — | — | — | 6.90 | 6.90 | 6.90 |
| | | Dissolution rate | — | — | — | — | — | 0.12 | 0.17 | 0.1 |
| | Polymerization | Type | C-1 | C-1 | C-1 | C-1 | C-1 | C-1 | C-1 | C-1 |
| | initiator | Parts by mass | 0.89 | 0.89 | 0.89 | 0.89 | 0.89 | 0.89 | 0.89 | 0.89 |
| | | Type | — | — | — | — | — | — | — | — |
| | | Parts by mass | — | — | — | — | — | — | — | — |
| | Polymerizable | Type | D-1 | D-1 | D-1 | D-1 | D-1 | D-1 | D-1 | D-1 |
| | compound | Parts by mass | 5.36 | 5.36 | 5.36 | 5.36 | 5.36 | 5.36 | 5.36 | 5.36 |
| | | Type | — | — | — | — | — | — | — | — |
| | | Parts by mass | — | — | — | — | — | — | — | — |
| | Thermal-base | Type | — | — | — | — | — | — | — | — |
| | generator | Parts by mass | — | — | — | — | — | — | — | — |
| | Silane | Type | F-1 | F-1 | F-1 | F-1 | F-1 | F-1 | F-1 | F-1 |
| | coupling agent | Parts by mass | 0.45 | 0.45 | 0.45 | 0.45 | 0.45 | 0.45 | 0.45 | 0.45 |
| | Polymerization | Type | G-1 | G-1 | G-1 | G-1 | G-1 | G-1 | G-1 | G-1 |
| | inhibitor | Parts by mass | 0.03 | 0.03 | 0.03 | 0.03 | 0.03 | 0.03 | 0.03 | 0.03 |
| | Migration | Type | H-1 | H-1 | H-1 | H-1 | H-1 | H-1 | H-1 | H-1 |
| | suppressing | Parts by mass | 0.03 | 0.03 | 0.03 | 0.03 | 0.03 | 0.03 | 0.03 | 0.03 |
| | agent | | | | | | | | | |
| | Other | Type | — | — | — | — | — | — | — | — |
| | additives | Parts by mass | — | — | — | — | — | — | — | — |
| | Solvent | Type | GBL | GBL | GBL | GBL | GBL | GBL | GBL | GBL |
| | | Parts by mass | 70.24 | 70.24 | 70.24 | 70.24 | 70.24 | 70.24 | 70.24 | 70.24 |
| | | Type | — | — | — | — | — | — | — | — |
| | | Parts by mass | — | — | — | — | — | — | — | — |
| Process | Coating method | | Spin | Spin | Spin | Spin | Spin | Spin | Spin | Spin |
| | | | coating | coating | coating | coating | coating | coating | coating | coating |
| | SB | Temperature | 110 | 110 | 110 | 110 | 110 | 110 | 110 | 110 |
| | | [° C.] | | | | | | | | |
| | | Time [min] | 5 | 5 | 5 | 5 | 5 | 5 | 5 | 5 |
| | Exposure | | i-ray | i-ray | i-ray | i-ray | i-ray | i-ray | i-ray | i-ray |
| | Development | Method | Spray | Spray | Spray | Spray | Spray | Spray | Spray | Spray |
| | Curing | Method | N₂ oven | N₂ oven | N₂ oven | N₂ oven | N₂ oven | N₂ oven | N₂ oven | N₂ oven |
| | | Temperature | 230 | 230 | 230 | 230 | 230 | 230 | 230 | 230 |
| | | [° C.] | | | | | | | | |
| | | Time [min] | 180 | 180 | 180 | 180 | 180 | 180 | 180 | 180 |

| | | | | | | | | | |
|---|---|---|---|---|---|---|---|---|---|
| Result | Composition dissolution rate | 0.40 | 0.40 | 0.38 | 0.38 | 0.39 | 0.36 | 0.36 | 0.36 |
| | Resolution | A | A | A | A | A | A | A | A |
| | Pattern collapse resistance | A | A | A | A | A | A | A | A |
| | Pattern shape | A | A | A | A | A | A | A | A |

TABLE 5

| | | | Example | | | | | | | |
|---|---|---|---|---|---|---|---|---|---|---|
| | | | 25 | 26 | 27 | 28 | 29 | 30 | 31 | 32 |
| Composition | Resin | Type | P1 | P1 | P1 | P1 | P1 | P1 | P1 | P1 |
| | | Mw | 22,000 | 22,000 | 22,000 | 22,000 | 22,000 | 22,000 | 22,000 | 22,000 |
| | | Parts by mass | 11.50 | 4.60 | 16.10 | 23.00 | 23.00 | 23.00 | 23.00 | 23.00 |
| | | Dissolution rate | 0.1 | 0.1 | 0.1 | 0.1 | 0.1 | 0.1 | 0.1 | 0.1 |
| | | Type | P8 | P8 | P1 | — | — | — | — | — |
| | | Mw | 22,000 | 22,000 | 7,500 | — | — | — | — | — |
| | | Parts by mass | 11.50 | 18.40 | 6.90 | — | — | — | — | — |
| | | Dissolution rate | 0.1 | 0.1 | 0.14 | — | — | — | — | — |
| | Polymerization | Type | C-1 | C-1 | C-1 | C-1 | C-1 | C-1 | C-1 | C-1 |
| | initiator | Parts by mass | 0.89 | 0.89 | 0.89 | 0.89 | 0.89 | 0.89 | 0.89 | 0.89 |
| | | Type | — | — | — | — | — | — | — | — |
| | | Parts by mass | — | — | — | — | — | — | — | — |
| | Polymerizable | Type | D-1 | D-1 | D-1 | D-1 | D-1 | D-1 | D-1 | D-1 |
| | compound | Parts by mass | 5.36 | 5.36 | 5.36 | 5.36 | 5.36 | 5.36 | 5.36 | 5.36 |
| | | Type | — | — | — | — | — | — | — | — |
| | | Parts by mass | — | — | — | — | — | — | — | — |
| | Thermal-base | Type | — | — | — | — | — | — | — | — |
| | generator | Parts by mass | — | — | — | — | — | — | — | — |
| | Silane | Type | F-1 | F-1 | F-1 | F-1 | F-1 | F-1 | F-1 | F-1 |
| | coupling agent | Parts by mass | 0.45 | 0.45 | 0.45 | 0.45 | 0.45 | 0.45 | 0.45 | 0.45 |
| | Polymerization | Type | G-1 | G-1 | G-1 | G-1 | G-1 | G-1 | G-1 | G-1 |
| | inhibitor | Parts by mass | 0.03 | 0.03 | 0.03 | 0.03 | 0.03 | 0.03 | 0.03 | 0.03 |
| | Migration | Type | H-1 | H-1 | H-1 | H-1 | H-1 | H-1 | H-1 | H-1 |
| | suppressing | Parts by mass | 0.03 | 0.03 | 0.03 | 0.03 | 0.03 | 0.03 | 0.03 | 0.03 |
| | agent | | | | | | | | | |
| | Other | Type | — | — | — | — | — | — | — | — |
| | additives | Parts by mass | — | — | — | — | — | — | — | — |
| | Solvent | Type | GBL | GBL | GBL | GBL | GBL | GBL | GBL | GBL |
| | | Parts by mass | 70.24 | 70.24 | 70.24 | 70.24 | 70.24 | 70.24 | 70.24 | 70.24 |
| | | Type | — | — | — | — | — | — | — | — |
| | | Parts by mass | — | — | — | — | — | — | — | — |
| Process | Coating method | | Spin | Spin | Spin | Spin | Spin | Spin | Spin | Spin |
| | | | coating | coating | coating | coating | coating | coating | coating | coating |
| | SB | Temperature | 110 | 110 | 110 | 110 | 120 | 110 | 120 | 110 |
| | | [° C.] | | | | | | | | |
| | | Time [min] | 5 | 5 | 5 | 5 | 5 | 3 | 3 | 5 |
| | Exposure | | i-ray | i-ray | i-ray | i-ray | i-ray | i-ray | i-ray | i-ray |
| | Development | Method | Spray | Spray | Spray | Spray | Spray | Spray | Spray | Puddle |
| | Curing | Method | N₂ oven | N₂ oven | N₂ oven | N₂ oven | N₂ oven | N₂ oven | N₂ oven | N₂ oven |
| | | Temperature | 230 | 230 | 230 | 230 | 230 | 230 | 230 | 230 |
| | | [° C.] | | | | | | | | |
| | | Time [min] | 180 | 180 | 180 | 180 | 180 | 180 | 180 | 180 |

| | | | | | | | | | |
|---|---|---|---|---|---|---|---|---|---|
| Result | Composition dissolution rate | 0.36 | 0.36 | 0.36 | 0.36 | 0.33 | 0.38 | 0.36 | 0.36 |
| | Resolution | A | A | A | A | A | A | A | A |
| | Pattern collapse resistance | A | A | A | A | A | A | A | A |
| | Pattern shape | A | A | A | A | A | A | A | A |

TABLE 6

| | | | Example | | | | | | | |
|---|---|---|---|---|---|---|---|---|---|---|
| | | | 33 | 34 | 35 | 36 | 37 | 38 | 39 | 40 |
| Composition | Resin | Type | P1 | P1 | P1 | P1 | P1 | P1 | P1 | P1 |
| | | Mw | 22,000 | 22,000 | 22,000 | 22,000 | 22,000 | 22,000 | 22,000 | 22,000 |
| | | Parts by mass | 23.00 | 23.00 | 23.00 | 23.00 | 23.00 | 23.00 | 23.00 | 23.00 |
| | | Dissolution rate | 0.1 | 0.1 | 0.1 | 0.1 | 0.1 | 0.1 | 0.1 | 0.1 |
| | | Type | — | — | — | — | — | — | — | — |
| | | Mw | — | — | — | — | — | — | — | — |
| | | Parts by mass | — | — | — | — | — | — | — | — |
| | | Dissolution rate | — | — | — | — | — | — | — | — |
| | Polymerization | Type | C-1 | C-1 | C-1 | C-1 | C-1 | C-1 | C-1 | C-2 |
| | initiator | Parts by mass | 0.89 | 0.89 | 0.89 | 0.89 | 0.89 | 0.89 | 0.89 | 0.89 |
| | | Type | — | — | — | — | — | — | — | — |
| | | Parts by mass | — | — | — | — | — | — | — | — |
| | Polymerizable | Type | D-1 | D-1 | D-1 | D-1 | D-1 | D-1 | D-1 | D-1 |
| | compound | Parts by mass | 5.36 | 5.36 | 5.36 | 5.36 | 5.36 | 5.36 | 5.36 | 5.36 |
| | | Type | — | — | — | — | — | — | — | — |
| | | Parts by mass | — | — | — | — | — | — | — | — |
| | Thermal-base | Type | — | — | — | — | — | — | — | — |
| | generator | Parts by mass | — | — | — | — | — | — | — | — |
| | Silane | Type | F-1 | F-1 | F-1 | F-1 | F-1 | F-1 | F-1 | F-1 |
| | coupling agent | Parts by mass | 0.45 | 0.45 | 0.45 | 0.45 | 0.45 | 0.45 | 0.45 | 0.45 |
| | Polymerization | Type | G-1 | G-1 | G-1 | G-1 | G-1 | G-1 | G-1 | G-1 |
| | inhibitor | Parts by mass | 0.03 | 0.03 | 0.03 | 0.03 | 0.03 | 0.03 | 0.03 | 0.03 |
| | Migration | Type | H-1 | H-1 | H-1 | H-1 | H-1 | H-1 | H-1 | H-1 |
| | suppressing | Parts by mass | 0.03 | 0.03 | 0.03 | 0.03 | 0.03 | 0.03 | 0.03 | 0.03 |
| | agent | | | | | | | | | |
| | Other | Type | — | — | — | — | — | — | — | — |
| | additives | Parts by mass | — | — | — | — | — | — | — | — |
| | Solvent | Type | GBL | GBL | GBL | GBL | GBL | GBL | GBL | GBL |
| | | Parts by mass | 70.24 | 70.24 | 70.24 | 70.24 | 70.24 | 70.24 | 70.24 | 70.24 |
| | | Type | — | — | — | — | — | — | — | — |
| | | Parts by mass | — | — | — | — | — | — | — | — |
| Process | Coating method | | Spin | Spin | Spin | Spin | Spin | Spin | Spin | Spin |
| | | | coating | coating | coating | coating | coating | coating | coating | coating |
| | SB | Temperature | 110 | 110 | 110 | 110 | 110 | 110 | 110 | 110 |
| | | [° C.] | | | | | | | | |
| | | Time [min] | 5 | 5 | 5 | 5 | 5 | 5 | 5 | 5 |
| | Exposure | | i-ray | i-ray | i-ray | i-ray | i-ray | i-ray | i-ray | i-ray |
| | Development | Method | Straight | Spray | Spray | Spray | Spray | Spray | Spray | Spray |
| | Curing | Method | N₂ oven | Vacuum oven | IR oven | N₂ oven | N₂ oven | N₂ oven | N₂ oven | N₂ oven |
| | | Temperature | 230 | 230 | 230 | 350 | 230 | 180 | 170 | 230 |
| | | [° C.] | | | | | | | | |
| | | Time [min] | 180 | 180 | 180 | 60 | 60 | 120 | 120 | 180 |

| | | | | | | | | | |
|---|---|---|---|---|---|---|---|---|---|
| Result | Composition dissolution rate | 0.36 | 0.36 | 0.36 | 0.36 | 0.36 | 0.36 | 0.36 | 0.36 |
| | Resolution | A | A | A | A | A | A | A | A |
| | Pattern collapse resistance | A | A | A | A | A | A | A | A |
| | Pattern shape | A | A | A | A | A | A | A | A |

TABLE 7

| | | | Example | | | | | | | |
|---|---|---|---|---|---|---|---|---|---|---|
| | | | 41 | 42 | 43 | 44 | 45 | 46 | 47 | 48 |
| Composition | Resin | Type | P1 | P1 | P1 | P1 | P1 | P1 | P1 | P1 |
| | | Mw | 22,000 | 22,000 | 22,000 | 22,000 | 22,000 | 22,000 | 22,000 | 22,000 |
| | | Parts by mass | 23.00 | 23.00 | 23.00 | 23.00 | 23.00 | 23.00 | 23.00 | 23.00 |
| | | Dissolution rate | 0.1 | 0.1 | 0.1 | 0.1 | 0.1 | 0.1 | 0.1 | 0.1 |
| | | Type | — | — | — | — | — | — | — | — |
| | | Mw | — | — | — | — | — | — | — | — |
| | | Parts by mass | — | — | — | — | — | — | — | — |
| | | Dissolution rate | — | — | — | — | — | — | — | — |
| | Polymerization | Type | C-3 | C-4 | C-5 | C-6 | C-1 | C-6 | C-1 | C-1 |
| | initiator | Parts by mass | 0.89 | 0.89 | 0.89 | 0.89 | 0.45 | 0.45 | 0.89 | 0.89 |
| | | Type | — | — | — | — | C-3 | C-3 | — | — |
| | | Parts by mass | — | — | — | — | 0.45 | 0.45 | — | — |
| | Polymerizable | Type | D-1 | D-1 | D-1 | D-1 | D-1 | D-1 | D-2 | D-3 |
| | compound | Parts by mass | 5.36 | 5.36 | 5.36 | 5.36 | 5.36 | 5.36 | 5.36 | 5.36 |
| | | Type | — | — | — | — | — | — | — | — |
| | | Parts by mass | — | — | — | — | — | — | — | — |
| | Thermal-base | Type | — | — | — | — | — | — | — | — |
| | generator | Parts by mass | — | — | — | — | — | — | — | — |
| | Silane | Type | F-1 | F-1 | F-1 | F-1 | F-1 | F-1 | F-1 | F-1 |
| | coupling agent | Parts by mass | 0.45 | 0.45 | 0.45 | 0.45 | 0.45 | 0.45 | 0.45 | 0.45 |
| | Polymerization | Type | G-1 | G-1 | G-1 | G-1 | G-1 | G-1 | G-1 | G-1 |
| | inhibitor | Parts by mass | 0.03 | 0.03 | 0.03 | 0.03 | 0.03 | 0.03 | 0.03 | 0.03 |
| | Migration | Type | H-1 | H-1 | H-1 | H-1 | H-1 | H-1 | H-1 | H-1 |
| | suppressing | Parts by mass | 0.03 | 0.03 | 0.03 | 0.03 | 0.03 | 0.03 | 0.03 | 0.03 |
| | agent | | | | | | | | | |
| | Other | Type | — | — | — | — | — | — | — | — |
| | additives | Parts by mass | — | — | — | — | — | — | — | — |
| | Solvent | Type | GBL | GBL | GBL | GBL | GBL | GBL | GBL | GBL |
| | | Parts by mass | 70.24 | 70.24 | 70.24 | 70.24 | 70.24 | 70.24 | 70.24 | 70.24 |
| | | Type | — | — | — | — | — | — | — | — |
| | | Parts by mass | — | — | — | — | — | — | — | — |
| Process | Coating method | | Spin | Spin | Spin | Spin | Spin | Spin | Spin | Spin |
| | | | coating | coating | coating | coating | coating | coating | coating | coating |
| | SB | Temperature | 110 | 110 | 110 | 110 | 110 | 110 | 110 | 110 |
| | | [° C.] | | | | | | | | |
| | | Time [min] | 5 | 5 | 5 | 5 | 5 | 5 | 5 | 5 |
| | Exposure | | i-ray | i-ray | i-ray | i-ray | i-ray | i-ray | i-ray | i-ray |
| | Development | Method | Spray | Spray | Spray | Spray | Spray | Spray | Spray | Spray |
| | Curing | Method | N₂ oven | N₂ oven | N₂ oven | N₂ oven | N₂ oven | N₂ oven | N₂ oven | N₂ oven |
| | | Temperature | 230 | 230 | 230 | 230 | 230 | 230 | 230 | 230 |
| | | [° C.] | | | | | | | | |
| | | Time [min] | 180 | 180 | 180 | 180 | 180 | 180 | 180 | 180 |

| | | | | | | | | | |
|---|---|---|---|---|---|---|---|---|---|
| Result | Composition dissolution rate | 0.36 | 0.36 | 0.36 | 0.36 | 0.36 | 0.36 | 0.36 | 0.36 |
| | Resolution | A | A | A | A | A | A | A | A |
| | Pattern collapse resistance | A | A | A | A | A | A | A | A |
| | Pattern shape | A | A | A | A | A | A | A | A |

TABLE 8

| | | | Example | | | | | | | |
|---|---|---|---|---|---|---|---|---|---|---|
| | | | 49 | 50 | 51 | 52 | 53 | 54 | 55 | 56 |
| Composition | Resin | Type | P1 | P1 | P1 | P1 | P1 | P1 | P1 | P1 |
| | | Mw | 22,000 | 22,000 | 22,000 | 22,000 | 22,000 | 22,000 | 22,000 | 22,000 |
| | | Parts by mass | 23.00 | 23.00 | 23.00 | 23.00 | 23.00 | 23.00 | 23.00 | 23.00 |
| | | Dissolution rate | 0.1 | 0.1 | 0.1 | 0.1 | 0.1 | 0.1 | 0.1 | 0.1 |
| | | Type | — | — | — | — | — | — | — | — |
| | | Mw | — | — | — | — | — | — | — | — |
| | | Parts by mass | — | — | — | — | — | — | — | — |
| | | Dissolution rate | — | — | — | — | — | — | — | — |
| | Polymerization | Type | C-1 | C-1 | C-1 | C-1 | C-1 | C-1 | C-1 | C-1 |
| | initiator | Parts by mass | 0.89 | 0.89 | 0.89 | 0.89 | 0.89 | 0.89 | 0.89 | 0.89 |
| | | Type | — | — | — | — | — | — | — | — |
| | | Parts by mass | — | — | — | — | — | — | — | — |
| | Polymerizable | Type | D-4 | D-5 | D-6 | D-7 | D-8 | D-9 | D-2 | D-3 |
| | compound | Parts by mass | 5.36 | 5.36 | 5.36 | 5.36 | 5.36 | 5.36 | 2.68 | 2.68 |
| | | Type | — | — | — | — | — | — | D-1 | D-5 |
| | | Parts by mass | — | — | — | — | — | — | 2.68 | 2.68 |
| | Thermal-base | Type | — | — | — | — | — | — | — | — |
| | generator | Parts by mass | — | — | — | — | — | — | — | — |
| | Silane | Type | F-1 | F-1 | F-1 | F-1 | F-1 | F-1 | F-1 | F-1 |
| | coupling agent | Parts by mass | 0.45 | 0.45 | 0.45 | 0.45 | 0.45 | 0.45 | 0.45 | 0.45 |
| | Polymerization | Type | G-1 | G-1 | G-1 | G-1 | G-1 | G-1 | G-1 | G-1 |
| | inhibitor | Parts by mass | 0.03 | 0.03 | 0.03 | 0.03 | 0.03 | 0.03 | 0.03 | 0.03 |
| | Migration | Type | H-1 | H-1 | H-1 | H-1 | H-1 | H-1 | H-1 | H-1 |
| | suppressing | Parts by mass | 0.03 | 0.03 | 0.03 | 0.03 | 0.03 | 0.03 | 0.03 | 0.03 |
| | agent | | | | | | | | | |
| | Other | Type | — | — | — | — | — | — | — | — |
| | additives | Parts by mass | — | — | — | — | — | — | — | — |
| | Solvent | Type | GBL | GBL | GBL | GBL | GBL | GBL | GBL | GBL |
| | | Parts by mass | 70.24 | 70.24 | 70.24 | 70.24 | 70.24 | 70.24 | 70.24 | 70.24 |
| | | Type | — | — | — | — | — | — | — | — |
| | | Parts by mass | — | — | — | — | — | — | — | — |
| Process | Coating method | | Spin | Spin | Spin | Spin | Spin | Spin | Spin | Spin |
| | | | coating | coating | coating | coating | coating | coating | coating | coating |
| | SB | Temperature | 110 | 110 | 110 | 110 | 110 | 110 | 110 | 110 |
| | | [° C.] | | | | | | | | |
| | | Time [min] | 5 | 5 | 5 | 5 | 5 | 5 | 5 | 5 |
| | Exposure | | i-ray | i-ray | i-ray | i-ray | i-ray | i-ray | i-ray | i-ray |
| | Development | Method | Spray | Spray | Spray | Spray | Spray | Spray | Spray | Spray |
| | Curing | Method | N₂ oven | N₂ oven | N₂ oven | N₂ oven | N₂ oven | N₂ oven | N₂ oven | N₂ oven |
| | | Temperature | 230 | 230 | 230 | 230 | 230 | 230 | 230 | 230 |
| | | [° C.] | | | | | | | | |
| | | Time [min] | 180 | 180 | 180 | 180 | 180 | 180 | 180 | 180 |

| | | | | | | | | | |
|---|---|---|---|---|---|---|---|---|---|
| Result | Composition dissolution rate | 0.36 | 0.36 | 0.36 | 0.36 | 0.36 | 0.36 | 0.36 | 0.36 |
| | Resolution | A | A | A | A | A | A | A | A |
| | Pattern collapse resistance | A | A | A | A | A | A | A | A |
| | Pattern shape | A | A | A | A | A | A | A | A |

TABLE 9

| | | | Example | | | | | | | |
|---|---|---|---|---|---|---|---|---|---|---|
| | | | 57 | 58 | 59 | 60 | 61 | 62 | 63 | 64 |
| Composition | Resin | Type | P1 | P1 | P1 | P1 | P1 | P1 | P1 | P1 |
| | | Mw | 22,000 | 22,000 | 22,000 | 22,000 | 22,000 | 22,000 | 22,000 | 22,000 |
| | | Parts by mass | 23.00 | 23.00 | 23.00 | 24.79 | 24.79 | 23.00 | 23.00 | 23.00 |
| | | Dissolution rate | 0.1 | 0.1 | 0.1 | 0.1 | 0.1 | 0.1 | 0.1 | 0.1 |
| | | Type | — | — | — | — | — | — | — | — |
| | | Mw | — | — | — | — | — | — | — | — |
| | | Parts by mass | — | — | — | — | — | — | — | — |
| | | Dissolution rate | — | — | — | — | — | — | — | — |
| | Polymerization | Type | C-1 | C-1 | C-1 | C-1 | C-1 | C-1 | C-1 | C-1 |
| | initiator | Parts by mass | 0.89 | 0.89 | 0.89 | 0.89 | 0.89 | 0.89 | 0.89 | 0.89 |
| | | Type | — | — | — | — | — | — | — | — |
| | | Parts by mass | — | — | — | — | — | — | — | — |
| | Polymerizable | Type | D-6 | D-6 | D-2 | D-1 | D-5 | D-1 | D-1 | D-1 |
| | compound | Parts by mass | 3.75 | 3.75 | 3.75 | 3.57 | 3.57 | 5.36 | 5.36 | 5.36 |
| | | Type | D-7 | D-8 | D-9 | — | — | — | — | — |
| | | Parts by mass | 1.61 | 1.61 | 1.61 | — | — | — | — | — |
| | Thermal-base | Type | — | — | — | — | — | — | — | — |
| | generator | Parts by mass | — | — | — | — | — | — | — | — |
| | Silane | Type | F-1 | F-1 | F-1 | F-1 | F-1 | F-2 | F-3 | F-4 |
| | coupling agent | Parts by mass | 0.45 | 0.45 | 0.45 | 0.45 | 0.45 | 0.45 | 0.45 | 0.45 |
| | Polymerization | Type | G-1 | G-1 | G-1 | G-1 | G-1 | G-1 | G-1 | G-1 |
| | inhibitor | Parts by mass | 0.03 | 0.03 | 0.03 | 0.03 | 0.03 | 0.03 | 0.03 | 0.03 |
| | Migration | Type | H-1 | H-1 | H-1 | H-1 | H-1 | H-1 | H-1 | H-1 |
| | suppressing | Parts by mass | 0.03 | 0.03 | 0.03 | 0.03 | 0.03 | 0.03 | 0.03 | 0.03 |
| | agent | | | | | | | | | |
| | Other | Type | — | — | — | — | — | — | — | — |
| | additives | Parts by mass | — | — | — | — | — | — | — | — |
| | Solvent | Type | GBL | GBL | GBL | GBL | GBL | GBL | GBL | GBL |
| | | Parts by mass | 70.24 | 70.24 | 70.24 | 70.24 | 70.24 | 70.24 | 70.24 | 70.24 |
| | | Type | — | — | — | — | — | — | — | — |
| | | Parts by mass | — | — | — | — | — | — | — | — |
| Process | Coating method | | Spin | Spin | Spin | Spin | Spin | Spin | Spin | Spin |
| | | | coating | coating | coating | coating | coating | coating | coating | coating |
| | SB | Temperature | 110 | 110 | 110 | 110 | 110 | 110 | 110 | 110 |
| | | [° C.] | | | | | | | | |
| | | Time [min] | 5 | 5 | 5 | 5 | 5 | 5 | 5 | 5 |
| | Exposure | | i-ray | i-ray | i-ray | i-ray | i-ray | i-ray | i-ray | i-ray |
| | Development | Method | Spray | Spray | Spray | Spray | Spray | Spray | Spray | Spray |
| | Curing | Method | N₂ oven | N₂ oven | N₂ oven | N₂ oven | N₂ oven | N₂ oven | N₂ oven | N₂ oven |
| | | Temperature | 230 | 230 | 230 | 230 | 230 | 230 | 230 | 230 |
| | | Time [min] | 180 | 180 | 180 | 180 | 180 | 180 | 180 | 180 |

| | | | | | | | | | |
|---|---|---|---|---|---|---|---|---|---|
| Result | Composition dissolution rate | 0.36 | 0.36 | 0.36 | 0.32 | 0.32 | 0.36 | 0.36 | 0.36 |
| | Resolution | A | A | A | A | A | A | A | A |
| | Pattern collapse resistance | A | A | A | A | A | A | A | A |
| | Pattern shape | A | A | A | A | A | A | A | A |

TABLE 10

| | | | Example | | | | | | | |
|---|---|---|---|---|---|---|---|---|---|---|
| | | | 65 | 66 | 67 | 68 | 69 | 70 | 71 | 72 |
| Composition | Resin | Type | P1 | P1 | P1 | P1 | P1 | P1 | P1 | P1 |
| | | Mw | 22,000 | 22,000 | 22,000 | 22,000 | 22,000 | 22,000 | 22,000 | 22,000 |
| | | Parts by mass | 23.00 | 23.00 | 23.00 | 23.00 | 23.00 | 23.00 | 23.00 | 23.00 |
| | | Dissolution rate | 0.1 | 0.1 | 0.1 | 0.1 | 0.1 | 0.1 | 0.1 | 0.1 |
| | | Type | — | — | — | — | — | — | — | — |
| | | Mw | — | — | — | — | — | — | — | — |
| | | Parts by mass | — | — | — | — | — | — | — | — |
| | | Dissolution rate | — | — | — | — | — | — | — | — |
| | Polymerization | Type | C-1 | C-1 | C-1 | C-1 | C-1 | C-1 | C-1 | C-1 |
| | initiator | Parts by mass | 0.89 | 0.89 | 0.89 | 0.89 | 0.89 | 0.89 | 0.89 | 0.89 |
| | | Type | — | — | — | — | — | — | — | — |
| | | Parts by mass | — | — | — | — | — | — | — | — |
| | Polymerizable | Type | D-1 | D-1 | D-1 | D-1 | D-1 | D-1 | D-1 | D-1 |
| | compound | Parts by mass | 5.36 | 5.36 | 5.36 | 5.36 | 5.36 | 5.36 | 5.36 | 5.36 |
| | | Type | — | — | — | — | — | — | — | — |
| | | Parts by mass | — | — | — | — | — | — | — | — |
| | Thermal-base | Type | — | — | — | — | — | — | — | — |
| | generator | Parts by mass | — | — | — | — | — | — | — | — |
| | Silane | Type | F-5 | F-6 | F-1 | F-1 | F-1 | F-1 | F-1 | F-1 |
| | coupling agent | Parts by mass | 0.45 | 0.45 | 0.45 | 0.45 | 0.45 | 0.45 | 0.45 | 0.45 |
| | Polymerization | Type | G-1 | G-1 | G-2 | G-3 | G-4 | G-1 | G-1 | G-1 |
| | inhibitor | Parts by mass | 0.03 | 0.03 | 0.03 | 0.03 | 0.03 | 0.03 | 0.03 | 0.03 |
| | Migration | Type | H-1 | H-1 | H-1 | H-1 | H-1 | H-2 | H-3 | H-4 |
| | suppressing | Parts by mass | 0.03 | 0.03 | 0.03 | 0.03 | 0.03 | 0.03 | 0.03 | 0.03 |
| | agent | | | | | | | | | |
| | Other | Type | — | — | — | — | — | — | — | — |
| | additives | Parts by mass | — | — | — | — | — | — | — | — |
| | Solvent | Type | GBL | GBL | GBL | GBL | GBL | GBL | GBL | GBL |
| | | Parts by mass | 70.24 | 70.24 | 70.24 | 70.24 | 70.24 | 70.24 | 70.24 | 70.24 |
| | | Type | — | — | — | — | — | — | — | — |
| | | Parts by mass | — | — | — | — | — | — | — | — |
| Process | Coating method | | Spin | Spin | Spin | Spin | Spin | Spin | Spin | Spin |
| | | | coating | coating | coating | coating | coating | coating | coating | coating |
| | SB | Temperature | 110 | 110 | 110 | 110 | 110 | 110 | 110 | 110 |
| | | [° C.] | | | | | | | | |
| | | Time [min] | 5 | 5 | 5 | 5 | 5 | 5 | 5 | 5 |
| | Exposure | | i-ray | i-ray | i-ray | i-ray | i-ray | i-ray | i-ray | i-ray |
| | Development | Method | Spray | Spray | Spray | Spray | Spray | Spray | Spray | Spray |
| | Curing | Method | N₂ oven | N₂ oven | N₂ oven | N₂ oven | N₂ oven | N₂ oven | N₂ oven | N₂ oven |
| | | Temperature | 230 | 230 | 230 | 230 | 230 | 230 | 230 | 230 |
| | | [° C.] | | | | | | | | |
| | | Time [min] | 180 | 180 | 180 | 180 | 180 | 180 | 180 | 180 |

| | | | | | | | | | |
|---|---|---|---|---|---|---|---|---|---|
| Result | Composition dissolution rate | 0.36 | 0.36 | 0.36 | 0.36 | 0.36 | 0.36 | 0.36 | 0.36 |
| | Resolution | A | A | A | A | A | A | A | A |
| | Pattern collapse resistance | A | A | A | A | A | A | A | A |
| | Pattern shape | A | A | A | A | A | A | A | A |

TABLE 11

| | | | Example | | | | | | | |
|---|---|---|---|---|---|---|---|---|---|---|
| | | | 73 | 74 | 75 | 76 | 77 | 78 | 79 | 80 |
| Composition | Resin | Type | P1 | P1 | P1 | P1 | P1 | P1 | P1 | P1 |
| | | Mw | 22,000 | 22,000 | 22,000 | 22,000 | 22,000 | 22,000 | 22,000 | 22,000 |
| | | Parts by mass | 23.00 | 23.00 | 23.00 | 23.00 | 23.00 | 23.00 | 23.00 | 23.00 |
| | | Dissolution rate | 0.1 | 0.1 | 0.1 | 0.1 | 0.1 | 0.1 | 0.1 | 0.1 |
| | | Type | — | — | — | — | — | — | — | — |
| | | Mw | — | — | — | — | — | — | — | — |
| | | Parts by mass | — | — | — | — | — | — | — | — |
| | | Dissolution rate | — | — | — | — | — | — | — | — |
| | Polymerization | Type | C-1 | C-1 | C-1 | C-1 | C-1 | C-1 | C-1 | C-1 |
| | initiator | Parts by mass | 0.89 | 0.89 | 0.89 | 0.89 | 0.89 | 0.89 | 0.89 | 0.89 |
| | | Type | — | — | — | — | — | — | — | — |
| | | Parts by mass | — | — | — | — | — | — | — | — |
| | Polymerizable | Type | D-1 | D-1 | D-1 | D-1 | D-1 | D-1 | D-1 | D-1 |
| | compound | Parts by mass | 4.91 | 4.91 | 4.91 | 4.91 | 5.21 | 4.91 | 5.33 | 5.33 |
| | | Type | — | — | — | — | — | — | — | — |
| | | Parts by mass | — | — | — | — | — | — | — | — |
| | Thermal-base | Type | — | — | — | — | — | — | — | — |
| | generator | Parts by mass | — | — | — | — | — | — | — | — |
| | Silane | Type | F-1 | F-1 | F-1 | F-1 | F-1 | F-1 | F-1 | F-1 |
| | coupling agent | Parts by mass | 0.45 | 0.45 | 0.45 | 0.45 | 0.45 | 0.45 | 0.45 | 0.45 |
| | Polymerization | Type | G-1 | G-1 | G-1 | G-1 | G-1 | G-1 | G-1 | G-1 |
| | inhibitor | Parts by mass | 0.03 | 0.03 | 0.03 | 0.03 | 0.03 | 0.03 | 0.03 | 0.03 |
| | Migration | Type | H-1 | H-1 | H-1 | H-1 | H-1 | H-1 | H-1 | H-1 |
| | suppressing | Parts by mass | 0.03 | 0.03 | 0.03 | 0.03 | 0.03 | 0.03 | 0.03 | 0.03 |
| | agent | | | | | | | | | |
| | Other | Type | I-1 | I-2 | I-3 | I-4 | I-5 | I-6 | I-7 | I-8 |
| | additives | Parts by mass | 0.45 | 0.45 | 0.45 | 0.45 | 0.15 | 0.45 | 0.03 | 0.03 |
| | Solvent | Type | GBL | GBL | GBL | GBL | GBL | GBL | GBL | GBL |
| | | Parts by mass | 70.24 | 70.24 | 70.24 | 70.24 | 70.24 | 70.24 | 70.24 | 70.24 |
| | | Type | — | — | — | — | — | — | — | — |
| | | Parts by mass | — | — | — | — | — | — | — | — |
| Process | Coating method | | Spin | Spin | Spin | Spin | Spin | Spin | Spin | Spin |
| | | | coating | coating | coating | coating | coating | coating | coating | coating |
| | SB | Temperature | 110 | 110 | 110 | 110 | 110 | 110 | 110 | 110 |
| | | [° C.] | | | | | | | | |
| | | Time [min] | 5 | 5 | 5 | 5 | 5 | 5 | 5 | 5 |
| | Exposure | | i-ray | i-ray | i-ray | i-ray | i-ray | i-ray | i-ray | i-ray |
| | Development | Method | Spray | Spray | Spray | Spray | Spray | Spray | Spray | Spray |
| | Curing | Method | N₂ oven | N₂ oven | N₂ oven | N₂ oven | N₂ oven | N₂ oven | N₂ oven | N₂ oven |
| | | Temperature | 230 | 230 | 230 | 230 | 230 | 230 | 230 | 230 |
| | | [° C.] | | | | | | | | |
| | | Time [min] | 180 | 180 | 180 | 180 | 180 | 180 | 180 | 180 |

| | | | | | | | | | |
|---|---|---|---|---|---|---|---|---|---|
| Result | Composition dissolution rate | 0.36 | 0.36 | 0.26 | 0.36 | 0.36 | 0.36 | 0.34 | 0.34 |
| | Resolution | A | A | A | A | A | A | A | A |
| | Pattern collapse resistance | A | A | A | A | A | A | A | A |
| | Pattern shape | A | A | A | A | A | A | A | A |

TABLE 12

| | | | Example | | | | | | | |
|---|---|---|---|---|---|---|---|---|---|---|
| | | | 81 | 82 | 83 | 84 | 85 | 86 | 87 | 88 |
| Composition | Resin | Type | P1 | P1 | P1 | P1 | P1 | P1 | P1 | P1 |
| | | Mw | 22,000 | 22,000 | 22,000 | 22,000 | 22,000 | 22,000 | 22,000 | 22,000 |
| | | Parts by mass | 23.00 | 23.00 | 23.00 | 23.00 | 23.00 | 23.00 | 23.00 | 23.00 |
| | | Dissolution rate | 0.1 | 0.1 | 0.1 | 0.1 | 0.1 | 0.1 | 0.1 | 0.1 |
| | | Type | — | — | — | — | — | — | — | — |
| | | Mw | — | — | — | — | — | — | — | — |
| | | Parts by mass | — | — | — | — | — | — | — | — |
| | | Dissolution rate | — | — | — | — | — | — | — | — |
| | Polymerization | Type | C-1 | C-1 | C-1 | C-1 | C-1 | C-1 | C-1 | C-1 |
| | initiator | Parts by mass | 0.89 | 0.89 | 0.89 | 0.89 | 0.89 | 0.89 | 0.89 | 0.89 |
| | | Type | — | — | — | — | — | — | — | — |
| | | Parts by mass | — | — | — | — | — | — | — | — |
| | Polymerizable | Type | D-5 | D-5 | D-5 | D-5 | D-5 | D-5 | D-5 | D-5 |
| | compound | Parts by mass | 4.91 | 4.91 | 4.91 | 4.91 | 5.21 | 4.91 | 5.33 | 5.33 |
| | | Type | — | — | — | — | — | — | — | — |
| | | Parts by mass | — | — | — | — | — | — | — | — |
| | Thermal-base | Type | — | — | — | — | — | — | — | — |
| | generator | Parts by mass | — | — | — | — | — | — | — | — |
| | Silane | Type | F-1 | F-1 | F-1 | F-1 | F-1 | F-1 | F-1 | F-1 |
| | coupling agent | Parts by mass | 0.45 | 0.45 | 0.45 | 0.45 | 0.45 | 0.45 | 0.45 | 0.45 |
| | Polymerization | Type | G-1 | G-1 | G-1 | G-1 | G-1 | G-1 | G-1 | G-1 |
| | inhibitor | Parts by mass | 0.03 | 0.03 | 0.03 | 0.03 | 0.03 | 0.03 | 0.03 | 0.03 |
| | Migration | Type | H-1 | H-1 | H-1 | H-1 | H-1 | H-1 | H-1 | H-1 |
| | suppressing | Parts by mass | 0.03 | 0.03 | 0.03 | 0.03 | 0.03 | 0.03 | 0.03 | 0.03 |
| | agent | | | | | | | | | |
| | Other | Type | I-1 | I-2 | I-3 | I-4 | I-5 | I-6 | I-7 | I-8 |
| | additives | Parts by mass | 0.45 | 0.45 | 0.45 | 0.45 | 0.15 | 0.45 | 0.03 | 0.03 |
| | Solvent | Type | GBL | GBL | GBL | GBL | GBL | GBL | GBL | GBL |
| | | Parts by mass | 70.24 | 70.24 | 70.24 | 70.24 | 70.24 | 70.24 | 70.24 | 70.24 |
| | | Type | — | — | — | — | — | — | — | — |
| | | Parts by mass | — | — | — | — | — | — | — | — |
| Process | Coating method | | Spin | Spin | Spin | Spin | Spin | Spin | Spin | Spin |
| | | | coating | coating | coating | coating | coating | coating | coating | coating |
| | SB | Temperature | 110 | 110 | 110 | 110 | 110 | 110 | 110 | 110 |
| | | [° C.] | | | | | | | | |
| | | Time [min] | 5 | 5 | 5 | 5 | 5 | 5 | 5 | 5 |
| | Exposure | | i-ray | i-ray | i-ray | i-ray | i-ray | i-ray | i-ray | i-ray |
| | Development | Method | Spray | Spray | Spray | Spray | Spray | Spray | Spray | Spray |
| | Curing | Method | N₂ oven | N₂ oven | N₂ oven | N₂ oven | N₂ oven | N₂ oven | N₂ oven | N₂ oven |
| | | Temperature | 230 | 230 | 230 | 230 | 230 | 230 | 230 | 230 |
| | | [° C.] | | | | | | | | |
| | | Time [min] | 180 | 180 | 180 | 180 | 180 | 180 | 180 | 180 |

| | | | | | | | | | |
|---|---|---|---|---|---|---|---|---|---|
| Result | Composition dissolution rate | 0.36 | 0.36 | 0.26 | 0.36 | 0.36 | 0.36 | 0.34 | 0.34 |
| | Resolution | A | A | A | A | A | A | A | A |
| | Pattern collapse resistance | A | A | A | A | A | A | A | A |
| | Pattern shape | A | A | A | A | A | A | A | A |

TABLE 13

| | | | Example | | | | Comparative Example | |
|---|---|---|---|---|---|---|---|---|
| | | | 89 | 90 | 91 | 92 | 1 | 2 |
| Composition | Resin | Type | P1 | P1 | P1 | P4 | B-1 | B-2 |
| | | Mw | 22,000 | 22,000 | 22,000 | 22,000 | 7,500 | 50,000 |
| | | Parts by mass | 23.00 | 23.00 | 23.00 | 23.00 | 12.95 | 18.00 |
| | | Dissolution rate | 0.1 | 0.1 | 0.1 | 0.18 | >0.3 | <0.01 |
| | | Type | — | — | — | — | — | — |
| | | Mw | — | — | — | — | — | — |
| | | Parts by mass | — | — | — | — | — | — |
| | | Dissolution rate | — | — | — | — | — | — |
| | Polymerization | Type | C-1 | C-1 | C-1 | C-1 | C-7 | C-1 |
| | initiator | Parts by mass | 0.89 | 0.89 | 0.89 | 0.89 | 0.20 | 0.70 |
| | | Type | — | — | — | — | C-8 | — |
| | | Parts by mass | — | — | — | — | 0.20 | — |
| | Polymerizable | Type | D-1 | D-1 | D-5 | D-1 | D-10 | D-1 |
| | compound | Parts by mass | 5.36 | 4.91 | 4.91 | 4.91 | 2.99 | 4.19 |
| | | Type | — | — | — | — | D-11 | — |
| | | Parts by mass | — | — | — | — | 1.00 | — |
| | Thermal-base | Type | — | — | — | E-1 | — | — |
| | generator | Parts by mass | — | — | — | 0.45 | — | — |
| | Silane coupling | Type | F-1 | F-1 | F-1 | F-1 | — | F-1 |
| | agent | Parts by mass | 0.45 | 0.45 | 0.45 | 0.45 | — | 0.35 |
| | Polymerization | Type | G-1 | G-1 | G-1 | G-1 | — | G-1 |
| | inhibitor | Parts by mass | 0.03 | 0.03 | 0.03 | 0.03 | — | 0.02 |
| | Migration | Type | H-1 | H-1 | H-1 | H-1 | — | H-1 |
| | suppressing | Parts by mass | 0.03 | 0.03 | 0.03 | 0.03 | — | 0.02 |
| | agent | | | | | | | |
| | Other additives | Type | — | I-1 | I-1 | — | I-9 | — |
| | | Parts by mass | — | 0.45 | 0.45 | — | 2.99 | — |
| | Solvent | Type | GVL | GVL | GVL | NMP | GBL | GBL |
| | | Parts by mass | 70.24 | 70.24 | 70.24 | 70.24 | 79.68 | 76.71 |
| | | Type | — | — | — | — | — | — |
| | | Parts by mass | — | — | — | — | — | — |
| Process | Coating method | | Spin coating | Spin coating | Spin coating | Spin coating | Spin coating | Spin coating |
| | SB | Temperature | 110 | 110 | 110 | 110 | 110 | 110 |
| | | [° C.] | | | | | | |
| | | Time [min] | 5 | 5 | 5 | 5 | 5 | 5 |
| | Exposure | | i-ray | i-ray | i-ray | i-ray | i-ray | i-ray |
| | Development | Method | Spray | Spray | Spray | Spray | Spray | Spray |
| | Curing | Method | N₂ oven | N₂ oven | N₂ oven | N₂ oven | N₂ oven | N₂ oven |
| | | Temperature | 230 | 230 | 230 | 230 | 230 | 230 |
| | | [° C.] | | | | | | |
| | | Time [min] | 180 | 180 | 180 | 180 | 180 | 180 |

| | | | | | | | |
|---|---|---|---|---|---|---|---|
| Result | Composition dissolution rate | 0.36 | 0.36 | 0.36 | 0.50 | >0.55 | <0.01 |
| | Resolution | A | A | A | B | C | C |
| | Pattern collapse resistance | A | A | A | B | C | C |
| | Pattern shape | A | A | A | A | B | B |

Details of each of the components listed in the table are as follows.

### [Resin]

P-1 to P-17, B-1, and B-2: P-1 to P-17, B-1, and B-2 synthesized above

### [Polymerization Initiator]

C-1 to C-8: Compounds having the following structures

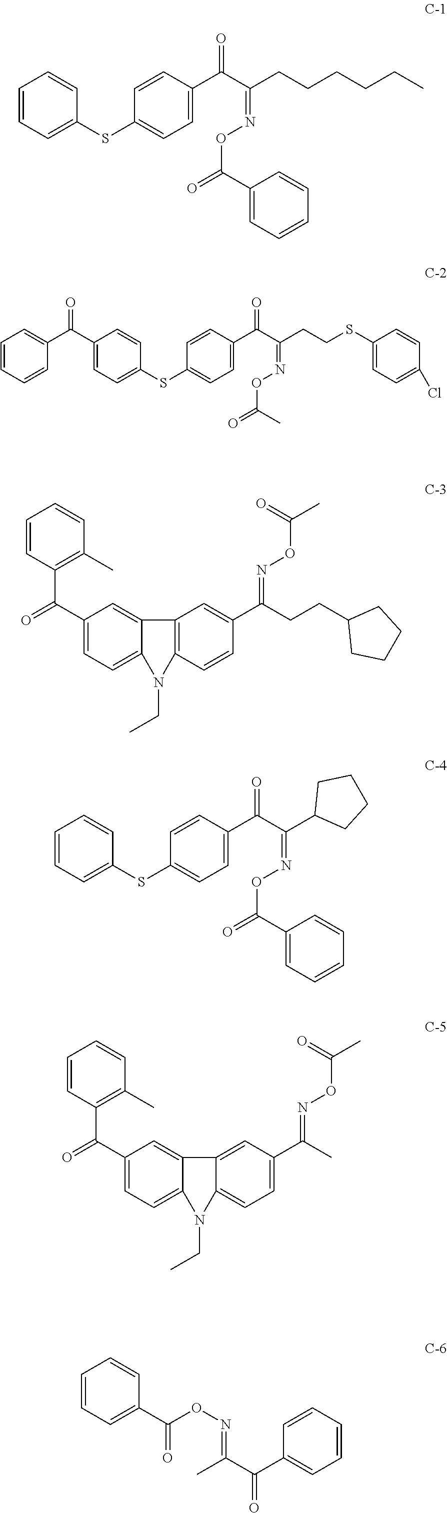 [SMILES: CCCCCC/C(=N/OC(=O)c1ccccc1)C(=O)c1ccc(Sc2ccccc2)cc1 ; CC(=O)O/N=C(/CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCC3CCCC3)=N/OC(C)=O)ccc21 ; O=C(O/N=C(\C(=O)c1ccc(Sc2ccccc2)cc1)C1CCCC1)c1ccccc1 ; CCn1c2ccc(C(=O)c3ccccc3C)cc2c2cc(/C(C)=N/OC(C)=O)ccc21 ; C/C(=N\OC(=O)c1ccccc1)C(=O)c1ccccc1]

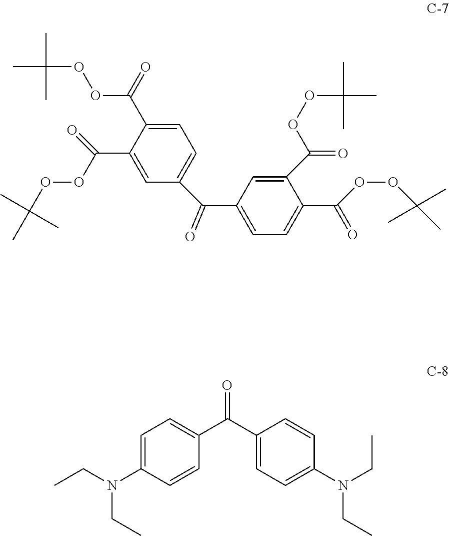

### [Polymerizable Compound]

D-1: SR-209 (manufactured by Sartomer Company Inc.)
D-2: LIGHT ACRYLATE 4EG-A (manufactured by KYOEISHA CHEMICAL Co., Ltd.)
D-3: NOD-N (manufactured by Shin-Nakamura Chemical Co., Ltd.)
D-4: A-DOD-N (manufactured by Shin-Nakamura Chemical Co., Ltd.)
D-5: DDD (1,12-dodecanediol dimethacrylate, manufactured by Shin-Nakamura Chemical Co., Ltd.)
D-6: A-DCP (manufactured by Shin-Nakamura Chemical Co., Ltd.)
D-7: A-9300 (manufactured by Shin-Nakamura Chemical Co., Ltd.)
D-8: A-GLY-9E (manufactured by Shin-Nakamura Chemical Co., Ltd.)
D-9: TMPT (manufactured by Shin-Nakamura Chemical Co., Ltd.)
D-10: NK ESTER A-BPE-30 (manufactured by Shin-Nakamura Chemical Co., Ltd.)
D-11: BR-31 (manufactured by DKS Co., Ltd.)

### [Thermal-Base Generator]

E-1: A compound having the following structure

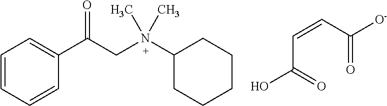

### [Silane Coupling Agent]

F-1: A compound having the following structure
F-2: X-12-967C (manufactured by Shin-Etsu Chemical Co., Ltd.)
F-3: KBM-503 (manufactured by Shin-Etsu Chemical Co., Ltd.)
F-4: KBM-1083 (manufactured by Shin-Etsu Chemical Co., Ltd.)
F-5: KBM-573 (manufactured by Shin-Etsu Chemical Co., Ltd.)
F-6: KBE-903 (manufactured by Shin-Etsu Chemical Co., Ltd.)

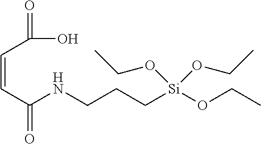 [SMILES: CCO[Si](CCCNC(=O)/C=C\C(=O)O)(OCC)OCC]

### [Polymerization Inhibitor]

G-1 to G-4: Compounds having the following structures

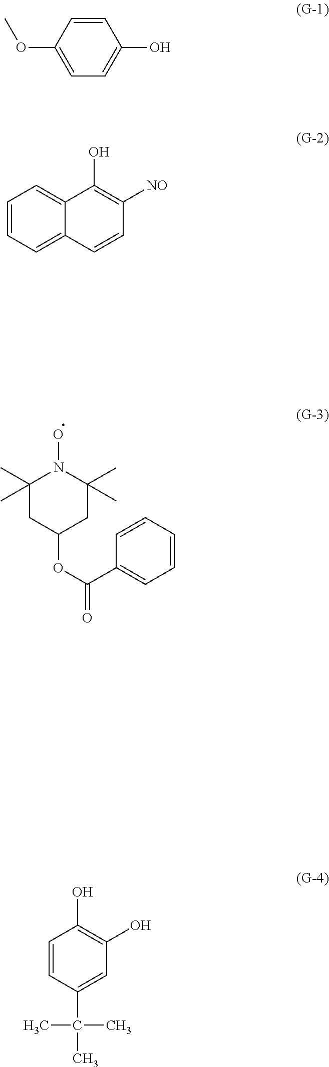

### [Migration Suppressing Agent]

H-1 to H-4: compounds having the following structures

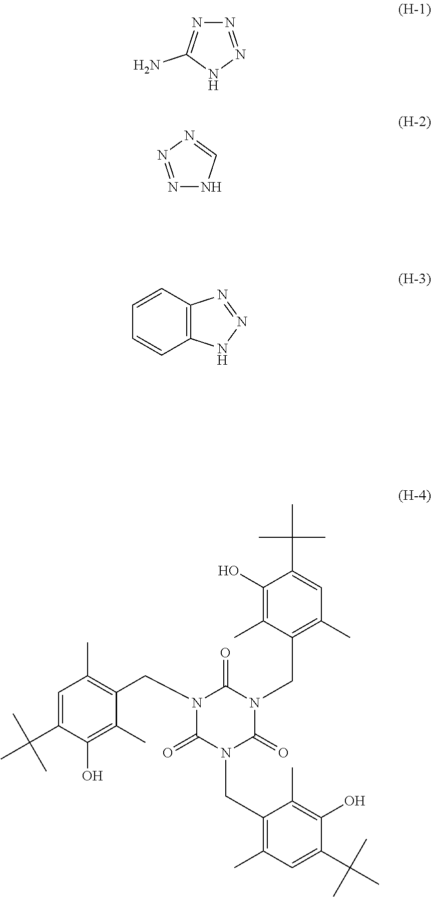 [SMILES: Nc1nnn[nH]1 ; c1nnn[nH]1 ; c1ccc2[nH]nnc2c1 ; Cc1cc(C(C)(C)C)c(O)c(C)c1Cn1c(=O)n(Cc2c(C)cc(C(C)(C)C)c(O)c2C)c(=O)n(Cc2c(C)cc(C(C)(C)C)c(O)c2C)c1=O]

### [Other Additives]

I-1: A compound having the following structure (titanium compound)
I-2: A compound having the following structure (titanium compound)
I-3: TC-750 (manufactured by Matsumoto Fine Chemical Co., Ltd.)
I-4: Ester of 2,2′,3,3′-tetrahydro-3,3,3′,3′-tetramethyl-1,1′-spirobi (1H-inden)-5,5′,6,6′,7,7′-hexanol and 1,2-naphthoquinone-(2)-diazo-5-sulfonic acid (NQD (naphthoquinone diazide))
I-5: A compound having the following structure
I-6: PARKMILL D (manufactured by NOF Corporation)
I-7: F-554 (fluorine-based surfactant, manufactured by Shin-Etsu Chemical Co., Ltd.)
I-8: KF-6000 (silicone-based surfactant, manufactured by Shin-Etsu Chemical Co., Ltd.)
I-9: triphenyl phosphate

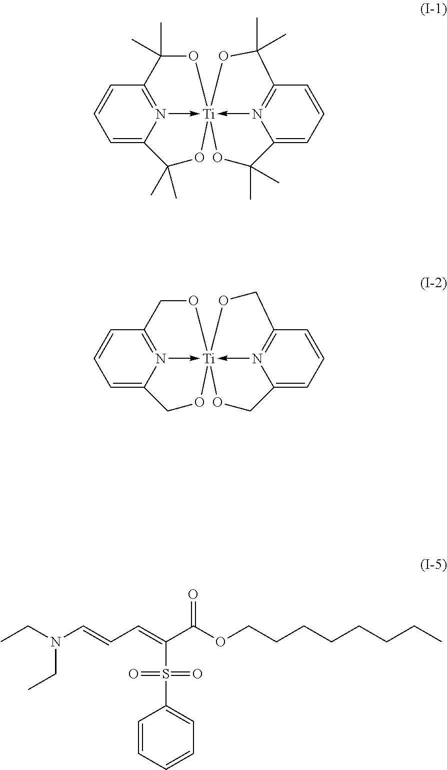

### [Solvent]

GBL: γ-butyrolactone
GVL: γ-valerolactone
DMSO: dimethyl sulfoxide.
NMP: N-methyl-2-pyrrolidone

### [Curing Method]

N2 OVEN: CLH-21 (manufactured by Koyo Corporation)
Vacuum oven: PB12 (manufactured by Yield Engineering Systems, Inc.)
IR oven: RTP-6 (manufactured by ADVANCE RIKO, Inc.)

### <Evaluation>

### [Measurement of Dissolution Rate]

In each of Examples and Comparative Examples, the composition having the composition shown in the table was applied onto a silicon wafer by the method described in the column of “Coating method” in the table, and heating was carried out at the temperature described in the column of “Temperature” of “SB” and the time described in the column of “Time” of “SB” in the table, so that a resin composition layer (film) having the film thickness of 10 μm was formed on the silicon wafer.

The silicon wafer on which the obtained resin composition layer was formed was immersed in cyclopentanone for 15 seconds, and then the wafer was rotated at 2,000 rpm for 10 seconds after the immersion. After that, the film thickness of the resin composition layer after the immersion was measured at 10 points on the coated surface with an ellipsometer (KT-22 manufactured by FOOTHILL), and the arithmetic mean value thereof was obtained. The dissolution rate (μm/sec) was calculated from 10 μm, which is the film thickness measured by the above-described measurement and the film thickness before immersion. The measurement results are described in the column of “Composition dissolution rate” in the table.

In addition, a resin layer (film) was formed from the GBL (γ-butyrolactone) solution of each resin used in each of Examples and Comparative Examples by the same method as described above, and the dissolution rate was measured. The measurement results are described in the column of “Dissolution rate” of “Resin” in the table. [Evaluation of resolution]

In each of Examples and Comparative Examples, the resin composition having the composition shown in the table was applied onto a silicon wafer by the method described in the column of “Coating method” in the table, and heating was carried out at the temperature described in the column of “Temperature” of “SB” and the time described in the column of “Time” of “SB” in the table, so that a resin composition layer was formed on the silicon wafer such that the film thickness of the obtained cured substance was 3 μm. The coating conditions were appropriately adjusted. The obtained resin composition layer was exposed using an i-ray stepper (manufactured by Canon Inc.: FPA-3000 i5) in a range of 100 to 800 mJ/cm² at each exposure amount in increments of 50 mJ/cm² using a square via mask in which a pattern was formed in increments of 0.5 μm up to 0.5 to 10 μm.

Thereafter, the development was carried out with cyclopentanone for 30 seconds and rinsing was carried out with propylene glycol monomethyl ether acetate (PGMEA) for 30 seconds according to the method described in the column of “Method” in “Development” of the table.

Furthermore, using the device described in the column of “Method” of “Curing” in the table, heating was carried out at the temperature and time described in the columns of “Temperature” and “Time” of “Curing” in the table to obtain a cured substance having a film thickness of 3 μm.

The minimum opening mask diameter of the obtained cured substance was determined by observing the cross section of the opening pattern portion with a scanning electron microscope S-4800 (manufactured by Hitachi High-Technologies Corporation), and evaluated according to the following evaluation standard. The minimum opening mask diameter was the smallest among the mask diameters in which the opening pattern was formed with at least one exposure amount among the above-described exposure amounts. The evaluation results are described in the column of “Resolution” in the table.

### (Evaluation Standards)

A: The minimum opening mask diameter was 3 μm or less.
B: The minimum opening mask diameter was more than 3 μm and 5 μm or less.
C: The minimum opening mask diameter was more than 5 μm.

### [Evaluation of Pattern Collapse Resistance]

In each of Examples and Comparative Examples, a resin pattern having a film thickness of 3 μm was obtained by the same method as above, except that in the above-described “Evaluation of resolution”, the square via mask was changed to a line-and-space mask up to 0.5 μm to 10 μm in increments of 0.5 μm.

The maximum collapse occurrence mask width of the obtained resin pattern was determined by observing the cross section of the line-and-space portion with a scanning electron microscope S-4800 (manufactured by Hitachi High-Tech Corporation), and evaluated according to the following evaluation standard. The maximum collapse occurrence mask width was the maximum mask diameter among the mask diameters at which the pattern collapse was observed at at least one exposure amount among each exposure amount described above. The evaluation results are described in the column of “Pattern collapse resistance” in the table.

### (Evaluation Standards)

A: The maximum collapse occurrence mask diameter was 2 μm or less.
B: The maximum collapse occurrence mask diameter was more than 2 μm and 3 μm or less.
C: The maximum collapse occurrence mask diameter was more than 3 μm.

### [Evaluation of Pattern Shape]

In each of Examples and Comparative Examples, a resin pattern having a film thickness of 3 μm was obtained by the same method as in the above-described “Evaluation of resolution”.

The taper angle of the opening portion of the 5 μm square via of the obtained resin pattern was measured, and the taper angle of at least one exposure amount among the results of the exposure at each of the above-described exposure amounts was evaluated as “A” in a case of being 80° or more and less than 90°, and evaluated as “B” in a case of being other than 80° or more and less than 90°. The taper angle was calculated by cutting the base material on which the resin pattern was formed and observing the cross section with a scanning electron microscope. The evaluation results are described in the column of “Pattern shape” in Table.

From the above results, it can be seen that the resin composition according to the embodiment of the present invention has excellent resolution in a case of forming a pattern of a cured substance.

In the resin composition of Comparative Example 1, the dissolution rate of the film having a film thickness of 10 μm, which is obtained from the composition, in cyclopentanone is more than 0.55 μm/sec, and the dissolution rate of the film having a film thickness of 10 μm of the contained resin in cyclopentanone is more than 0.2 μm/sec. In such a comparative example, it can be seen that the resolution is inferior.

In the resin composition of Comparative Example 2, the dissolution rate of the film having a film thickness of 10 μm, which is obtained from the composition, in cyclopentanone is less than 0.01 μm/sec, and the dissolution rate of the film having a film thickness of 10 μm of the contained resin in cyclopentanone is less than 0.01 μm/sec. In such a comparative example, it can be seen that the resolution is inferior.

### Example 101

The resin composition used in Example 1 was applied in a layered manner to a surface of a base material on which a copper wire having a line and space of 2 μm was formed by a spin coating method, dried at 110° C. for 5 minutes to form a resin composition layer having a film thickness of 5 μm, and exposed at a wavelength of 365 nm and an exposure amount of 300 mJ/cm² using an i-ray stepper (manufactured by Canon Inc.: FPA-3000 i5). Next, the layer was developed with cyclopentanone for 30 seconds and rinsed with PGMEA for 30 seconds to obtain a layer pattern. Next, the temperature was raised at a temperature rising rate of 10° C./min in a nitrogen atmosphere, and after the temperature reached 230° C., the temperature was maintained at 230° C. for 3 hours, thereby forming an interlayer insulating film for a re-distribution layer. This interlayer insulating film for a re-distribution layer was excellent in insulating properties.

In addition, in a case where a semiconductor device was manufactured using this interlayer insulating film for a re-distribution layer, it has been confirmed that the semiconductor device operates without any problem.

What is claimed is:

1. A resin composition comprising:
at least one resin selected from the group consisting of a polyimide and a precursor of the polyimide;
a polymerizable compound; and
a polymerization initiator,
wherein a dissolution rate of a film having a film thickness of 10 μm, which is obtained from the resin composition, in cyclopentanone is 0.01 to 0.55 μm/sec.

2. A resin composition comprising:
at least one resin selected from the group consisting of a polyimide and a precursor of the polyimide;
a polymerizable compound; and
a polymerization initiator,
wherein the resin composition includes a resin in which a dissolution rate of a film of the resin having a film thickness of 10 μm in cyclopentanone is 0.01 to 0.2 μm/sec as the resin.

3. The resin composition according to claim 1,
wherein a weight-average molecular weight of the resin is 8,000 or more and less than 30,000.

4. The resin composition according to claim 1,
wherein the resin is a resin having a ring structure with 5 or more ring members in a side chain.

5. The resin composition according to claim 1,
wherein the resin is a resin including a structure represented by Formula (A-1), 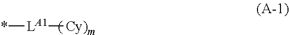
In Formula (A-1), L^{A1} represents a single bond or an (m+1)-valent linking group, Cy's each independently represent a ring structure with 5 or more ring members, which may have a substituent, m represents an integer of 1 or more, and * represents a bonding site to another structure.

6. The resin composition according to claim 1,
wherein the resin has a polymerizable group.

7. The resin composition according to claim 1,
wherein the resin has a repeating unit represented by Formula (1-1), 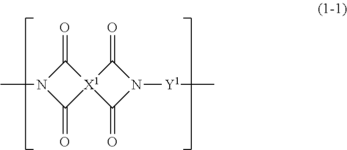
in Formula (1-1), X¹ is a tetravalent organic group, and Y¹ is an organic group including a group having an ethylenically unsaturated bond.

8. The resin composition according to claim 7,
wherein a value of a molar amount of oxygen atoms/weight-average molecular weight in the resin is 9.7 mmol/g or less.

9. The resin composition according to claim 7,
wherein Y¹ in Formula (1-1) includes a ring structure with 5 or more ring members.

10. The resin composition according to claim 7,
wherein Y¹ in Formula (1-1) includes a vinylphenyl group.

11. The resin composition according to claim 7,
wherein Y¹ in Formula (1-1) includes a structure represented by Formula (B-1) or (B-2), 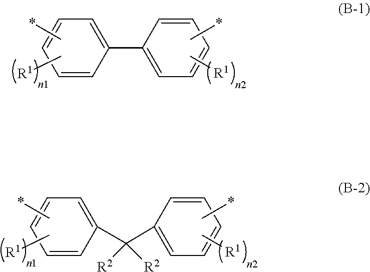
in Formula (B-1), R¹'s each independently represent an organic group including a group having an ethylenically unsaturated bond, n1 represents an integer of 0 to 3, n2 represents an integer of 0 to 3, n1+n2 represents an integer of 1 to 6, and * represents a bonding site to another structure,
in Formula (B-2), R¹'s each independently represent an organic group including a group having an ethylenically unsaturated bond, n1 represents an integer of 0 to 3, n2 represents an integer of 0 to 3, n1+n2 represents an integer of 1 to 6, R²'s each independently represent an alkyl group or a fluoroalkyl group, and * represents a bonding site to another structure.

12. The resin composition according to claim 11, further comprising:
a repeating unit represented by Formula (1-2), 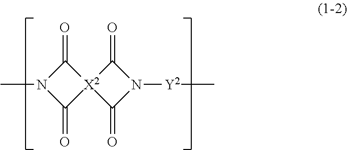
in Formula (1-2), X² is a tetravalent organic group, Y² is a divalent organic group having no ethylenically unsaturated bond, and at least one of X² or Y² includes a group obtained by removing two or more hydrogen atoms from a structure represented by Formula (C-1), 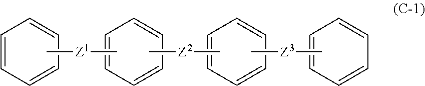
in Formula (C-1), Z¹ to Z³ are each independently a single bond or a divalent linking group, and four benzene rings described in Formula (C-1) may each have a substituent.

13. A resin composition comprising:
a resin having a repeating unit represented by Formula (1-3) and a structure represented by Formula (A-1);
a polymerizable compound; and
a polymerization initiator, 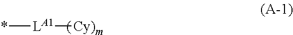
in Formula (A-1), L^{A1} represents a single bond or an (m+1)-valent linking group, Cy's each independently represent a ring structure with 5 or more ring members, which may have a substituent, m represents an integer of 1 or more, and * represents a bonding site to another structure, 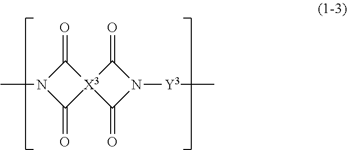
in Formula (1-3), X³ is a tetravalent organic group, Y³ is a divalent organic group including a vinylphenyl group, and Y³ includes a structure represented by Formula (B-1) or Formula (B-2), 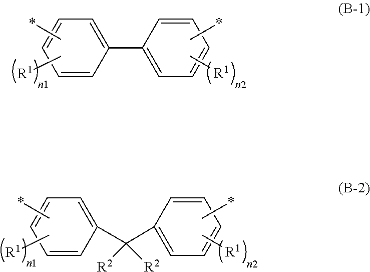
in Formula (B-1), R¹'s each independently represent an organic group including a group having an ethylenically unsaturated bond, n1 represents an integer of 0 to 3, n2 represents an integer of 0 to 3, n1+n2 represents an integer of 1 to 6, and * represents a bonding site to another structure,
in Formula (B-2), R¹'s each independently represent an organic group including a group having an ethylenically unsaturated bond, n1 represents an integer of 0 to 3, n2 represents an integer of 0 to 3, n1+n2 represents an integer of 1 to 6, R²'s each independently represent an alkyl group or a fluoroalkyl group, and * represents a bonding site to another structure.

14. The resin composition according to claim 1,
wherein the resin composition contains a radically polymerizable compound as the polymerizable compound, and
a content of the radically polymerizable compound is 8 parts by mass or more and 30 parts by mass or less with respect to 100 parts by mass of the resin.

15. The resin composition according to claim 1,
wherein the resin composition includes a photoradical polymerization initiator as the polymerization initiator, and
the resin composition includes a radically polymerizable compound as the polymerizable compound.

16. The resin composition according to claim 15,
wherein the radically polymerizable compound includes two or more (meth)acryloyl groups.

17. The resin composition according to claim 15,
wherein the resin composition includes an oxime compound as the photoradical polymerization initiator.

18. The resin composition according to claim 15,
wherein the resin composition includes a compound having a ketoxime group as the photoradical polymerization initiator.

19. The resin composition according to claim 1,
wherein the resin composition includes a resin having an ethylenically unsaturated bond equivalent of 0.5 to 2.0 mmol/g as the resin.

20. The resin composition according to claim 1,
wherein the resin composition is used for forming an interlayer insulating film for a re-distribution layer.

21. A cured substance obtained by curing the resin composition according to claim 1.

22. A laminate comprising:
two or more layers consisting of the cured substance according to claim 21; and
a metal layer provided between any of the layers consisting of the cured substance.

23. A manufacturing method for a cured substance, comprising:
a film forming step of applying the resin composition according to claim 1 onto a base material to form a film.

24. The manufacturing method for a cured substance according to claim 23, further comprising:
an exposure step of selectively exposing the film; and
a development step of developing the film using a developer to form a pattern.

25. The manufacturing method for a cured substance according to claim 23, further comprising:
a heating step of heating the film at 50° C. to 450° C.

26. A manufacturing method for a laminate, comprising:
the manufacturing method for a cured substance according to claim 23.

27. A manufacturing method for a semiconductor device, comprising:
the manufacturing method for a cured substance according to claim 23.

28. A semiconductor device comprising:
the cured substance according to claim 21.
